(19) United States
(12) Patent Application Publication
(10) Pub. No.: US 2023/0408920 A1
(43) Pub. Date: Dec. 21, 2023

(54) ACTINIC RAY-SENSITIVE OR RADIATION-SENSITIVE RESIN COMPOSITION, RESIST FILM, PATTERN FORMING METHOD, AND METHOD FOR MANUFACTURING ELECTRONIC DEVICE

(71) Applicant: FUJIFILM Corporation, Tokyo (JP)

(72) Inventors: Shuhei YAMAGUCHI, Haibara-gun (JP); Taro MIYOSHI, Haibara-gun (JP)

(73) Assignee: FUJIFILM Corporation, Tokyo (JP)

(21) Appl. No.: 18/458,609

(22) Filed: Aug. 30, 2023

Related U.S. Application Data
(63) Continuation of application No. PCT/JP22/08175, filed on Feb. 28, 2022.

(30) Foreign Application Priority Data
Mar. 12, 2021 (JP) 2021-040544

(51) Int. Cl. G03F 7/039

(52) U.S. Cl. CPC G03F 7/039

(57) ABSTRACT

Provided are an actinic ray-sensitive or radiation-sensitive resin composition in which LWR of a pattern to be obtained is excellent; a resist film; a pattern forming method; and a method for manufacturing an electronic device.

The actinic ray-sensitive or radiation-sensitive resin composition contains a resin having a group which is decomposed by action of acid to generate a polar group, in which the resin includes a repeating unit represented by General Formula (A2), and at least one of a requirement 1 or a requirement 2 is satisfied.
Requirement 1: the actinic ray-sensitive or radiation-sensitive resin composition contains a salt represented by General Formula (1)
Requirement 2: the resin has a residue formed by removing one hydrogen atom from the salt represented by General Formula (1)

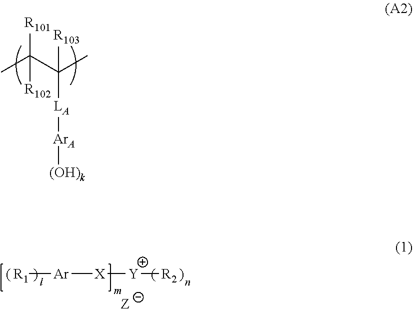

### CROSS-REFERENCE TO RELATED APPLICATIONS

This application is a Continuation of PCT International Application No. PCT/JP2022/008175 filed on Feb. 28, 2022, which claims priority under 35 U.S.C. § 119(a) to Japanese Patent Application No. 2021-040544 filed on Mar. 12, 2021. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. Description of the Related Art

Examples of a pattern forming method include the following methods.

An actinic ray-sensitive or radiation-sensitive resin film (hereinafter, also referred to as “resist film”) formed of an actinic ray-sensitive or radiation-sensitive resin composition is exposed to light to cause a change in solubility of the resist film in a developer in a region reflecting the exposed pattern. Thereafter, development is performed using a developer (for example, alkali water-based developer, organic solvent-based developer, or the like) to remove an exposed portion or non-exposed portion of the resist film, thereby obtaining a desired pattern.

For example, JP4407814B discloses a resist material containing a resin which has a group in which polarity is increased by action of acid and a photoacid generator which has phenacyltetrahydrothiophenium as a cation.

### SUMMARY OF THE INVENTION

The present inventors have studied a resist solution (actinic ray-sensitive or radiation-sensitive resin composition) formed of the resist material disclosed in JP4407814B, and have found that there is room for improvement in line width roughness (LWR) of a pattern obtained using a resist film formed of the resist composition disclosed in JP4407814B.

An object of the present invention is to provide an actinic ray-sensitive or radiation-sensitive resin composition in which LWR of a pattern to be obtained is excellent.

In addition, another object of the present invention is to provide a resist film, a pattern forming method, and a method for manufacturing an electronic device.

The present inventor has conducted intensive studies to achieve the above-described objects, and as a result, it has been found that the above-described objects can be achieved by the following configurations.

[1] An actinic ray-sensitive or radiation-sensitive resin composition comprising:
a resin having a group which is decomposed by action of acid to generate a polar group,
in which the resin includes a repeating unit represented by General Formula (A2) described later, and
at least one of a requirement 1 or a requirement 2 described later is satisfied.

[2] The actinic ray-sensitive or radiation-sensitive resin composition according to [1],
in which the salt represented by General Formula (1) is a salt represented by General Formula (2) described later.

[3] The actinic ray-sensitive or radiation-sensitive resin composition according to [1] or [2],
in which at least one of R₁'s represents a group represented by General Formula (X1) described later.

[4] The actinic ray-sensitive or radiation-sensitive resin composition according to any one of [1] to [3],
in which at least one of R₁'s represents a group represented by General Formula (X2) described later.

[5] The actinic ray-sensitive or radiation-sensitive resin composition according to any one of [1] to [4],
in which the resin has a repeating unit having a group which is decomposed by action of acid to generate a polar group, and
the group which is decomposed by action of acid to generate a polar group is a group which is decomposed by action of acid to generate a carboxy group or a phenolic hydroxyl group.

[6] The actinic ray-sensitive or radiation-sensitive resin composition according to [5],
in which the repeating unit having a group which is decomposed by action of acid to generate a polar group is a repeating unit represented by any one of General Formula (3), (4), (5), (6), or (7) described later.

[7] The actinic ray-sensitive or radiation-sensitive resin composition according to [6],
in which the repeating unit having a group which is decomposed by action of acid to generate a polar group is the repeating unit represented by General Formula (6) or General Formula (7).

[8] A resist film formed of the actinic ray-sensitive or radiation-sensitive resin composition according to any one of [1] to [7].

[9] A pattern forming method comprising:
a resist film forming step of forming a resist film using the actinic ray-sensitive or radiation-sensitive resin composition according to any one of [1] to [7];
an exposing step of exposing the resist film; and
a developing step of developing the exposed resist film using a developer.

[10] A method for manufacturing an electronic device, comprising:
the pattern forming method according to [9].

According to the present invention, it is possible to provide an actinic ray-sensitive or radiation-sensitive resin composition in which LWR of a pattern to be obtained is excellent.

In addition, according to the present invention, it is possible to provide a resist film, a pattern forming method, and a method for manufacturing an electronic device.

### BRIEF DESCRIPTION OF THE DRAWINGS

FIG. 1 is a proton nuclear magnetic resonance chart in a synthesis example of the salt represented by General Formula (1).

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Hereinafter, meaning of each description in the present specification will be explained.

“Organic group” refers to a group including at least one carbon atom.

In notations for a group (atomic group), in a case where the group is cited without specifying that it is substituted or unsubstituted, the group includes both a group having no substituent and a group having a substituent as long as it does not impair the spirit of the present invention. For example, an “alkyl group” includes not only an alkyl group having no substituent (unsubstituted alkyl group), but also an alkyl group having a substituent (substituted alkyl group).

The “alkyl group” represents a linear or branched alkyl group. “Cycloalkyl group” represents a cyclic alkyl group.

A substituent is a monovalent substituent unless otherwise specified.

Examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; an alkyl group; a cycloalkyl group; an aryl group (which may include a heteroatom); a hydroxyl group; a carboxyl group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; an alkylthio group; and a combination thereof. In the specification, these substituent groups are also referred to as “substituent K”.

“Actinic ray” or “radiation” means, for example, a bright line spectrum of a mercury lamp, far ultraviolet rays typified by an excimer laser, extreme ultraviolet rays (EUV light), X-rays, electron beams (EB), or the like.

“Light” means actinic ray or radiation.

Unless otherwise specified, “exposure” encompasses not only exposure by a bright line spectrum of a mercury lamp, far ultraviolet rays typified by an excimer laser, extreme ultraviolet rays (EUV light), X-rays, or the like, but also drawing by particle beams such as electron beams and ion beams.

“to” is used to mean that numerical values described before and after a range are included as the lower limit and the upper limit.

A bonding direction of divalent groups cited in the present specification is not limited unless otherwise specified. For example, in a case where Y in a compound represented by General Formula “X—Y—Z” is —COO—, Y may be —CO—O— or —O—CO—. In addition, the above-described compound may be “X—CO—O—Z” or “X—O—CO—Z”.

(Meth)acrylate represents acrylate and methacrylate.

(Meth)acrylic represents acrylic and methacrylic.

A weight-average molecular weight (Mw), a number-average molecular weight (Mn), and a dispersity (hereinafter, also referred to as “molecular weight distribution”) (Mw/Mn) of a resin are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

A compositional ratio (molar ratio, mass ratio, or the like) of a resin is measured by ¹³C-nuclear magnetic resonance (NMR).

An acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicates values determined by computation using the software package.

Software Package 1: Advanced Chemistry Development (ACD/Labs) Software V 8.14 for Solaris (1994-2007 ACD/Labs).

On the other hand, the pKa can also be determined by a molecular orbital computation method. Examples of a specific method therefor include a method for performing calculation by computing H⁺ dissociation free energy in an aqueous solution based on a thermodynamic cycle. With regard to a computation method for H⁺ dissociation free energy, the H⁺ dissociation free energy can be computed by, for example, density functional theory (DFT), but various other methods have been reported in literature and the like, and are not limited thereto. There are a plurality of software applications capable of performing DFT, and examples thereof include Gaussian 16.

As described above, the pKa means a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

In addition, the pKa means a “pKa in an aqueous solution” as described above, but in a case where the pKa in an aqueous solution cannot be calculated, a “pKa in a dimethyl sulfoxide (DMSO) solution” is adopted.

“Solid content” is intended to be components which form the resist film, and does not include a solvent. In addition, even in a case where a component is liquid, the component is included in the solid content as long as the component forms the resist film.

“1 inch” means 25.4 mm.

{Actinic Ray-Sensitive or Radiation-Sensitive Resin Composition}

The actinic ray-sensitive or radiation-sensitive resin composition according to the embodiment of the present invention is a composition containing a resin having a group which is decomposed by action of acid to generate a polar group, in which the resin includes a repeating unit represented by General Formula (A2), and at least one of a requirement 1 or a requirement 2 is satisfied.
Requirement 1: the actinic ray-sensitive or radiation-sensitive resin composition contains a salt represented by General Formula (1)
Requirement 2: the resin has a residue formed by removing one hydrogen atom from the salt represented by General Formula (1)

Hereinafter, the “actinic ray-sensitive or radiation-sensitive resin composition” will also be referred to as “resist composition”.

Hereinafter, the “resin having a group which is decomposed by action of acid to generate a polar group” will also referred to as “acid-decomposable resin”.

Hereinafter, the “repeating unit represented by General Formula (A2)” will also be referred to as “repeating unit A2”.

Hereinafter, the “salt represented by General Formula (1)” will also be referred to as “salt B”, and the “residue formed by removing one hydrogen atom from the salt represented by General Formula (1)” will also be referred to as “specific group”.

Hereinafter, each of the above-described requirements will also be referred to as “requirement 1” and “requirement 2”.

A working mechanism by which LWR in a case of forming a pattern is improved by adopting such configurations is not always clear, but is presumed to be as follows by the present inventors.

Since the salt B and the specific group according to the present invention have an electron-withdrawing group, charges in the salt B and the specific group are dispersed, and interaction with the phenolic hydroxyl group included in the repeating unit A2 is relaxed. As a result, compatibility between the salt B and the specific group in the resist film is improved, so that it is presumed that the LWR is excellent.

In addition, according to the present invention, it is possible to provide a resist film, a pattern forming method, and a method for manufacturing an electronic device, which relate to the actinic ray-sensitive or radiation-sensitive resin composition.

Hereinafter, a case where the LWR of the pattern to be obtained is more excellent is also referred to as “effect of the present invention is more excellent”.

Hereinafter, the resist composition according to the embodiment of the present invention will be described in detail.

The resist composition may be either a positive tone resist composition or a negative tone resist composition. In addition, the resist composition may be either a resist composition for alkali development or a resist composition for organic solvent development.

The resist composition may be a non-chemically amplified resist composition, or may have a mechanism as a chemically amplified resist composition in combination with the resist composition.

Hereinafter, various components of the resist composition will be described in detail.

[Salt B]

The salt B is a salt represented by General Formula (1).

The salt B can function as a photoacid generator.

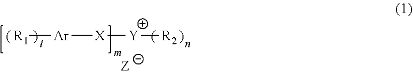

In General Formula (1), R₁'s each independently represent a monovalent substituent, R₂ represents an alkyl group which may have a substituent, a cycloalkyl group which may have a substituent, or an aryl group which may have a substituent, where in a case where n is 2, two R₂'s may be bonded to each other to form a ring, Ar represents an (l+1)-valent aromatic ring group, X represents a single bond or a divalent linking group, Y represents a sulfur atom or an iodine atom, Z⁻ represents an anion, 1 represents an integer of 1 to 5, in a case where Y is a sulfur atom, m represents an integer of 1 to 3 and n represents 3−m, in a case where Y is an iodine atom, m represents 1 or 2 and n represents 2−m, and at least one of R₁'s represents an electron-withdrawing group.

In General Formula (1), at least one of R₁'s is an electron-withdrawing group.

Among these, from the viewpoint that the effect of the present invention is more excellent, it is preferable that all of R₁'s are electron-withdrawing groups.

In the present specification, the electron-withdrawing group refers to a group in which a Hammett's substituent constant σₚ value is positive.

The substituent constant σₚ of Hammett's law is a numerical value representing an effect of the substituent on the acid dissociation equilibrium constant of a substituted benzoic acid, and is a parameter indicating electron-withdrawing and electron-donating strengths of the substituent. The Hammett's substituent constant σₚ value in the present specification indicates the substituent constant σ in a case where the substituent is positioned at the para position of benzoic acid. For the σₚ value, a value described in Chem. Rev., 1991, 91, 2, pp. 165 to 195 can be adopted. For substituents not described in the above literature, a value calculated according to a calculation method described in a literature “The Effect of Structure upon the Reactions of Organic Compounds. Benzene Derivatives” (J. Am. Chem. Soc. 1937, 59, 1, pp. 96 to 103).

The substituent constant σₚ value of the electron-withdrawing group represented by R₁ is preferably 0.30 or more, more preferably 0.50 or more, and still more preferably 0.60 or more. The upper limit thereof is not particularly limited, but is 1.50 or less in many cases and 1.30 or less in more cases.

Atoms constituting the electron-withdrawing group are not particularly limited, but preferably include any one of a carbon atom, a sulfur atom, or a nitrogen atom. Among the atoms constituting the electron-withdrawing group, it is preferable that any one of a carbon atom, a sulfur atom, or a nitrogen atom is directly bonded to Ar, and in particular, it is more preferable that a sulfur atom is bonded to Ar.

Examples of the electron-withdrawing group include an alkylacyl group, an arylacyl group, an alkyloxycarbonyl group, an aryloxycarbonyl group, a formyl group, a carbamoyl group, a cyano group, a nitro group, an alkylsulfinyl group, a cycloalkylsulfinyl group, an arylsulfinyl group, an alkylsulfonyl group, a cycloalkylsulfonyl group, an arylsulfonyl group, an alkyloxysulfonyl group, a cycloalkyloxysulfonyl group, and an acyloxysulfonyl group. In an alkyl group moiety and a cycloalkyl group moiety included in the above-described electron-withdrawing group, a hydrogen atom may be substituted with a halogen atom. The halogen atom is not particularly limited, and a fluorine atom is preferable. Among these, from the viewpoint that the effect of the present invention is more excellent, an alkylsulfonyl group, a cycloalkylsulfonyl group, or an arylsulfonyl group.

The number of carbon atoms in the alkyl group moiety included in the alkylsulfonyl group is not particularly limited, but is preferably 1 to 10, more preferably 1 to 5, and still more preferably 1 to 3.

All hydrogen atoms in the alkyl group moiety included in the alkylsulfonyl group may be substituted with halogen atoms (preferably, fluorine atoms).

All hydrogen atoms in the cycloalkyl group moiety included in the cycloalkylsulfonyl group may be substituted with halogen atoms (preferably, fluorine atoms).

An aryl group moiety included in the arylsulfonyl group may be monocyclic or polycyclic.

In addition, the aryl group moiety included in the arylsulfonyl group may include a heteroatom.

In addition, the aryl group moiety included in the arylsulfonyl group may be substituted with a halogen atom.

Examples of a ring constituting the aryl group moiety included in the arylsulfonyl group include a benzene ring, a naphthalene ring, a pyridine ring, a pyrrole ring, a furan ring, and a benzimidazole ring.

From the viewpoint that the effect of the present invention is more excellent, it is preferable that at least one of R₁'s is a group represented by General Formula (X1). The group represented by General Formula (X1) is preferably an electron-withdrawing group.

*-L-R₅ (X1)

In General Formula (X1), L represents —CO—, —SO₂—, or —SO—. R₅ represents a monovalent substituent. * represents a bonding position.

L is preferably —CO— or —SO₂—, and more preferably —SO₂—.

The monovalent substituent represented by R₅ is not particularly limited, and examples thereof include groups exemplified by the above-described substituent K. Among these, from the viewpoint that the effect of the present invention is more excellent, an alkyl group which may have a substituent, a cycloalkyl group which may have a substituent, or an aryl group which may have a substituent is preferable.

From the viewpoint that the effect of the present invention is more excellent, the number of carbon atoms in an alkyl group moiety in the alkyl group which may have a substituent is preferably 1 to 6, and more preferably 1 or 2.

The alkyl group moiety in the alkyl group which may have a substituent may be linear or branched.

Examples of the alkyl group moiety in the alkyl group which may have a substituent include a methyl group, an ethyl group, a propyl group, a isopropyl group, an sec-butyl group, and a t-butyl group, and a methyl group or an ethyl group is preferable. Examples of the substituent which may be included in the alkyl group include groups exemplified by the above-described substituent K, and a halogen atom is preferable and a fluorine atom is more preferable.

A part of hydrogen atoms in the alkyl group may be substituted with a substituent, or all the hydrogen atoms may be substituted with a substituent.

From the viewpoint that the effect of the present invention is more excellent, the number of carbon atoms in a cycloalkyl group moiety in the cycloalkyl group which may have a substituent is preferably 4 to 20, and more preferably 5 to 12.

The cycloalkyl group may be monocyclic or polycyclic.

Examples of the cycloalkyl group include a cyclopropyl group, a cyclobutyl group, and a cyclohexyl group.

A part of hydrogen atoms in the cycloalkyl group may be substituted with a substituent, or all the hydrogen atoms may be substituted with a substituent.

From the viewpoint that the effect of the present invention is more excellent, the number of carbon atoms in an aryl group moiety in the aryl group which may have a substituent is preferably 6 to 18, and more preferably 6 to 12.

The aryl group moiety in the aryl group which may have a substituent may be monocyclic or polycyclic.

In addition, the aryl group moiety in the aryl group which may have a substituent may include a heteroatom.

Examples of a ring constituting the aryl group moiety in the aryl group which may have a substituent include a benzene ring, a naphthalene ring, a pyridine ring, a pyrrole ring, a furan ring, and a benzimidazole ring. Examples of the substituent which may be included in the aryl group include groups exemplified by the above-described substituent K, and specific examples thereof include an alkyl group (for example, having 1 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom (for example, fluorine and iodine), a hydroxyl group, a carboxy group, and an alkylthio group.

Among these, from the viewpoint that the effect of the present invention is more excellent, it is preferable that at least one of R₁'s represents a group represented by General Formula (X2).

*—SO₂—R₅ (X2)

In General Formula (X2), R₅ represents a monovalent substituent. * represents a bonding position.

Since the definition of R₅ in General Formula (X2) is the same as the definition of R₅ in General Formula (X1), the description thereof will be omitted.

Examples of the electron-withdrawing group include a trifluoromethoxy group, an acetyl group, a trifluoroacetyl group, an ethylacyl group, a perfluoroethylacyl group, an n-propylacyl group, a perfluoro n-propylacyl group, a methyloxycarbonyl group, an ethyloxycarbonyl group, a phenylcarbonyloxy group, a methylsulfonyl group, a trifluoromethylsulfonyl group, an ethylsulfonyl group, a perfluoroethylsulfonyl group, a phenylsulfonyl group, a methyloxysulfonyl group, an ethyloxysulfonyl group, a methylsulfinyl group, a trifluoromethylsulfinyl group, an ethyl sulfinyl group, and a phenylsulfinyl group. Among these, a trifluoroacetyl group, a methylsulfonyl group, an ethylsulfonyl group, or a phenylsulfonyl group is preferable. In addition, from the viewpoint that development defect described later is suppressed, a methylsulfonyl group, an ethylsulfonyl group, or a phenylsulfonyl group is more preferable.

l represents an integer of 1 to 5. Among these, from the viewpoint that the effect of the present invention is more excellent, 1 or 2 is preferable, and 1 is more preferable.

R₁ which is not the electron-withdrawing group is not particularly limited, and examples thereof include an alkyl group which may have a substituent, a cycloalkyl group which may have a substituent, and an aryl group which may have a substituent.

The number of R₁'s which are not the electron-withdrawing groups is preferably 0 to 2, and more preferably 0.

In General Formula (1), R₂ represents an alkyl group which may have a substituent, a cycloalkyl group which may have a substituent, or an aryl group which may have a substituent, in which, in a case where n is 2, two R₂'s may be bonded to each other to form a ring.

From the viewpoint that the effect of the present invention is more excellent, the number of carbon atoms in an alkyl group moiety in the alkyl group which may have a substituent is preferably 1 to 6, and more preferably 1 or 2.

The alkyl group moiety in the alkyl group which may have a substituent may be linear or branched.

Examples of the alkyl group moiety in the alkyl group which may have a substituent include a methyl group, an ethyl group, a propyl group, a isopropyl group, an sec-butyl group, and a t-butyl group, and a methyl group or an ethyl group is preferable. Examples of the substituent which may be included in the alkyl group include groups exemplified by the above-described substituent K, and a halogen atom is preferable and a fluorine atom is more preferable.

A part of hydrogen atoms in the alkyl group may be substituted with a substituent, or all the hydrogen atoms may be substituted with a substituent.

From the viewpoint that the effect of the present invention is more excellent, the number of carbon atoms in a cycloalkyl group moiety in the cycloalkyl group which may have a substituent is preferably 4 to 20, and more preferably 5 to 12.

The cycloalkyl group may be monocyclic or polycyclic.

Examples of the cycloalkyl group include a cyclopropyl group, a cyclobutyl group, and a cyclohexyl group.

A part of hydrogen atoms in the cycloalkyl group may be substituted with a substituent, or all the hydrogen atoms may be substituted with a substituent.

From the viewpoint that the effect of the present invention is more excellent, the number of carbon atoms in an aryl group moiety in the aryl group which may have a substituent is preferably 6 to 18, and more preferably 6 to 12.

The aryl group moiety in the aryl group which may have a substituent may be monocyclic or polycyclic.

Examples of the aryl group in the aryl group which may have a substituent include a phenyl group and a naphthyl group. Examples of the substituent which may be included in the aryl group include groups exemplified by the above-described substituent K, and specific examples thereof include an alkyl group (for example, having 1 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom (for example, fluorine and iodine), a hydroxyl group, a carboxy group, and an alkylthio group.

In a case where n is 2, two R₂'s may be bonded to each other to form a ring, and the type of the ring to be formed is not particularly limited. Examples thereof include an alicyclic ring which may have a heteroatom (for example, an oxygen atom and a sulfur atom) and an aromatic ring which may have a heteroatom.

In General Formula (1), Ar represents an (l+1)-valent aromatic ring group. The (l+1)-valent aromatic ring group corresponds to a group formed by removing l+1 hydrogen atoms from an aromatic ring. For example, in a case where the (l+1) is 2, Ar represents a divalent aromatic ring group (an arylene group or a heteroarylene group).

The aromatic ring group is not particularly limited, and the aromatic ring constituting the aromatic ring group may be monocyclic or polycyclic.

Examples of the aromatic ring constituting the aromatic ring group include an aromatic hydrocarbon ring and an aromatic heterocyclic ring. Examples of the aromatic hydrocarbon ring include a benzene ring, a naphthalene ring, an anthracene ring, a phenanthrene ring, and a pyrene ring. Examples of the aromatic heterocyclic ring include a furan ring, a pyrrole ring, a pyrazole ring, an imidazole ring, a thiophene ring, an oxazole ring, and a thiazole ring.

In a case where the aromatic ring constituting the aromatic ring group is polycyclic, it may be a polycycle in which an aromatic hydrocarbon ring and an aromatic heterocyclic ring are combined. Examples of the polycycle include an indole ring, an isoindole ring, a benzimidazole ring, a purine ring, a carbazole ring, a benzofuran ring, an isobenzofuran ring, a benzothiophene ring, a benzoxazole ring, and a benzothiazole ring.

In General Formula (1), X represents a single bond or a divalent linking group.

The divalent linking group is not particularly limited, and examples thereof include —CO—, —O—, —NR^{X}—, —S—, —SO—, —SO₂—, an alkylene group (for example, having 1 to 6 carbon atoms), a cycloalkylene group (for example, having 3 to 15 carbon atoms), an alkenylene group (for example, having 2 to 6 carbon atoms), an alkynylene group, an arylene group, and a group combining a plurality of these groups (for example, —O—CO—O—, —COO—, —OCO—, —CONH—, and —NHCO—). R^{X} represents a hydrogen atom or a substituent. Examples of the above-described substituent include groups exemplified by the substituent K.

A hydrogen atom in the alkylene group, cycloalkylene group, alkenylene group, alkynylene group, and arylene group may be substituted with a substituent. Examples of the substituent include groups exemplified by the substituent K, and a halogen atom is preferable.

Among these, from the viewpoint that the effect of the present invention is more excellent, X is preferably —CO-alkylene group-.

In General Formula (1), Y represents a sulfur atom or an iodine atom.

In a case where Y is a sulfur atom, m represents an integer of 1 to 3 and n represents 3−m.

In a case where Y is an iodine atom, m represents 1 or 2 and n represents 2−m.

Y is preferably a sulfur atom.

It is preferable that m is 1 and n is 2.

Z⁻ represents an anion. Details of the anion will be described later together with Z⁻ in General Formula (2) described later.

From the viewpoint that the effect of the present invention is more excellent, the salt B is preferably a salt represented by General Formula (2).

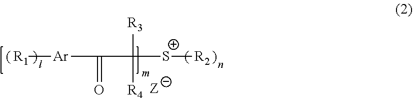

In General Formula (2), R₁'s each independently represent a monovalent substituent, R₂ represents an alkyl group which may have a substituent, a cycloalkyl group which may have a substituent, or an aryl group which may have a substituent, where in a case where n is 2, two R₂'s may be bonded to each other to form a ring, Ar represents an (l+1)-valent aromatic ring group, R₃ and R₄ each independently represent a hydrogen atom, an alkyl group, a cycloalkyl group, or an aryl group, where R₃ and R₄ may be bonded to each other to form a ring, Z⁻ represents an anion, 1 represents an integer of 1 to 5, m represents an integer of 1 to 3,

n represents 3−m, and at least one of R₁'s represents an electron-withdrawing group.

The definitions and suitable aspects of R₁, R₂, Ar, n, m, and 1 in General Formula (2) are the same as the definitions and suitable aspects of each group in General Formula (1).

R₃ and R₄ each independently represent a hydrogen atom, an alkyl group, a cycloalkyl group, or an aryl group, which may be bonded to each other to form a ring.

The number of carbon atoms in the alkyl group is not particularly limited, but from the viewpoint that the effect of the present invention is more excellent, it is preferably 1 to 6 and more preferably 1 or 2.

The alkyl group may be linear or branched.

Examples of the alkyl group include a methyl group, an ethyl group, a propyl group, an isopropyl group, an n-butyl group, an sec-butyl group, and a t-butyl group.

The number of carbon atoms in the cycloalkyl group is not particularly limited, but from the viewpoint that the effect of the present invention is more excellent, it is preferably 4 to 20 and more preferably 4 to 10.

The cycloalkyl group may be monocyclic or polycyclic.

Examples of the cycloalkyl group include a cyclopropyl group, a cyclobutyl group, and a cyclohexyl group.

Examples of the aryl group include a phenyl group and a naphthyl group.

Among these, R₃ and R₄ are each independently preferably a hydrogen atom, a methyl group, an ethyl group, an isopropyl group, a butyl group, or a t-butyl group, and more preferably a hydrogen atom, a methyl group, an isopropyl group, or a t-butyl group.

The combination of R₃ and R₄ is preferably a hydrogen atom and a hydrogen atom, a hydrogen atom and a t-butyl group, or a methyl group and a methyl group.

The ring formed by bonding R₃ and R₄ to each other is not particularly limited, and examples thereof include an alicyclic ring which may have a heteroatom (for example, an oxygen atom and a sulfur atom) and an aromatic ring which may have a heteroatom.

Specific examples of the salt B are shown below, but the present invention is not limited thereto.

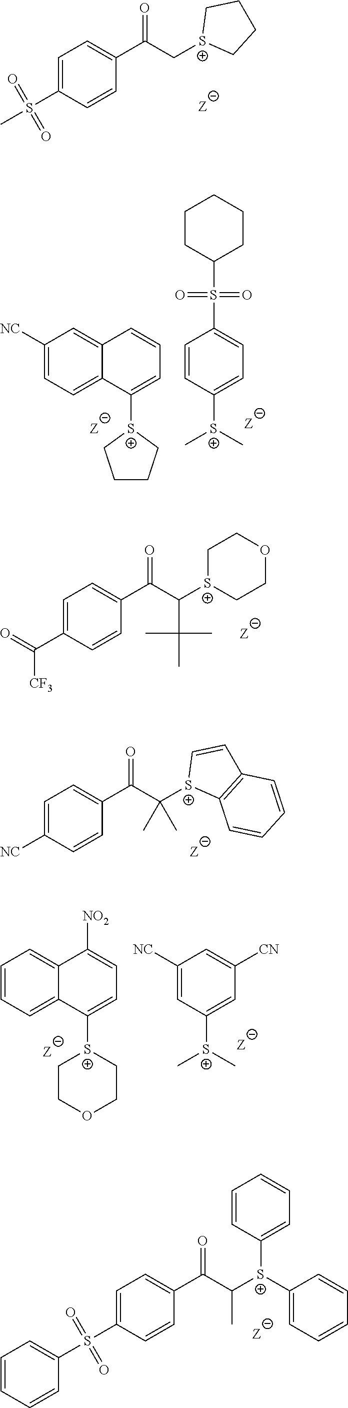

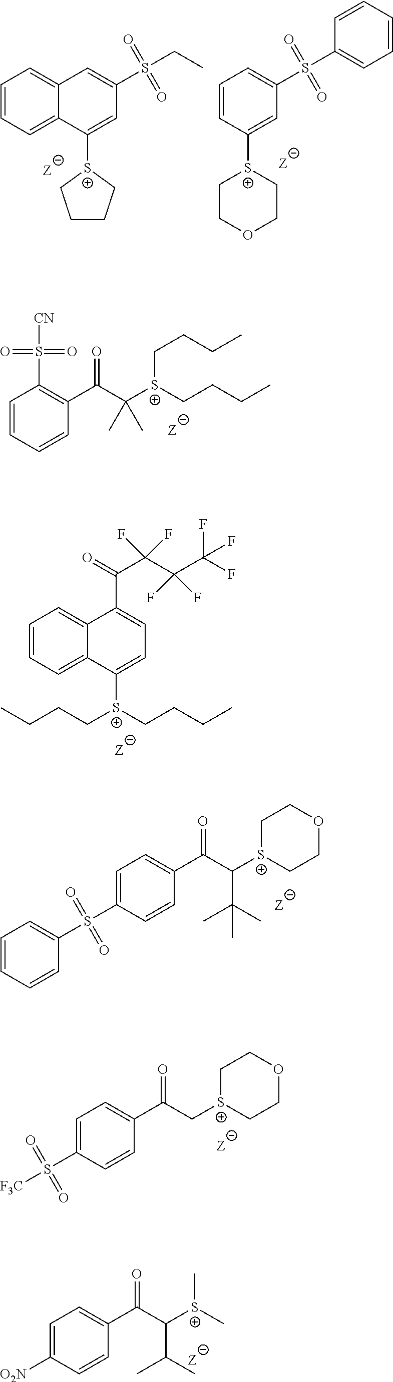

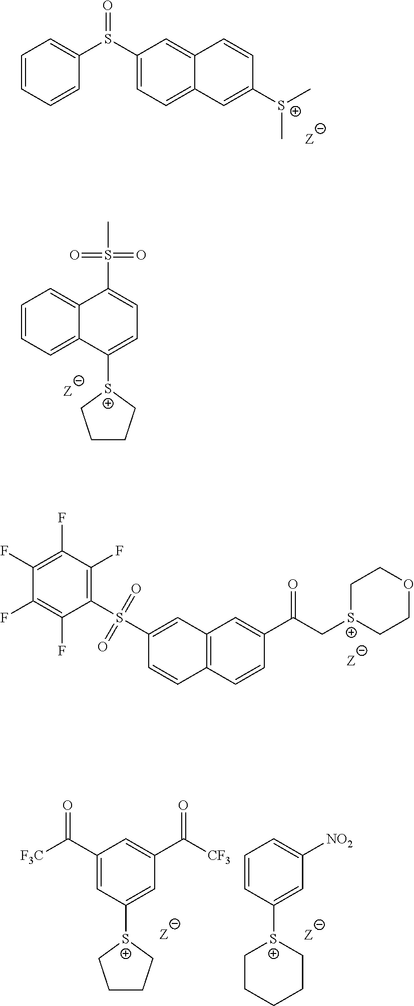

In General Formulae (1) and (2), Z⁻ represents an anion.

The anion is not particularly limited, and examples thereof include an inorganic anion and an organic anion. An organic anion is preferable.

The organic anion is not particularly limited, and examples thereof include a phenolic hydroxyl anion, a sulfonate anion (for example, an aliphatic sulfonate anion, an aromatic sulfonate anion, a camphor sulfonate anion, and the like), a carboxylate anion (for example, an aliphatic carboxylate anion, an aromatic carboxylate anion, an aralkyl carboxylate anion, a formate anion, a bicarbonate anion, and the like), a carbonylsulfonylimide anion, a bis(sulfonyl)imide anion (for example, a bis(alkylsulfonyl)imide anion and the like), a bis(carbonyl)imide anion, and a tris(alkylsulfonyl)methide anion.

An aliphatic moiety in the aliphatic sulfonate anion and the aliphatic carboxylate anion may be an alkyl group or a cycloalkyl group, and a linear or branched alkyl group having 1 to 30 carbon atoms or a cycloalkyl group having 3 to 30 carbon atoms is preferable.

The above-described alkyl group may be, for example, a fluoroalkyl group. The fluoroalkyl group may or may not have a substituent other than a fluorine atom, and may be a perfluoroalkyl group.

The above-described cycloalkyl group may be monocyclic or polycyclic, and one or more —CH₂-'s constituting a ring structure may be replaced with a heteroatom, —SO₂—, —SO₃—, an ester group, or a carbonyl group. The number of —CH₂—'s to be substituted is preferably 1 or 2. Examples of the heteroatom include an oxygen atom and a sulfur atom.

An aryl group in the aromatic sulfonate anion and the aromatic carboxylate anion is preferably an aryl group having 6 to 14 carbon atoms, and examples thereof include a phenyl group, a tolyl group, and a naphthyl group.

The alkyl group, cycloalkyl group, and aryl group mentioned above may have a substituent. The substituent is not particularly limited, and examples thereof include a nitro group, a halogen atom such as a fluorine atom and a chlorine atom, a carboxy group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

An aralkyl group in the aralkyl carboxylate anion is preferably an aralkyl group having 7 to 14 carbon atoms, and examples thereof include a benzyl group, a phenethyl group, a naphthylmethyl group, a naphthylethyl group, and a naphthylbutyl group.

Examples of the sulfonylimide anion include a saccharin anion.

As the alkyl group in the bis(alkylsulfonyl)imide anion and the tris(alkylsulfonyl)methide anion, an alkyl group having 1 to 5 carbon atoms is preferable. Examples of a substituent of these alkyl group include a halogen atom, an alkyl group substituted with a halogen atom, an alkoxy group, an alkylthio group, a cycloalkylsulfonyl group, an alkyloxysulfonyl group, an aryloxysulfonyl group, a cycloalkylaryloxysulfonyl group, and a cycloalkylaryloxysulfonyl group. A part of the alkyl group included in the substituent may be further substituted. Among these, as a substituent in the alkyl group of the bis(alkylsulfonyl)imide anion and the tris(alkylsulfonyl)methide anion, a fluorine atom or an alkyl group substituted with a fluorine atom is preferable.

In addition, the alkyl groups in the bis(alkylsulfonyl)imide anion may be bonded to each other to form a ring structure.

The organic anion is also preferably an aliphatic sulfonate anion in which at least an α-position of the sulfonic acid is substituted with a fluorine atom (for example, an aliphatic sulfonate anion in which one or two fluorine atoms are substituted at the α-position, and the like); an aliphatic sulfonate anion in which an α-position of the sulfonic acid is not substituted with a fluorine atom (for example, an aliphatic sulfonate anion a fluorine atom is not substituted at the α-position and zero to three of a fluorine atom or a perfluoroalkyl group are substituted at a β-position, and the like); an aromatic sulfonate anion substituted with a fluorine atom or a group having a fluorine atom; a bis(alkylsulfonyl)imide anion in which an alkyl group is substituted with a fluorine atom; or a tris(alkylsulfonyl)methide anion in which an alkyl group is substituted with a fluorine atom.

In addition, as the organic anion, an anion represented by General Formula (AN) is also preferable.

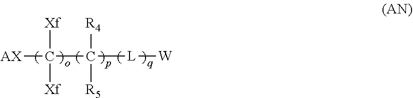

In General Formula (AN), AX represents —SO₃⁻ or —COO⁻. Xf represents a fluorine atom or an alkyl group substituted with at least one fluorine atom. R₄ and R₅ each independently represent a hydrogen atom, a fluorine atom, an alkyl group, or an alkyl group substituted with at least one fluorine atom. L represents a divalent linking group. W represents an organic group including a cyclic structure. In General Formula (AN), o represents an integer of 0 to 5. p represents an integer of 0 to 10. q represents an integer of 0 to 10.

In General Formula (AN), Xf represents a fluorine atom or an alkyl group substituted with at least one fluorine atom. The number of carbon atoms in the alkyl group is preferably 1 to 10 and more preferably 1 to 4. In addition, the alkyl group substituted with at least one fluorine atom is preferably a perfluoroalkyl group.

Xf is preferably a fluorine atom or a perfluoroalkyl group having 1 to 4 carbon atoms, and more preferably a fluorine atom or CF₃. In particular, it is still more preferable that both of the two Xf's are fluorine atoms.

In General Formula (AN), R₄ and R₅ each independently represent a hydrogen atom, a fluorine atom, an alkyl group, or an alkyl group substituted with at least one fluorine atom. In a case of a plurality of R₄ and R₅, R₄ and R₅ may be the same or different from each other.

The alkyl group represented by R₄ and R₅ may have a substituent other than the fluorine atom, and the number of carbon atoms therein is preferably 1 to 4.

Specific examples and suitable aspects of the alkyl group substituted with at least one fluorine atom are the same as the specific examples and suitable aspects of Xf.

R₄ and R₅ are preferably a hydrogen atom.

In addition, it is also preferable that one of R₄ and R₅ bonded to the same carbon atom is a hydrogen atom and the other is a fluorine atom or an alkyl group substituted with at least one fluorine atom. Among these, it is also preferable that, in —C(R₄)(R₅)— at least one of the first and second closest positions to AX, one of R₄ and R₅ bonded to the same carbon atom is a hydrogen atom and the other is a fluorine atom or an alkyl group substituted with at least one fluorine atom. In addition, it is also preferable that, in the —C(R₄)(R₅)— at least one of the first and second closest positions to AX, R₄ and R₅ are each independently a hydrogen atom or an alkyl group which may have a substituent other than the fluorine atom.

In General Formula (AN), L represents a divalent linking group. In a case of a plurality of L's, L's may be the same or different from each other.

Examples of the divalent linking group include —CO—, —O—, —NR^{X}—, —S—, —SO—, —SO₂—, an alkylene group (for example, having 1 to 6 carbon atoms), a cycloalkylene group (preferably having 3 to 15 carbon atoms), an alkenylene group (for example, having 2 to 6 carbon atoms), an alkynylene group, and a group combining a plurality of these groups (for example, —O—CO—O—, —COO—, —OCO—, —CONH—, and —NHCO—). R^{X} represents a hydrogen atom or a substituent. Examples of the above-described substituent include groups exemplified by the substituent K.

Among these, —O—CO—O—, —COO—, —OCO—, —CONH—, —NHCO—, —CO—, —O—, —SO₂—, —O—CO—O-alkylene group-, -alkylene group-O—CO—O—, —COO-alkylene group-, —OCO-alkylene group-, —CONH-alkylene group-, or —NHCO-alkylene group- is preferable; and —O—CO—O—, —O—CO—O-alkylene group-, -alkylene group-O—CO—O—, —COO—, —OCO—, —CONH—, —SO₂—, —COO-alkylene group-, or —OCO-alkylene group- is more preferable.

In General Formula (AN), W represents an organic group including a cyclic structure. Among these, a cyclic organic group is preferable.

Examples of the cyclic organic group include an alicyclic group, an aryl group, and a heterocyclic group. The cyclic organic group may be bonded to L through a linear organic group.

The alicyclic group may be monocyclic or polycyclic. Examples of the monocyclic alicyclic group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, an adamantyl group, and a cyclopentanoperhydrophenanthrenyl group. Among these, an alicyclic group having a bulky structure with 7 or more carbon atoms, such as a norbornyl group, a tricyclodecanyl group, a tetracyclodecanyl group, a tetracyclododecanyl group, an adamantyl group, and a cyclopentanoperhydrophenanthrenyl group, is preferable.

The bond with a carbon atom in the alicyclic ring group may be replaced with a bond including a heteroatom. Examples of the heteroatom include a nitrogen atom, an oxygen atom, and a sulfur atom.

The aryl group may be monocyclic or polycyclic. Examples of the aryl group include a phenyl group, a naphthyl group, a phenanthryl group, and an anthryl group.

The heterocyclic group may be monocyclic or polycyclic. In addition, the heterocyclic group may or may not have aromaticity. Examples of a heterocycle having aromaticity include a furan ring, a thiophene ring, a benzofuran ring, a benzothiophene ring, a dibenzofuran ring, a dibenzothiophene ring, and a pyridine ring. Examples of a heterocycle not having aromaticity include a tetrahydropyran ring, a lactone ring, a sultone ring, and a decahydroisoquinoline ring. As the heterocycle in the heterocyclic group, a furan ring, a thiophene ring, a pyridine ring, or a decahydroisoquinoline ring is preferable.

The above-described cyclic organic group may have a substituent. Examples of the substituent include an alkyl group (may be linear or branched; preferably having 1 to 12 carbon atoms), a cycloalkyl group (may be monocyclic, polycyclic, or spirocyclic; preferably having 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group, and a sulfonic acid ester group. A carbon constituting the cyclic organic group (carbon contributing to ring formation) may be a carbonyl carbon.

As the anion represented by General Formula (AN), AX-CF₂—CH₂—OCO-(L)q′-W, AX-CF₂—CHF—CH₂—OCO-(L)q′-W, AX-CF₂—COO-(L)q′-W, AX-CF₂—CF₂—CH₂—CH₂-(L)q-W, or AX-CF₂—CH(CF₃)—OCO-(L)q′-W is preferable. Here, AX, L, q, and W are the same as in General Formula (AN). q′ represents an integer of 0 to 10.

The organic anion may be an anion represented by General Formula (b1).

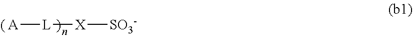

In General Formula (b1), L represents a single bond or a divalent linking group. In a case of a plurality of L's, the plurality of L's may be the same or different from each other. A represents a group which is decomposed by action of acid. In a case of a plurality of A's, the plurality of A's may be the same or different from each other. n represents an integer of 1 to 5. X represents an (n+1)-valent linking group.

In General Formula (b1), X represents an (n+1)-valent linking group.

The linking group represented by X is not particularly limited, and examples thereof include an aliphatic group which may be linear, branched, or cyclic, an aromatic ring group, —O—, —CO—, —COO—, —OCO—, and a group formed by combination of two or more of these groups.

As the above-described aliphatic group, a group formed by removing n+1 hydrogen atoms from alkane or a group formed by removing n+1 hydrogen atoms from cycloalkane is preferable. The alkane may be linear or branched, and the number of carbon atoms is preferably 1 to 20 and more preferably 1 to 10. The cycloalkane may be monocyclic or polycyclic, and the number of carbon atoms is preferably 3 to 20 and more preferably 5 to 10.

The above-described aliphatic group may have a substituent, and examples of the substituent include groups exemplified by the above-described substituent K.

The above-described aliphatic group may have a heteroatom (for example, a sulfur atom, an oxygen atom, and a nitrogen atom) between carbon atoms.

The above-described aromatic ring group is preferably a group formed by removing n+1 hydrogen atoms from an aromatic ring. The number of carbon atoms in the aromatic ring group is preferably 6 to 20, more preferably 6 to 18, and still more preferably 6 to 10.

The above-described aromatic ring group may have a substituent, and examples of the substituent include the above-described substituent K.

The above-described aromatic ring group may have a heteroatom (for example, a sulfur atom, an oxygen atom, and a nitrogen atom) between carbon atoms.

X is preferably an (n+1)-valent aromatic ring group.

In General Formula (b1), n represents an integer of 1 to 5, and is preferably an integer of 1 to 3, more preferably 2 or 3, and still more preferably 3.

In General Formula (b1), L represents a single bond or a divalent linking group.

The divalent linking group represented by L is not particularly limited, and examples thereof include an aliphatic group which may be linear, branched, or cyclic, an aromatic ring group, —O—, —CO—, —COO—, —OCO—, and a group formed by combination of two or more of these groups.

As the aliphatic group, an alkylene group or a cycloalkylene group is preferable. The alkylene group may be linear or branched, and the number of carbon atoms is preferably 1 to 20 and more preferably 1 to 10. The cycloalkylene group may be monocyclic or polycyclic, and the number of carbon atoms is preferably 3 to 20 and more preferably 5 to 10.

The above-described aliphatic group may have a substituent, and examples of the substituent include groups exemplified by the above-described substituent K.

The above-described aliphatic group may have a heteroatom (for example, a sulfur atom, an oxygen atom, and a nitrogen atom) between carbon atoms.

The above-described aromatic ring group is preferably an arylene group (preferably having 6 to 20 carbon atoms and more preferably having 6 to 10 carbon atoms).

The above-described aromatic ring group may have a substituent, and examples of the substituent include the above-described substituent K.

The above-described aromatic ring group may have a heteroatom (for example, a sulfur atom, an oxygen atom, and a nitrogen atom) between carbon atoms.

L is preferably an arylene group.

In General Formula (b1), A represents a group which is decomposed by action of acid to generate a polar group.

The group which is decomposed by action of acid to generate a polar group (hereinafter, also referred to as “acid-decomposable group”) preferably has a structure in which the polar group is protected by a leaving group which is eliminated by action of acid.

Examples of the polar group include an acidic group, such as a carboxyl group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group; and an alcoholic hydroxyl group.

As the polar group, a carboxy group, a phenolic hydroxyl group, or an alcoholic hydroxyl group is preferable.

Examples of the leaving group which is eliminated by action of acid include groups described in the acid-decomposable resin later.

The acid-decomposable group is preferably at least one selected from the group consisting of a group represented by General Formula (T-1) and a group represented by General Formula (T-2), and more preferably the group represented by General Formula (T-1).

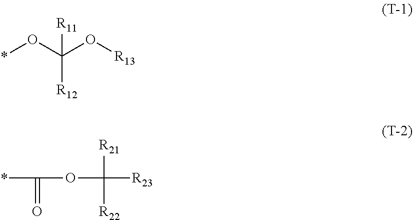

In General Formula (T-1), R₁ represents a hydrogen atom or an alkyl group.
R₁₂ represents a hydrogen atom, an alkyl group, a cycloalkyl group, or an aryl group, and the alkyl group and the cycloalkyl group may include an ether bond or a carbonyl bond.
R₁₃ represents an alkyl group, a cycloalkyl group, or an aryl group, and the alkyl group and the cycloalkyl group may include an ether bond or a carbonyl bond.
R₁₁ and R₁₂ may be bonded to each other to form a ring.
R₁₂ and R₁₃ may be bonded to each other to form a ring.
* represents a bonding site.

In General Formula (T-2), R₂₁, R₂₂, and R₂₃ each independently represent an alkyl group.

Two of R₂₁ to R₂₃ may be bonded to each other to form a ring.
* represents a bonding site.

In General Formula (T-1), R₁₁ represents a hydrogen atom or an alkyl group.

In a case where R₁₁ represents an alkyl group, the alkyl group may be linear or branched.

The number of carbon atoms in the alkyl group is preferably 1 to 10, more preferably 1 to 5, and still more preferably 1 to 3.

Examples of the alkyl group include a methyl group, an ethyl group, a propyl group, an n-butyl group, an sec-butyl group, a hexyl group, and an octyl group.

The above-described alkyl group may have a substituent, and examples of the substituent include groups exemplified by the above-described substituent K.

As R₁₁, a hydrogen atom or an alkyl group having 1 to 3 carbon atoms is preferable, and a hydrogen atom is more preferable.

In General Formula (T-1), R₁₂ represents a hydrogen atom, an alkyl group, a cycloalkyl group, or an aryl group.

In a case where R₁₂ represents an alkyl group, the alkyl group may be linear or branched.

The number of carbon atoms in the alkyl group is preferably 1 to 10, more preferably 1 to 5, and still more preferably 1 to 3.

Examples of the alkyl group include a methyl group, an ethyl group, a propyl group, an n-butyl group, an sec-butyl group, a hexyl group, and an octyl group.

The above-described alkyl group may have a substituent, and examples of the substituent include groups exemplified by the above-described substituent K.

The above-described alkyl group may include an ether bond or a carbonyl bond.

In a case where R₁₂ represents a cycloalkyl group, the cycloalkyl group may be monocyclic or polycyclic.

The number of carbon atoms in the cycloalkyl group is preferably 3 to 20, more preferably 5 to 15, and still more preferably 5 to 10.

Examples of the cycloalkyl group include a cyclopropyl group, a cyclobutyl group, a cyclopentyl group, a cyclohexyl group, a cyclooctyl group, an adamantyl group, a norbornyl group, an isobornyl group, a bornyl group, a dicyclopentyl group, an α-pinyl group, a tricyclodecanyl group, a tetracyclododecyl group, and an androstanyl group.

The above-described cycloalkyl group may have a substituent, and examples of the substituent include groups exemplified by the above-described substituent K.

The above-described cycloalkyl group may include an ether bond or a carbonyl bond.

In a case where R₁₂ represents an aryl group, the number of carbon atoms in the aryl group is preferably 6 to 20, more preferably 6 to 15, and still more preferably 6 to 10.

Examples of the aryl group include a phenyl group and a naphthyl group.

The above-described aryl group may have a substituent, and examples of the substituent include groups exemplified by the above-described substituent K.

As R₁₂, a hydrogen atom or an alkyl group having 1 to 5 carbon atoms is preferable.

In General Formula (T-1), R₁₃ represents an alkyl group, a cycloalkyl group, or an aryl group.

The alkyl group, cycloalkyl group, aryl group represented by R₁₃ are the same meanings as the alkyl group, cycloalkyl group, aryl group described as represented by R₁₂, respectively.

As R₁₃, an alkyl group having 1 to 5 carbon atoms is preferable.

R₁₁ and R₁₂ may be bonded to each other to form a ring.

The ring formed by bonding R₁₁ and R₁₂ to each other is preferably an aliphatic ring.

The aliphatic ring is preferably a cycloalkane having 3 to 20 carbon atoms, and more preferably a cycloalkane having 5 to 15 carbon atoms. The above-described cycloalkane may be monocyclic or polycyclic.

The above-described aliphatic ring may have a substituent, and examples of the substituent include groups exemplified by the above-described substituent K.

The above-described aliphatic ring may have a heteroatom (for example, a sulfur atom, an oxygen atom, and a nitrogen atom) between carbon atoms.

R₁₂ and R₁₃ may be bonded to each other to form a ring.

The ring formed by bonding R₁₂ and R₁₃ to each other is preferably an aliphatic ring including an oxygen atom as a ring member.

The aliphatic ring is preferably has 3 to 20 carbon atoms, and more preferably has 5 to 15 carbon atoms. The above-described aliphatic ring may be monocyclic or polycyclic.

The above-described aliphatic ring may have a substituent, and examples of the substituent include groups exemplified by the above-described substituent K.

The above-described aliphatic ring may have a heteroatom other than the oxygen atom (for example, a sulfur atom and a nitrogen atom) between carbon atoms.

An aspect in which, in General Formula (T-1), R₁₁ and R₁₂ are not bonded to each other and R₁₂ and R₁₃ are bonded to each other to form a ring is one preferred aspect of the present invention.

In General Formula (T-2), R₂₁, R₂₂, and R₂₃ each independently represent an alkyl group.

In a case where R₂₁, R₂₂, and R₂₃ represent an alkyl group, the alkyl group is not particularly limited, and may be linear or branched.

Examples of the above-described alkyl group include a methyl group, an ethyl group, an n-propyl group, an isopropyl group, an n-butyl group, an isobutyl group, and a t-butyl group, and an alkyl group having 1 to 4 carbon atoms is preferable.

The above-described alkyl group may further have a substituent. Examples of the substituent include an aryl group (for example, having 6 to 15 carbon atoms), a halogen atom, a hydroxyl group, an alkoxy group (for example, having 1 to 4 carbon atoms), a carboxy group, and an alkoxycarbonyl group (for example, having 2 to 6 carbon atoms). The number of carbon atoms in the substituent is preferably 8 or less.

Two of R₂₁ to R₂₃ may be bonded to each other to form a ring.

In a case where two of R₂₁ to R₂₃ are bonded to each other to form a ring, it is preferable to form a cycloalkyl group. The cycloalkyl group may be monocyclic or polycyclic. Examples of the monocyclic cycloalkyl group include a cyclopentyl group and a cyclohexyl group. Examples of the polycyclic cycloalkyl group include a norbornyl group, a tetracyclodecanyl group, a tetracyclododecanyl group, and an adamantyl group. Among these, a monocyclic cycloalkyl group having 5 or 6 carbon atoms is preferable.

In the above-described cycloalkyl group, for example, one of methylene groups constituting the ring may be replaced with a heteroatom such as an oxygen atom or a group having a heteroatom, such as a carbonyl group.

The organic anion may be an anion represented by General Formula (b2).

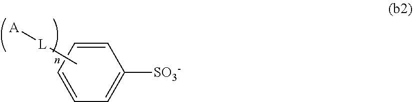

In General Formula (b2), L represents a single bond or a divalent linking group. In a case of a plurality of L's, the plurality of L's may be the same or different from each other. A represents a group which is decomposed by action of acid to generate a polar group. In a case of a plurality of A's, the plurality of A's may be the same or different from each other. n represents an integer of 1 to 5.

L, A, and n in General Formula (b2) are the same as L, A, and n in General Formula (b1) described above, respectively.

The organic anion may be an anion represented by General Formula (b3).

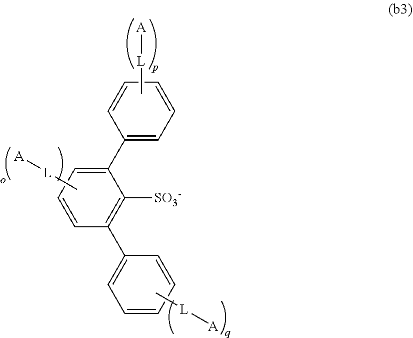

In General Formula (b3), L represents a single bond or a divalent linking group. In a case of a plurality of L's, the plurality of L's may be the same or different from each other. A represents a group which is decomposed by action of acid to generate a polar group. In a case of a plurality of A's, the plurality of A's may be the same or different from each other. o, p, and q each independently represent an integer of 0 to 5. However, the sum of o, p, and q is an integer of 1 to 5.

L and A in General Formula (b3) are the same as L and A in General Formula (b1) described above, respectively.

o, p, and q in General Formula (b3) each independently preferably represent an integer of 0 to 3, more preferably represent an integer of 0 to 2, and still more preferably represent 0 or 1.

Specific examples of the anionic moiety of the salt B are shown below, but the present invention is not limited thereto. Me represents a methyl group, and Et represents an ethyl group.

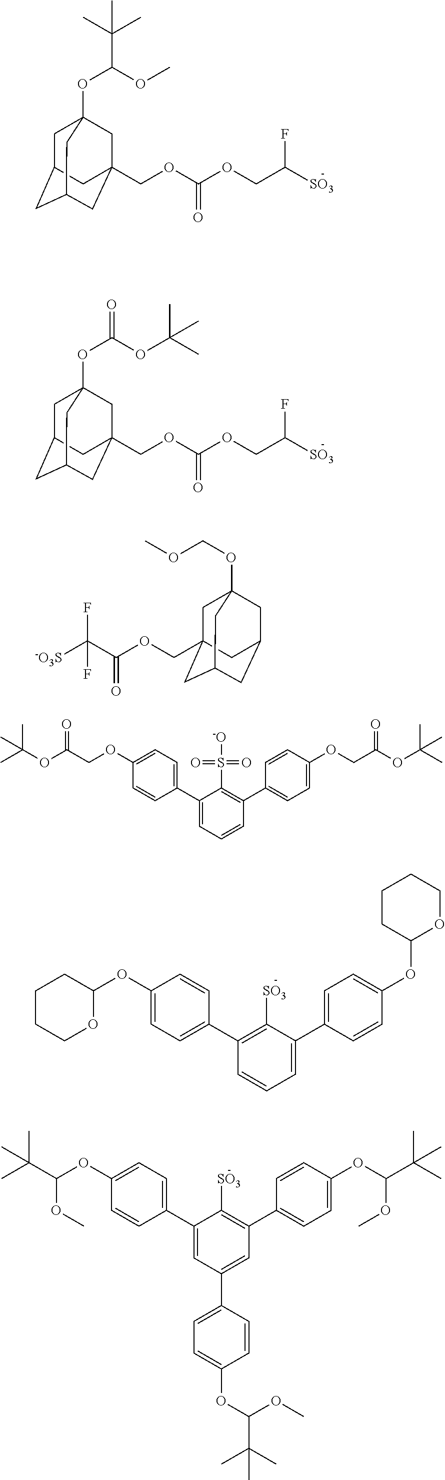

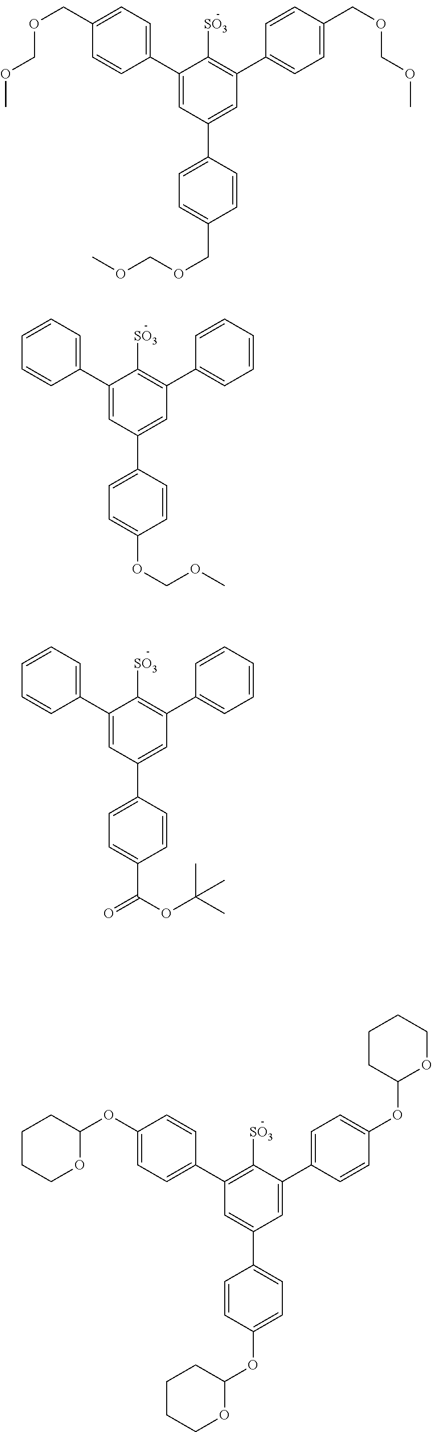

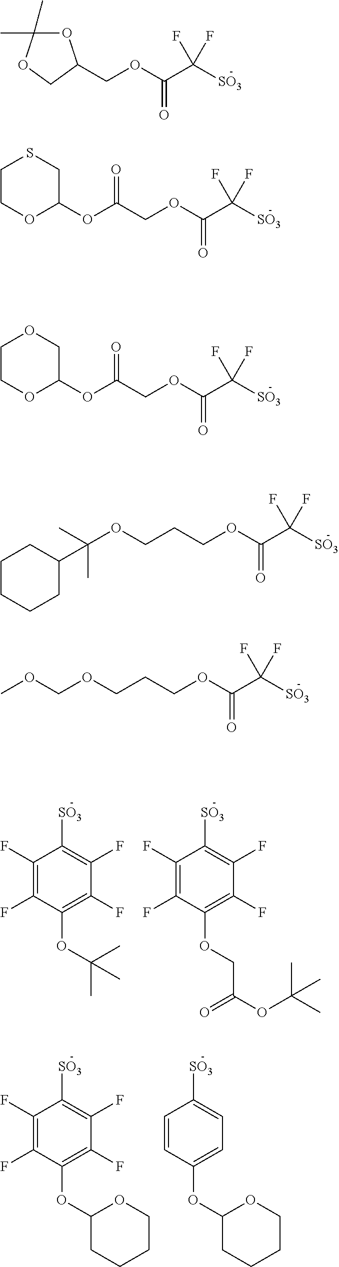

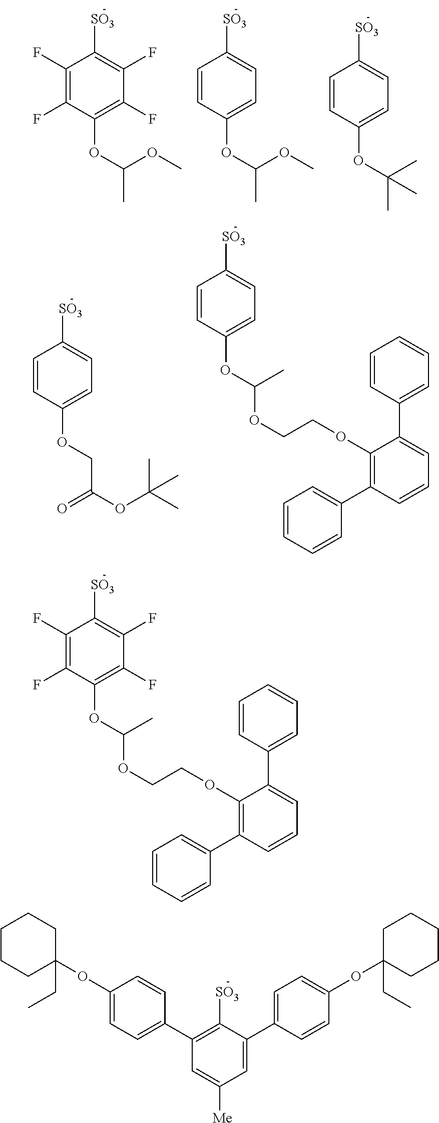

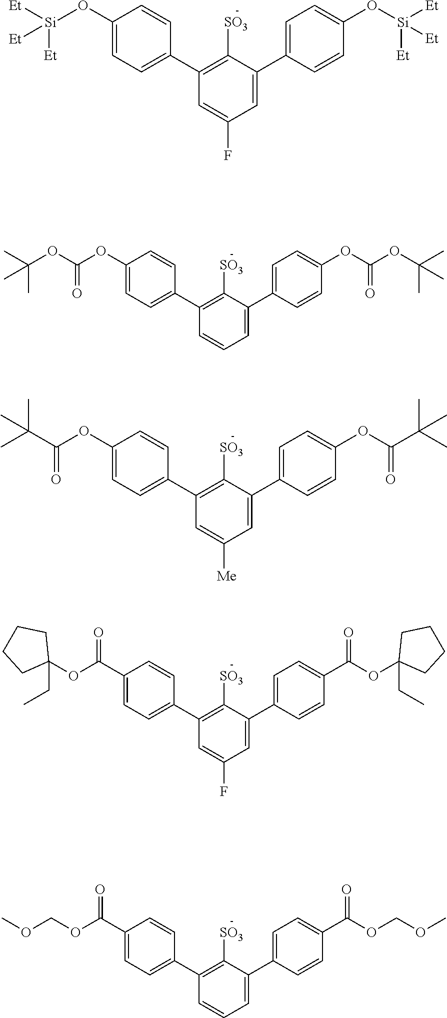

A pKa of the acid generated from the salt B is preferably −10 to 5.

In a case where the requirement 1 is satisfied and the requirement 2 is not satisfied, that is, in a case where the resist composition contains the salt B and the specific group is not included in the acid-decomposable resin, a content of the salt B in the resist composition is not particularly limited, but is preferably 1.0% to 30.0% by mass and more preferably 5.0% to 20.0% by mass with respect to the total solid content of the resist composition.

In a case where the requirement 1 and the requirement 2 are satisfied, a content of the salt B in the resist composition is not particularly limited, but is preferably 0.5% to 10.0% by mass and more preferably 1.0% to 5.0% by mass with respect to the total solid content of the resist composition.

In a case where the requirement 2 is satisfied, the content of the salt B means the content of the specific group portion.

In addition, the salt B may be used alone or in combination of two or more kinds thereof. In a case where two or more kinds thereof are used, a total content thereof is preferably within the suitable content range.

[Acid-Decomposable Resin]

The resist composition contains an acid-decomposable resin.

The acid-decomposable resin preferably has a repeating unit including a group which is decomposed by action of acid to generate a polar group.

The acid-decomposable resin further includes “repeating unit A2” described later.

In addition, since the resist composition satisfies at least one of the requirement 1 or the requirement 2, in a case where the resist composition does not contain the salt B, the acid-decomposable resin has the specific group, and in a case where the resist composition contains the salt B, the acid-decomposable resin may or may not have the specific group.

In the pattern forming method according to the embodiment of the present invention, in a case where an alkali developer is adopted as a developer, a positive tone pattern is suitably formed, and in a case where an organic developer is adopted as a developer, a negative tone pattern is suitably formed.

(Repeating Unit Having Acid-Decomposable Group)

The acid-decomposable group preferably has a structure in which a polar group is protected by a leaving group which is eliminated by action of acid. That is, the acid-decomposable resin preferably has a repeating unit having a group which is decomposed by action of acid to generate a polar group. The resin having this repeating unit has an increased polarity by action of acid, an increased solubility in an alkali developer, and a decreased solubility in an organic solvent.

As the polar group, an alkali-soluble group is preferable, and examples thereof include an acidic group, such as a carboxyl group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group; and an alcoholic hydroxyl group.

Among these, as the polar group, a carboxyl group, a phenolic hydroxyl group, a fluorinated alcohol group (preferably, a hexafluoroisopropanol group), or a sulfonic acid group is preferable.

Examples of the leaving group which is eliminated by action of acid include groups represented by General Formulae (Y1) to (Y4).

—C(Rx₁)(Rx₂)(Rx₃) General Formula (Y1):

—C(═O)OC(Rx₁)(Rx₂)(Rx₃) General Formula (Y2):

—C(R₃₆)(R₃₇)(OR₃₈) General Formula (Y3):

—C(Rn)(H)(Ar) General Formula (Y4):

In General Formula (Y1) and General Formula (Y2), Rx₁ to Rx₃ each independently represent a (linear or branched) alkyl group, a (monocyclic or polycyclic) cycloalkyl group, an (linear or branched) alkenyl group, or a (monocyclic or polycyclic) aryl group. In a case where all of Rx₁ to Rx₃ are (linear or branched) alkyl groups, it is preferable that at least two of Rx₁ to Rx₃ are methyl groups.

Among these, it is preferable that Rx₁ to Rx₃ each independently represent a linear or branched alkyl group, and it is more preferable that Rx₁ to Rx₃ each independently represent a linear alkyl group.

Two of Rx₁ to Rx₃ may be bonded to each other to form a monocycle or a polycycle.

As the alkyl group of Rx₁ to Rx₃, an alkyl group having 1 to 5 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group of Rx₁ to Rx₃, an aryl group having 6 to 10 carbon atoms is preferable, and examples thereof include a phenyl group, a naphthyl group, and an anthryl group.

As the alkenyl group of Rx₁ to Rx₃, a vinyl group is preferable.

A cycloalkane ring is preferable as the ring formed by the bonding of two of Rx₁ to Rx₃. As the cycloalkane ring formed by the bonding of two of Rx₁ to Rx₃, a monocyclic cycloalkane ring such as cyclopentane and cyclohexane, or a polycyclic cycloalkane ring such as norbornane, tetracyclodecane, a tetracyclododecane group, and adamantane is preferable, and a monocyclic cycloalkane ring having 5 or 6 carbon atoms is more preferable.

In the cycloalkane ring formed by the bonding of two of Rx₁ to Rx₃, for example, one of methylene groups constituting the ring may be replaced with a heteroatom such as an oxygen atom, with a group including a heteroatom, such as a carbonyl group, or with a vinylidene group. In addition, in the cycloalkane ring, one or more of the ethylene groups constituting the cycloalkane ring may be replaced with a vinylene group.

With regard to the group represented by General Formula (Y1) or General Formula (Y2), for example, an aspect in which Rx₁ is a methyl group or an ethyl group and Rx₂ and Rx₃ are bonded to each other to form the above-described cycloalkane ring is preferable.

For example, in a case where the resist composition is a resist composition for EUV exposure, it is also preferable that the alkyl group, cycloalkyl group, alkenyl group, and aryl group represented by Rx₁ to Rx₃ and the ring formed by bonding two of Rx₁ to Rx₃ further have a fluorine atom or an iodine atom as a substituent.

In General Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

The alkyl group, the cycloalkyl group, the aryl group, and the aralkyl group may include at least one of a heteroatom such as an oxygen atom or a group including a heteroatom, such as a carbonyl group. For example, in the above-described alkyl group, cycloalkyl group, aryl group, and aralkyl group, one or more of methylene groups may be replaced with at least one of a heteroatom such as an oxygen atom or a group including a heteroatom, such as a carbonyl group.

In addition, R₃₈ and another substituent included in the main chain of the repeating unit may be bonded to each other to form a ring. A group formed by the mutual bonding of R₃₈ and another substituent on the main chain of the repeating unit is preferably an alkylene group such as a methylene group.

For example, in a case where the resist composition is a resist composition for EUV exposure, it is also preferable that the monovalent organic group represented by R₃₆ to R₃₈ and the ring formed by bonding R₃₇ and R₃₈ with each other further have a fluorine atom or an iodine atom as a substituent.

In General Formula (Y4), Ar represents an aromatic ring group. Rn represents an alkyl group, a cycloalkyl group, or an aryl group. Rn and Ar may be bonded to each other to form a non-aromatic ring. Ar is preferably an aryl group.

For example, in a case where the resist composition is a resist composition for EUV exposure, it is also preferable that the aromatic ring group represented by Ar and the alkyl group, cycloalkyl group, and aryl group represented by Rn further have a fluorine atom or an iodine atom as a substituent.

The acid-decomposable resin preferably includes at least one selected from the group consisting of repeating units represented by General Formulae (3) to (7), and from the viewpoint that the effect of the present invention is more excellent, more preferably includes at least one selected from the group consisting of a repeating unit represented by General Formula (6) and a repeating unit represented by General Formula (7).

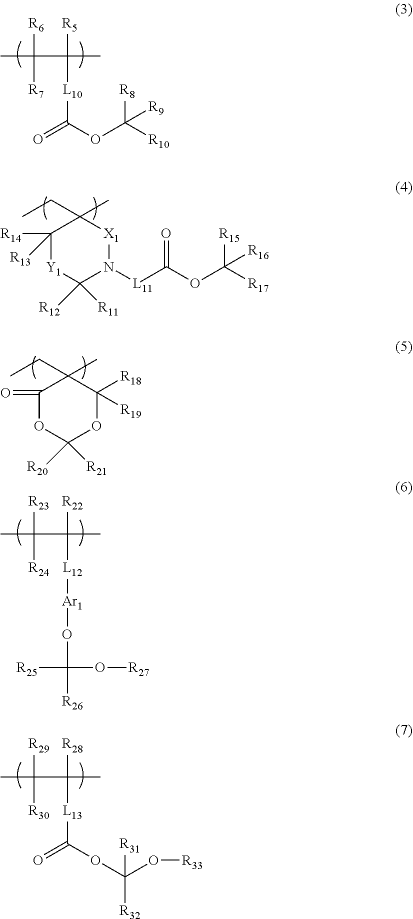

In General Formula (3), R₅ to R₇ each independently represent a hydrogen atom, an alkyl group, a cycloalkyl group, a halogen atom, a cyano group, or an alkoxycarbonyl group. L₁₀ represents a single bond or a divalent linking group. R₈ to R₁₀ each independently represent an alkyl group, a cycloalkyl group, an aryl group, an aralkyl group, or an alkenyl group.

R₅ to R₇ each independently represent a hydrogen atom, an alkyl group, a cycloalkyl group, a halogen atom, a cyano group, or an alkoxycarbonyl group.

The above-described alkyl group may be linear or branched. The number of carbon atoms in the above-described alkyl group is preferably 1 to 6.

The above-described cycloalkyl group may be monocyclic or polycyclic. The number of carbon atoms in the above-described cycloalkyl group is preferably 3 to 15.

Examples of the halogen atom include a fluorine atom, a chlorine atom, a bromine atom, and an iodine atom.

The number of carbon atoms in the above-described alkoxycarbonyl group is preferably 1 to 10. Examples of an alkyl group moiety in the above-described alkoxycarbonyl group include the same group as those in the above-described alkyl group.

As R₅, a hydrogen atom or an alkyl group is preferable, an alkyl group is more preferable, and a methyl group is still more preferable.

As R₆ and R₇, a hydrogen atom or an alkyl group is preferable, and a hydrogen atom is more preferable.

L₁₀ represents a single bond or a divalent linking group.

Examples of the divalent linking group include —CO—, —O—, —S, —SO—, —SO₂—, —NR^{N}—, a hydrocarbon group (for example, an alkylene group, a cycloalkylene group, an alkenylene group, an arylene group, and the like), and a group formed by a combination of these groups. R^{N} represents, for example, a substituent X described below. As L₁₀, a single bond or an alkylene group is preferable.

The above-described substituent X is not particularly limited, and examples thereof include a hydroxyl group, a thiol group, an amino group, a sulfonic acid group, an organic group, and a group formed by a combination of these groups. Among these, an organic group is preferable, and an alkyl group, an alkoxy group, an alkoxycarbonyl group, an alkenyl group, a cyano group, a cycloalkyl group, or an aromatic ring group is more preferable.

The above-described alkyl group may be linear or branched.

The number of carbon atoms in the above-described alkyl group is preferably 1 to 5.

Examples of the above-described alkyl group include a methyl group, an ethyl group, an n-propyl group, an isopropyl group, an n-butyl group, an isobutyl group, and a t-butyl group.

Examples of an alkyl group moiety in the above-descried alkoxy group and the above-described alkoxycarbonyl group include the same groups as those in the above-described alkyl group.

The above-described alkenyl group may be linear or branched.

The number of carbon atoms in the above-described alkenyl group is preferably 1 to 5.

Examples of the above-described alkenyl group include a vinyl group.

The number of ring member atoms in the above-described cycloalkyl group is preferably 3 to 15.

As the above-described cycloalkyl group, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a polycyclic cycloalkyl group is more preferable.

In the above-described cycloalkyl group, one or more (for example, one to three) of methylene groups constituting the ring may be replaced with a heteroatom (for example, —O—, —S—, and the like), —SO₂—, —SO₃—, an alkoxycarbonyl group, a carbonyl group, or a vinylidene group. In addition, in the above-described cycloalkyl group, one or more (for example, one or two) of ethylene groups constituting the cycloalkane ring may be replaced with a vinylene group.

The above-described aromatic ring group may be monocyclic or polycyclic.

The number of ring member atoms in the above-described aromatic ring group is preferably 5 to 15.

The above-described aromatic ring group may have one or more (for example, one to five) heteroatoms (for example, one or more atoms selected from the group consisting of an oxygen atom, a sulfur atom, a nitrogen atom, and the like) as the ring member atom.

Examples of the above-described aromatic ring group include aryl groups such as a benzene ring group, a naphthalene ring group, and an anthracene ring group, and thiazole ring groups such as a benzothiazole ring group.

The alkyl group, the alkoxy group, the alkoxycarbonyl group, the alkenyl group, the cycloalkyl group, and the aromatic ring group described above may further have a substituent Y.

Examples of the above-described substituent Y include a halogen atom (for example, a fluorine atom and the like), a hydroxyl group, a nitro group, a cyano group, a cycloalkyl group, and an aromatic ring group. Specifically, the above-described alkyl group may have a fluorine atom as the substituent and may be a perfluoroalkyl group. Examples of the cycloalkyl group and the aromatic ring group as the substituent X include the cycloalkyl group and the aromatic ring group described above as a form which the organic group can take.

As described above, the alkyl group, the alkoxy group, the alkoxycarbonyl group, the alkenyl group, the cycloalkyl group, and the aromatic ring group described above may further have a substituent, and this substituent may further have a substituent (hereinafter, also referred to as “substituent Z”). For example, the cycloalkyl group and the aromatic ring group described above may further have a substituent.

Examples of the above-described substituent Z include a halogen atom, a hydroxyl group, a nitro group, a cyano group, an alkyl group, an alkoxy group, an alkoxycarbonyl group, and an alkenyl group. Examples of the alkyl group, the alkoxy group, the alkoxycarbonyl group, and the alkenyl group as the substituent Z include the above-described alkyl group, the above-described alkoxy group, the above-described alkoxycarbonyl group, and the above-described alkenyl group, which can be adopted as the substituent X. The alkyl group, the alkoxy group, the alkoxycarbonyl group, and the alkenyl group as the substituent Z may further have the above-described substituent. The above-described hydrocarbon group may further have a substituent, and preferably has a halogen atom as the substituent.

R₈ to R₁₀ each independently represent an alkyl group, a cycloalkyl group, an aryl group, an aralkyl group, or an alkenyl group.

The above-described alkyl group may be linear or branched. The number of carbon atoms in the above-described alkyl group is preferably 1 to 6 and more preferably 1 to 3.

The above-described cycloalkyl group may be monocyclic or polycyclic. The number of carbon atoms in the above-described cycloalkyl group is preferably 3 to 15.

The above-described aryl group may be monocyclic or polycyclic. The number of carbon atoms in the above-described aryl group is preferably 6 to 15.

The number of carbon atoms in the above-described aralkyl group is preferably 7 to 18.

The above-described alkenyl group may be linear or branched. The number of carbon atoms in the above-described alkenyl group is preferably 2 to 6.

The alkyl group, cycloalkyl group, aryl group, aralkyl group, and alkenyl group described above may further have a substituent, and preferably have a halogen atom (preferably a fluorine atom) as the substituent.

As R₈ to R₁₀, an alkyl group or an aryl group is preferable, and an alkyl group is more preferable.

At least two of R₈ to R₁₀ may be bonded to each other to form a ring.

In General Formula (4), R₁₁ to R₁₄ each independently represent a hydrogen atom or an organic group. However, at least one of R₁₁ or R₁₂ represents an organic group. X₁ represents —CO—, —SO—, or —SO₂—. Y₁ represents —O—, —S—, —SO—, —SO₂—, or —NR₃₄—. R₃₄ represents a hydrogen atom or an organic group. L₁₁ represents a single bond or a divalent linking group. R₁₅ to R₁₇ each independently represent an alkyl group, a cycloalkyl group, an aryl group, an aralkyl group, or an alkenyl group.

R₁₁ to R₁₄ each independently represent a hydrogen atom or an organic group. However, at least one of R₁₁ or R₁₂ represents an organic group.

Examples of the above-described organic group include the organic groups exemplified by the substituent X in General Formula (3).

Among these, as the organic group, a (linear or branched) alkyl group (preferably having 1 to 6 carbon atoms), a (monocyclic or polycyclic) cycloalkyl group (preferably having 3 to 15 carbon atoms), a (monocyclic or polycyclic) aryl group (preferably having 6 to 15 carbon atoms), an aralkyl group (preferably having 7 to 18 carbon atoms), or a (linear or branched) alkenyl group (preferably having 2 to 6 carbon atoms) is preferable.

As R₁₁ and R₁₂, an alkyl group is preferable, and an alkyl group having a fluorine atom is more preferable.

As R₁₃ and R₁₄, a hydrogen atom or an alkyl group is preferable, and a hydrogen atom is more preferable.

X₁ represents —CO—, —SO—, or —SO₂—. As X₁, —CO— is preferable.

Y₁ represents —O—, —S—, —SO—, —SO₂—, or —NR₃₄—. As Y₁, —O— or —S— is preferable, and —O— is more preferable.

R₃₄ represents a hydrogen atom or an organic group. As R₃₄, an organic group (for example, an alkyl group) is preferable.

L₁₁ represents a single bond or a divalent linking group.

Examples of the above-described divalent linking group include —CO—, —O—, —S, —SO—, —SO₂—, —NR^{N}—, a hydrocarbon group (for example, an alkylene group, a cycloalkylene group, an alkenylene group, an arylene group, and the like), and a group formed by a combination of these groups. R_{N} represents the above-described substituent X. The above-described hydrocarbon group may further have a substituent, and preferably has a halogen atom as the substituent.

As L₁₁, a hydrocarbon group is preferable, and an alkylene group is more preferable.

R₁₅ to R₁₇ each independently represent an alkyl group, a cycloalkyl group, an aryl group, an aralkyl group, or an alkenyl group.

The above-described alkyl group may be linear or branched. The number of carbon atoms in the above-described alkyl group is preferably 1 to 6.

The above-described cycloalkyl group may be monocyclic or polycyclic. The number of carbon atoms in the above-described cycloalkyl group is preferably 3 to 15.

The above-described aryl group may be monocyclic or polycyclic. The number of carbon atoms in the above-described aryl group is preferably 6 to 15.

The number of carbon atoms in the above-described aralkyl group is preferably 7 to 18.

The above-described alkenyl group may be linear or branched. The number of carbon atoms in the above-described alkenyl group is preferably 2 to 6.

The alkyl group, cycloalkyl group, aryl group, aralkyl group, and alkenyl group described above may further have a substituent, and preferably have a halogen atom (preferably a fluorine atom) as the substituent.

As R₁₅ to R₁₇, an alkyl group or an aryl group is preferable.

At least two of R₁₅ to R₁₇ may be bonded to each other to form a ring.

In General Formula (5), R₁₈ and R₁₉ each independently represent a hydrogen atom or an organic group. R₂₀ and R₂₁ each independently represent a hydrogen atom, an alkyl group, a cycloalkyl group, an aryl group, an aralkyl group, or an alkenyl group.

Examples of the above-described organic group include the organic group (for example, an alkyl group and the like) exemplified by the substituent represented by R₈ to R₁₀ in General Formula (3).

As R₁₈ and R₁₉, a hydrogen atom or an alkyl group is preferable, and a hydrogen atom is more preferable.

Examples of R₂₀ and R₂₁ include R₁₅ to R₁₇ in General Formula (4), and a hydrogen atom or an alkyl group is preferable.

At least two of R₁₈ to R₂₁ may be bonded to each other to form a ring. Among these, it is preferable that R₁₈ and R₁₉, and R₂₀ and R₂₁ are bonded to each other to form a ring.

In General Formula (6), R₂₂ to R₂₄ each independently represent a hydrogen atom, an alkyl group, a cycloalkyl group, a halogen atom, a cyano group, or an alkoxycarbonyl group. L₁₂ represents a single bond or a divalent linking group. Ar₁ represents an aromatic ring group. R₂₅ to R₂₇ each independently represent a hydrogen atom, an alkyl group, a cycloalkyl group, an aryl group, an aralkyl group, or an alkenyl group.

R₂₂ to R₂₄ each independently represent a hydrogen atom, an alkyl group, a cycloalkyl group, a halogen atom, a cyano group, or an alkoxycarbonyl group.

The above-described alkyl group may be linear or branched. The number of carbon atoms in the above-described alkyl group is preferably 1 to 6 and more preferably 1 to 3.

The above-described cycloalkyl group may be monocyclic or polycyclic. The number of carbon atoms in the above-described cycloalkyl group is preferably 3 to 15.

Examples of the halogen atom include a fluorine atom, a chlorine atom, a bromine atom, and an iodine atom.

The number of carbon atoms in the above-described alkoxycarbonyl group is preferably 1 to 10. Examples of an alkyl group moiety in the above-described alkoxycarbonyl group include the same group as those in the above-described alkyl group.

As R₂₂ to R₂₄, a hydrogen atom or an alkyl group is preferable, and a hydrogen atom is more preferable.

L₁₂ represents a single bond or a divalent linking group.

Examples of the divalent linking group represented by L₁₂ include groups exemplified by L₁₁ in General Formula (4), L₁₂ is preferably a single bond.

Ar₁ represents an aromatic ring group.

The above-described aromatic ring group may be monocyclic or polycyclic.

The number of ring member atoms in the above-described aromatic ring group is preferably 5 to 15. The above-described aromatic ring group may have one or more (for example, one to five) heteroatoms (for example, one or more atoms selected from the group consisting of an oxygen atom, a sulfur atom, a nitrogen atom, and the like) as the ring member atom. As the above-described aromatic ring group, a benzene ring group is preferable.

R₂₅ to R₂₇ each independently represent a hydrogen atom, an alkyl group, a cycloalkyl group, an aryl group, an aralkyl group, or an alkenyl group.

Examples of the group represented by R₂₅ to R₂₇ include the group represented by R₁₅ to R₁₇ in General Formula (4).

As R₂₅ to R₂₇, a hydrogen atom or an alkyl group is preferable.

At least two of R₂₅ to R₂₇ may be bonded to each other to form a ring. Among these, it is preferable that R₂₆ and R₂₇ are bonded to each other to form a ring. In addition, Ar₁ may be bonded to R₂₄ or R₂₅ to form a ring.

In General Formula (7), R₂₈ to R₃₀ each independently represent a hydrogen atom, an alkyl group, a cycloalkyl group, a halogen atom, a cyano group, or an alkoxycarbonyl group. L₁₃ represents a single bond or a divalent linking group. R₃₁ and R₃₂ each independently represent a hydrogen atom, an alkyl group, a cycloalkyl group, an aryl group, an aralkyl group, or an alkenyl group. R₃₃ represents an alkyl group, a cycloalkyl group, an aryl group, an aralkyl group, or an alkenyl group.

R₂₈ to R₃₀ have the same meanings as R₂₂ to R₂₄ in General Formula (6), and suitable aspects thereof are also the same.

L₁₃ has the same meaning as L₁₂ in General Formula (6), and a suitable aspect thereof is also the same.

R₃₃ has the same meaning as R₁₅ to R₁₇ in General Formula (4), and a suitable aspect thereof is also the same.

At least two of R₃₁ to R₃₃ may be bonded to each other to form a ring. Among these, it is preferable that R₃₂ and R₃₃ are bonded to each other to form a ring.

With respect to all repeating units in the acid-decomposable resin, a content of the repeating unit having an acid-decomposable group is preferably 1% by mole or more, more preferably 10% by mole or more, and from the viewpoint that the LWR is more excellent, it is still more preferably 15% by mole or more. The upper limit thereof is preferably 90% by mole or less, more preferably 70% by mole or less, and still more preferably 60% by mole or less with respect to all repeating units.

The repeating unit having an acid-decomposable group may be used alone or in combination of two or more kinds thereof. In a case where two or more kinds thereof are used, a total content thereof is preferably within the suitable content range.

(Repeating Unit Having Specific Group)

In a case where the resist composition does not satisfy the requirement 1, the acid-decomposable resin has the specific group. In a case where the resist composition satisfies the requirement 1, the acid-decomposable resin may or may have the specific group.

In a case where the acid-decomposable resin includes the specific group, the acid-decomposable resin includes a repeating unit having the specific group (hereinafter, also referred to as “repeating unit a”).

The specific group may be directly bonded to a main chain of the repeating unit a, or the specific group may form a part of the main chain of the repeating unit a.

The specific group is a residue formed by removing one hydrogen atom in the above-described salt B.

In a case forming the specific group, a hydrogen atom to be removed from the salt B is not particularly limited, but it is preferable that the specific group is formed by removing a hydrogen atom from Z⁻ in General Formula (1) or (2) described above. For example, it is preferable that the residue is formed by removing a hydrogen atom from W in General Formula (AN) described above or A in General Formulae (b1) to (b3) described above.

In addition, the specific group is preferably a group represented by General Formula (Tx).

*-L_{T}-A⁻C⁺ General Formula (Tx)

In General Formula (Tx), * represents a bonding position. L_{T} represents a single bond or a divalent linking group.

The divalent linking group is not particularly limited, and examples thereof include an aliphatic group which may be linear, branched, or cyclic, an aromatic ring group, —O—, —CO—, —COO—, —OCO—, and a group formed by combination of two or more of these groups.

As the aliphatic group, an alkylene group or a cycloalkylene group is preferable. The alkylene group may be linear or branched, and the number of carbon atoms is preferably 1 to 20 and more preferably 1 to 10. The cycloalkylene group may be monocyclic or polycyclic, and the number of carbon atoms is preferably 3 to 20 and more preferably 5 to 10.

The above-described aliphatic group may have a substituent, and examples of the substituent include groups exemplified by the above-described substituent K.

The above-described aliphatic group may have a heteroatom (for example, a sulfur atom, an oxygen atom, and a nitrogen atom) between carbon atoms.

A⁻ represents —SO₃⁻ or —COO⁻.

C⁺ represents a cation represented by General Formula (Ty), and is preferably a cation represented by General Formula (Tz).

The definition of each group in General Formula (Ty) and General Formula (Tz) is the same as the definition of each group in General Formula (1) and General Formula (2).

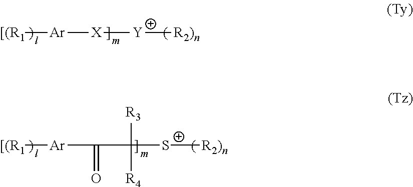

As the repeating unit having a specific group, a repeating unit represented by Formula (a) is preferable.

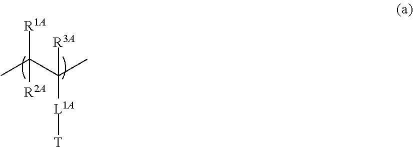

In General Formula (a), R^{1A} to R^{3A} each independently represent a hydrogen atom or a substituent. L^{1A} represents a single bond or a divalent linking group. T represents the specific group.

R^{1A} to R^{3A} each independently represent a hydrogen atom or a substituent.

R^{1A} to R^{3A} are each independently preferably a hydrogen atom, an alkyl group, a cycloalkyl group, a halogen atom, a cyano group, or an alkoxycarbonyl group; more preferably a hydrogen atom, a halogen atom, or an alkyl group; and still more preferably a hydrogen atom or a methyl group.

L^{A1} represents a single bond or a divalent linking group.

Examples of the above-described divalent linking group include —CO—, —O—, —S, —SO—, —SO₂—, —NR^{N}—, a hydrocarbon group (for example, an alkylene group, a cycloalkylene group, an alkenylene group, an arylene group, and the like), and a group formed by a combination of these groups. R_{N} represents a substituent (for example, the above-described substituent X). The above-described hydrocarbon group may further have a substituent, and preferably has a halogen atom (preferably a fluorine atom) as the substituent.

The above-described alkylene group may be linear or branched.

The number of carbon atoms in the above-described alkylene group is preferably 1 to 4.

The above-described cycloalkylene group may be monocyclic or polycyclic.

The number of carbon atoms in the above-described cycloalkylene group is preferably 3 to 15.

One or more (for example, one or two) of —CH₂-'s constituting a ring structure of the above-described cycloalkylene group may be replaced with a heteroatom (for example, —O—, —S—, and the like), —SO₂—, —SO₃—, an alkoxycarbonyl group, or a carbonyl group.

T represents the specific group.

The specific group is as described above.

It is more preferable that the acid-decomposable resin has at least one selected from the group consisting of repeating units represented by General Formulae (aa) to (ac).

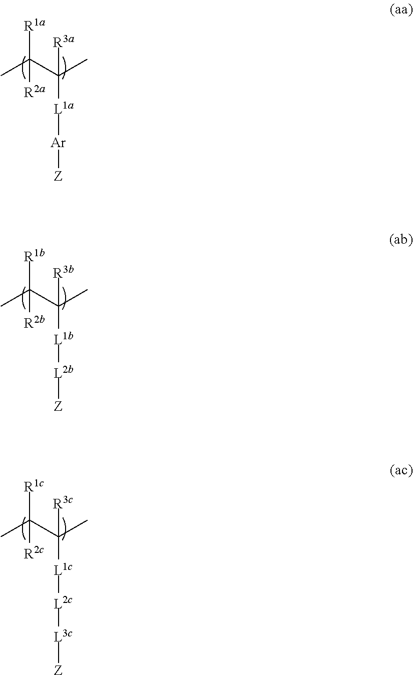

In General Formula (aa), R^{1a} to R^{3a} each independently represent a hydrogen atom or a substituent. L^{1a} represents a single bond, an alkylene group, —COO—, an aromatic ring group, or a group formed by a combination of these groups. Ar represents an aromatic ring group. Z represents the specific group.

R^{1a} to R^{3a} each independently represent a hydrogen atom or a substituent.

R^{1a} to R^{3a} are each independently preferably a hydrogen atom, an alkyl group, a cycloalkyl group, a halogen atom, a cyano group, or an alkoxycarbonyl group; more preferably a hydrogen atom, a halogen atom, or an alkyl group; and still more preferably a hydrogen atom or a methyl group.

L^{1a} represents a single bond, an alkylene group, —COO—, an aromatic ring group, or a group formed by a combination of these groups.

The above-described alkylene group may be linear or branched.

The number of carbon atoms in the above-described alkylene group is preferably 1 to 4.

The above-described aromatic ring group may be monocyclic or polycyclic.

The number of ring member atoms in the above-described aromatic ring group is preferably 5 to 15. The above-described aromatic ring group may have one or more (for example, one to five) heteroatoms (for example, at least one atom selected from the group consisting of an oxygen atom, a sulfur atom, a nitrogen atom, and the like) as the ring member atom. As the above-described aromatic ring group, a benzene ring group is preferable.

Examples of the combined group described above include —COO-alkylene group and —COO-aromatic ring group-.

The alkylene group and aromatic ring group described above may further have a substituent.

Examples of the above-described substituent include the above-described substituent X.

As L^{1a}, a single bond or an alkylene group is preferable, and a single bond is more preferable.

Ar represents an aromatic ring group.

The above-described aromatic ring group may be monocyclic or polycyclic.

The number of ring member atoms in the above-described aromatic ring group is preferably 5 to 15.

The above-described aromatic ring group may have one or more (for example, one to five) heteroatoms (for example, at least one atom selected from the group consisting of an oxygen atom, a sulfur atom, a nitrogen atom, and the like) as the ring member atom.

The above-described aromatic ring group may further have a substituent.

Examples of the above-described substituent include the above-described substituent X.

In addition, examples of the above-described substituent also include T described above.

As the above-described aromatic ring group, an arylene group such as a phenylene group and a naphthylene group is preferable, and a phenylene group is more preferable.

In General Formula (ab), R^{1b} to R^{3b} each independently represent a hydrogen atom or a substituent. L^{1b} represents a single bond, an alkylene group, —COO—, or a group formed by a combination of these groups. L^{2b} represents a single bond or an alkylene group. Z represents the specific group.

R^{1b} to R^{3b} each independently represent a hydrogen atom or a substituent.

R^{1b} to R^{3b} are each independently preferably a hydrogen atom, an alkyl group, a cycloalkyl group, a halogen atom, a cyano group, or an alkoxycarbonyl group; more preferably a hydrogen atom, a halogen atom, or an alkyl group; and still more preferably a hydrogen atom or a methyl group.

L^{1b} represents a single bond, an alkylene group, —COO—, or a group formed by a combination of these groups.

The above-described alkylene group may be linear or branched.

The number of carbon atoms in the above-described alkylene group is preferably 1 to 4.

Examples of the combined group described above include —COO-alkylene group.

The above-described alkylene group may further have a substituent.

Examples of the above-described substituent include the above-described substituent X.

As L^{1b}, a single bond or an alkylene group is preferable, and a single bond is more preferable.

L^{2b} represents a single bond or an alkylene group.

Examples of the above-described alkylene group include the alkylene group which can be adopted as L^{1A} in General Formula (a). In addition, examples of the above-described substituent also include T described above.

As L^{2b}, an alkylene group is preferable.

In General Formula (ac), R^{1c} to R^{3c} each independently represent a hydrogen atom or a substituent. L^{1c} represents a single bond, an alkylene group, —COO—, an aromatic ring group, or a group formed by a combination of these groups. L²c represents a cycloalkylene group. L^{3c} represents a single bond or a divalent linking group. Z represents the specific group.

R^{1c} to R^{3c} each independently represent a hydrogen atom or a substituent.

R^{1c} to R^{3c} are each independently preferably a hydrogen atom, an alkyl group, a cycloalkyl group, a halogen atom, a cyano group, or an alkoxycarbonyl group; more preferably a hydrogen atom, a halogen atom, or an alkyl group; and still more preferably a hydrogen atom or a methyl group.

L^{1c} represents a single bond, an alkylene group, —COO—, an aromatic ring group, or a group formed by a combination of these groups.

Examples of L^{1c} include L^{1a} in General Formula (aa).

As L^{1c}, a single bond, an alkylene group, —COO—, or a group formed by a combination of these groups is preferable, and —COO— is more preferable.

L^{2c} represents a cycloalkylene group.

The above-described cycloalkylene group may be monocyclic or polycyclic.

The number of carbon atoms in the above-described cycloalkylene group is preferably 3 to 15.

One or more (for example, one or two) of —CH₂-'s constituting a ring structure of the above-described cycloalkylene group may be replaced with a heteroatom (for example, —O—, —S—, and the like), —SO₂—, —SO₃—, an alkoxycarbonyl group, or a carbonyl group.

The above-described cycloalkylene group may further have a substituent.

Examples of the above-described substituent include the above-described substituent X.

In addition, examples of the above-described substituent also include T described above.

L^{3c} represents a single bond or a divalent linking group.

Examples of the above-described divalent linking group include —CO—, —O—, —S, —SO—, —SO₂—, —NR^{N}—, a hydrocarbon group (for example, an alkylene group, a cycloalkylene group, an alkenylene group, an arylene group, and the like), and a group formed by a combination of these groups. R^{N} represents a hydrogen atom or the above-described substituent X. The above-described hydrocarbon group may further have a substituent, and preferably has a halogen atom (preferably a fluorine atom) as the substituent. In addition, examples of the above-described substituent also include T described above.

As L^{3c}, an alkylene group which may have a fluorine atom or an alkoxycarbonyl group which may have a fluorine atom is preferable.

In General Formulae (aa) to (ac), Z represents the specific group.

A content of the repeating unit a is preferably 1% by mole or more, more preferably 5% by mole or more, and still more preferably 10% by mole or more with respect to all repeating units in the acid-decomposable resin. The upper limit thereof is preferably less than 50%, more preferably 40% by mole or less, and still more preferably 30% by mole or less with respect to all repeating units.

The repeating unit a may be used alone or in combination of two or more kinds thereof. In a case where two or more kinds of the repeating units a are used, a total content thereof is preferably within the content range.

(Repeating Unit A2)

The acid-decomposable resin includes a repeating unit represented by General Formula (A2).

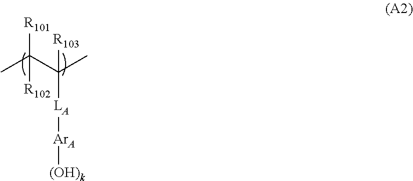

In General Formula (A2), R₁₀₁ to R₁₀₃ each independently represent a hydrogen atom, an alkyl group, a cycloalkyl group, a halogen atom, a cyano group, or an alkyloxycarbonyl group. However, R₁₀₂ may be bonded to Ar_{A} to form a ring, and in this case, R₁₀₂ represents a single bond or an alkylene group.

L_{A} represents a single bond or a divalent linking group.

Ar_{A} represents a (k+1)-valent aromatic ring group.

k represents an integer of 1 to 5.

Hereinafter, each element will be described in detail.

In General Formula (A2), R₁₀₁ to R₁₀₃ each independently represent a hydrogen atom, an alkyl group, a cycloalkyl group, a halogen atom, a cyano group, or an alkyloxycarbonyl group.

The above-described alkyl group may be linear or branched. The number of carbon atoms in the above-described alkyl group is preferably 1 to 6 and more preferably 1 to 3.

The above-described cycloalkyl group may be monocyclic or polycyclic. The number of carbon atoms in the above-described cycloalkyl group is preferably 3 to 15.

Examples of the halogen atom include a fluorine atom, a chlorine atom, a bromine atom, and an iodine atom.

The number of carbon atoms in the above-described alkoxycarbonyl group is preferably 1 to 10. Examples of an alkyl group moiety in the above-described alkoxycarbonyl group include the same group as those in the above-described alkyl group.

The above-described alkyl group, cycloalkyl group, and alkyloxycarbonyl group may further have a substituent. Examples of the above-described substituent include an alkyl group, a cycloalkyl group, an aryl group, an amino group, an amide group, a ureido group, a urethane group, a hydroxyl group, a carboxy group, a halogen atom, an alkoxy group, a thioether group, an acyl group, an acyloxy group, an alkoxycarbonyl group, a cyano group, and a nitro group.

As R₁₀₁ to R₁₀₃, a hydrogen atom or an alkyl group is preferable, and a hydrogen atom is more preferable.

R₁₀₂ may be bonded to Ar_{A} to form a ring, and in this case, R₁₀₂ represents a single bond or an alkylene group. Examples of a structure formed by bonding R₁₀₂ and Ar_{A} include a structure derived from an acenaphthylene ring, an indene ring, and the like (B-7 and B-37 exemplified in the specific structure of the repeating unit A2 described later).

L_{A} represents a single bond or a divalent linking group.

Examples of the divalent linking group include —CO—, —O—, —COO—, —S, —SO—, —SO₂—, —NR^{N}— (R^{N} represents a hydrogen atom or a substituent), a hydrocarbon group (for example, an alkylene group, a cycloalkylene group, an alkenylene group, an arylene group, and the like), and a group formed by a combination of these groups. The above-described hydrocarbon group may further have a substituent.

Ar_{A} represents a (k+1)-valent aromatic ring group. The (k+1)-valent aromatic ring group corresponds to a group formed by removing k+1 hydrogen atoms from an aromatic ring. For example, in a case where the (k+1) is 2, Ar_{A} represents a divalent aromatic ring group (an arylene group or a heteroarylene group).

The aromatic ring group is not particularly limited, and the aromatic ring constituting the aromatic ring group may be monocyclic or polycyclic.

Examples of the aromatic ring constituting the aromatic ring group include an aromatic hydrocarbon ring and an aromatic heterocyclic ring. Examples of the aromatic hydrocarbon ring include a benzene ring, a naphthalene ring, an anthracene ring, a phenanthrene ring, and a pyrene ring. Examples of the aromatic heterocyclic ring include a furan ring, a pyrrole ring, a pyrazole ring, an imidazole ring, a thiophene ring, an oxazole ring, and a thiazole ring.

In a case where the aromatic ring constituting the aromatic ring group is polycyclic, it may be a polycycle in which an aromatic hydrocarbon ring and an aromatic heterocyclic ring are combined. Examples of the polycycle include an indole ring, an isoindole ring, a benzimidazole ring, a purine ring, a carbazole ring, a benzofuran ring, an isobenzofuran ring, a benzothiophene ring, a benzoxazole ring, and a benzothiazole ring.

The aromatic ring group may further have a substituent. Examples of the substituent include groups exemplified by the substituent K, and an alkyl group or a halogen atom is preferable, and a fluorine atom, a chlorine atom, an iodine atom, or a bromine atom is more preferable.

k represents an integer of 1 to 5. In a case where R₁₀₂ is bonded to Ar_{A} to form a ring and Ar_{A} has 6 carbon atoms, k represents an integer of 1 to 4.

k is preferably 1 or 2.

Examples of the repeating unit A2 are shown below, but the present invention is not limited thereto. a in the examples represents an integer and may be 1 to 3. R in the examples represents a hydrogen atom, an alkyl group, a cycloalkyl group, a halogen atom, a cyano group, or an alkyloxycarbonyl group.

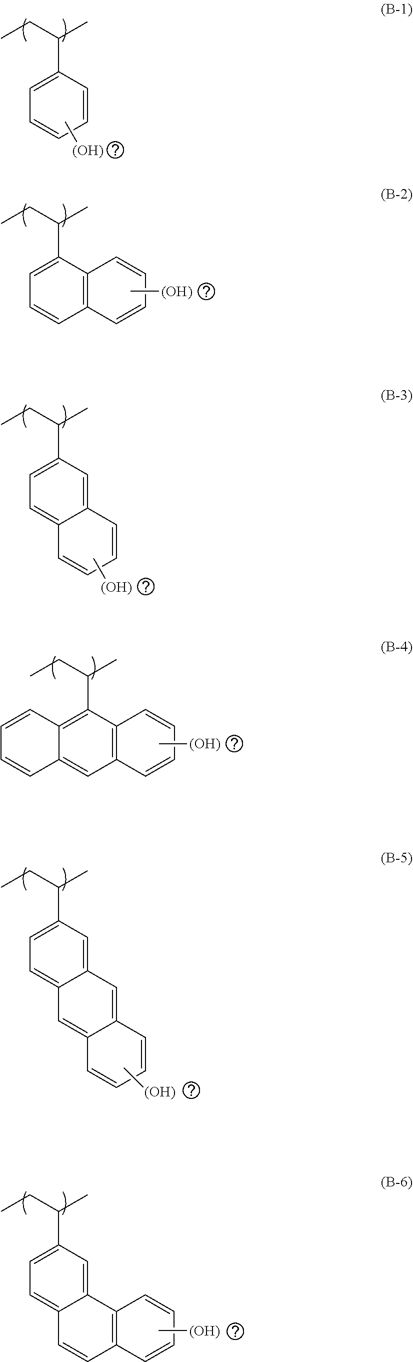

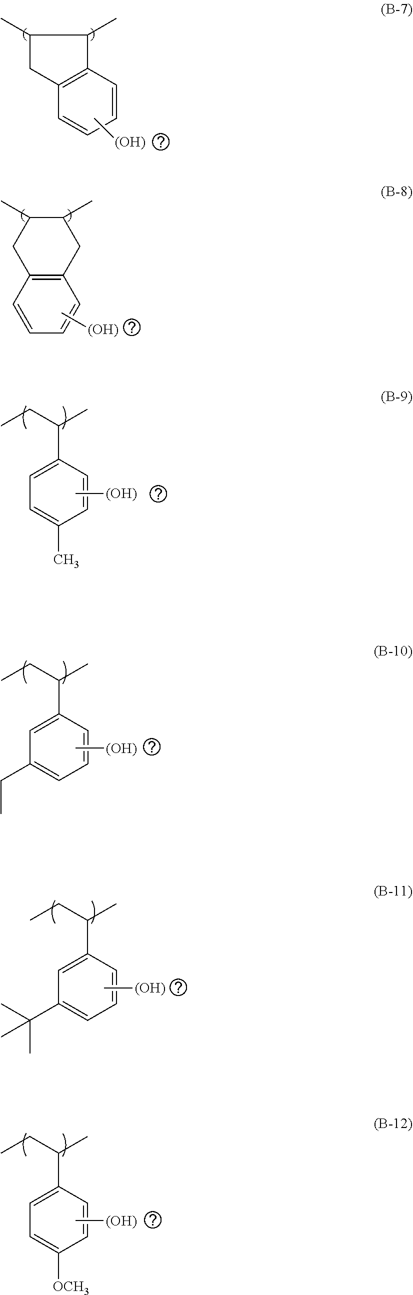

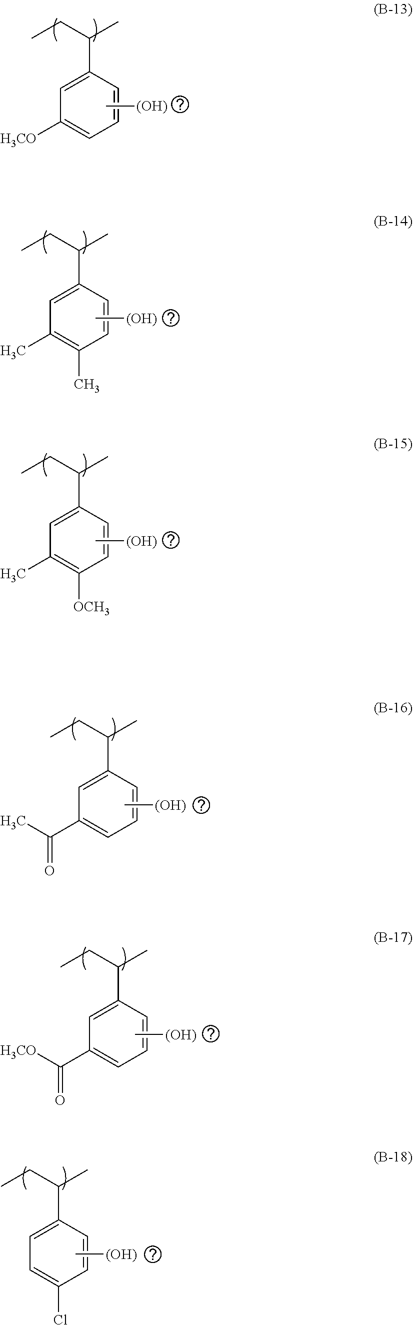

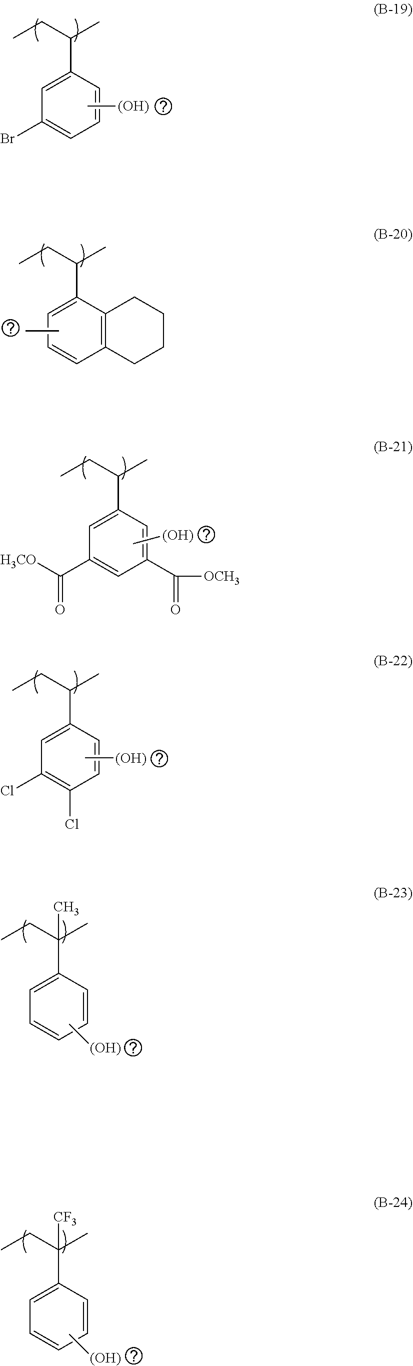

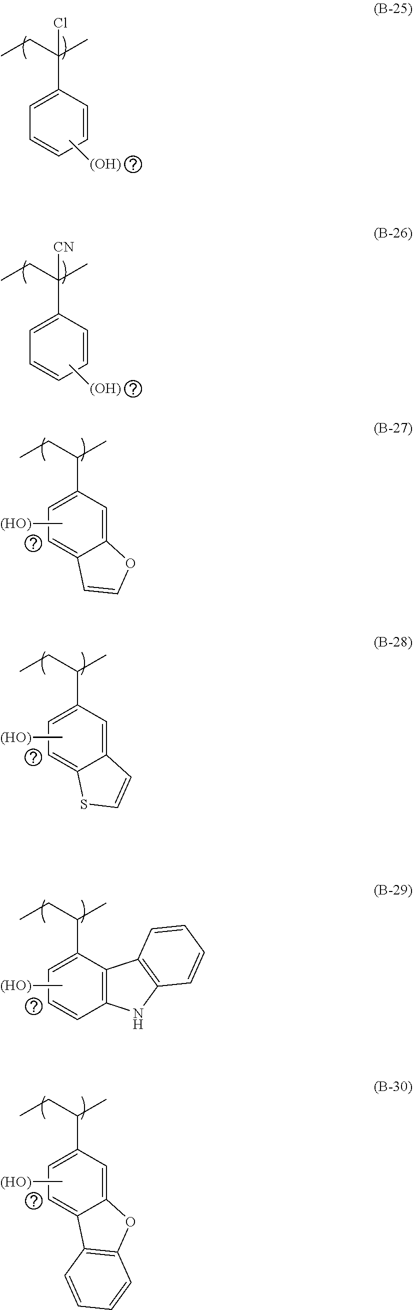

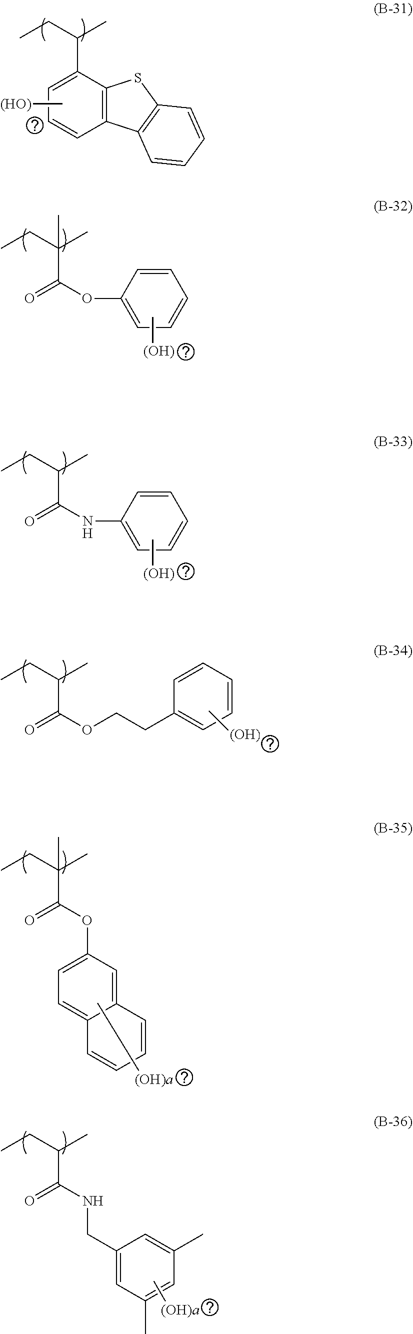

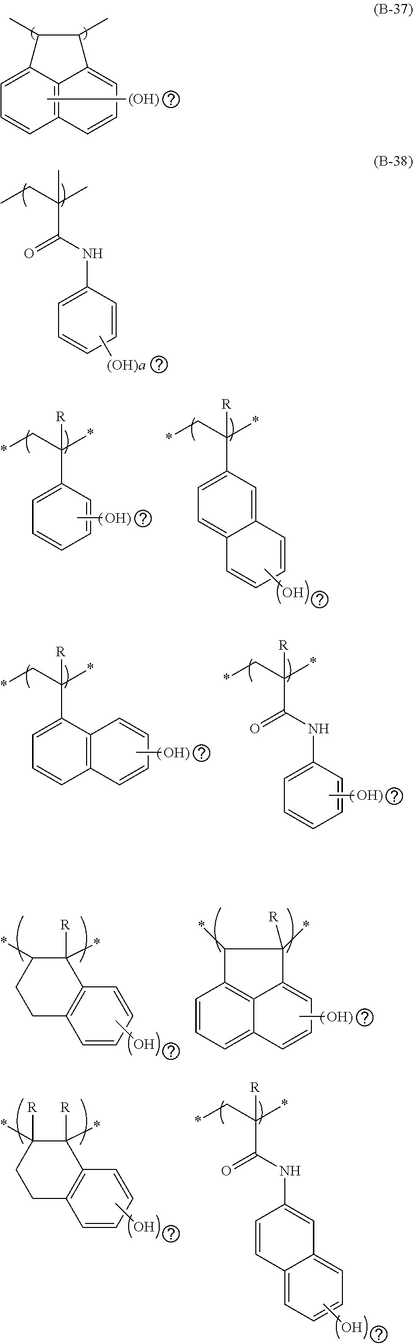

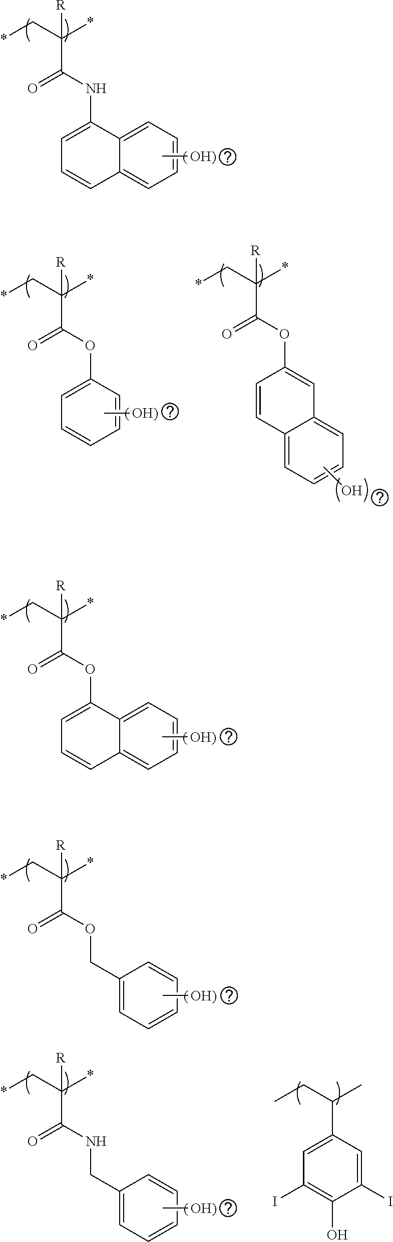

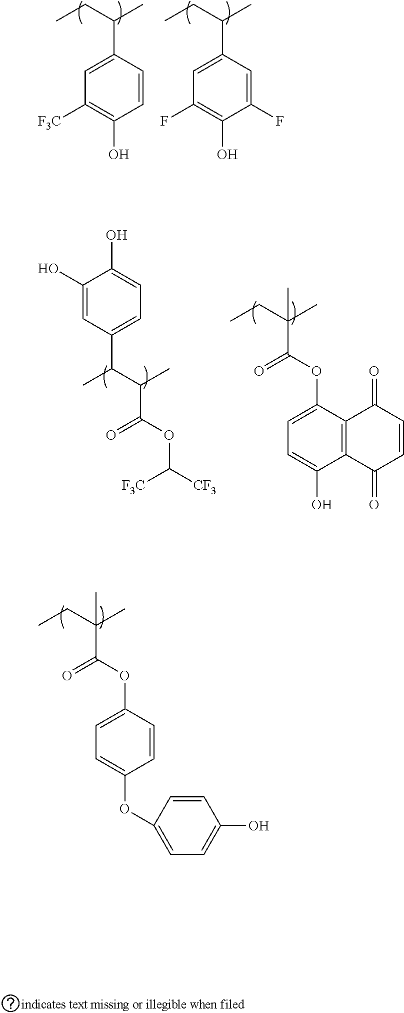

A content of the repeating unit A2 is preferably 5% by mole or more, and more preferably 10% by mole or more with respect to all repeating units in the acid-decomposable resin. The upper limit thereof is preferably 70% by mole or less, more preferably 65% by mole or less, and still more preferably 60% by mole or less with respect to all repeating units in the acid-decomposable resin.

(Repeating Unit Having Acid Group)

The acid-decomposable resin may have a repeating unit having an acid group.

The repeating unit having an acid group is different from the above-described repeating unit. That is, the above-described repeating unit represented by General Formula (A2) is not included in the repeating unit having an acid group.

As the acid group, an acid group having a pKa of 13 or less (however, excluding a phenolic hydroxyl group) is preferable. An acid dissociation constant of the above-described acid group is preferably 13 or less, more preferably 3 to 13, and still more preferably 5 to 10.

In a case where the acid-decomposable resin has an acid group having a pKa of 13 or less, a content of the acid group in the acid-decomposable resin is 0.2 to 6.0 mmol/g in many cases, preferably 0.8 to 6.0 mmol/g, more preferably 1.2 to 5.0 mmol/g, and still more preferably 1.6 to 4.0 mmol/g. In a case where the content of the acid group is within the above-described range, the development proceeds satisfactorily, the formed pattern shape is excellent, and the resolution is also excellent.

As the acid group, for example, a carboxy group, a fluorinated alcohol group (preferably, a hexafluoroisopropanol group), a sulfonic acid group, a sulfonamide group, or an isopropanol group is preferable.

In addition, in the above-described hexafluoroisopropanol group, one or more (preferably one or two) fluorine atoms may be substituted with a group (an alkoxycarbonyl group and the like) other than a fluorine atom. —C(CF₃)(OH)—CF₂— formed as above is also preferable as the acid group. In addition, one or more fluorine atoms may be substituted with a group other than a fluorine atom to form a ring including —C(CF₃)(OH)—CF₂—.

The repeating unit having an acid group may have a fluorine atom or an iodine atom.

The repeating unit having an acid group is exemplified below.

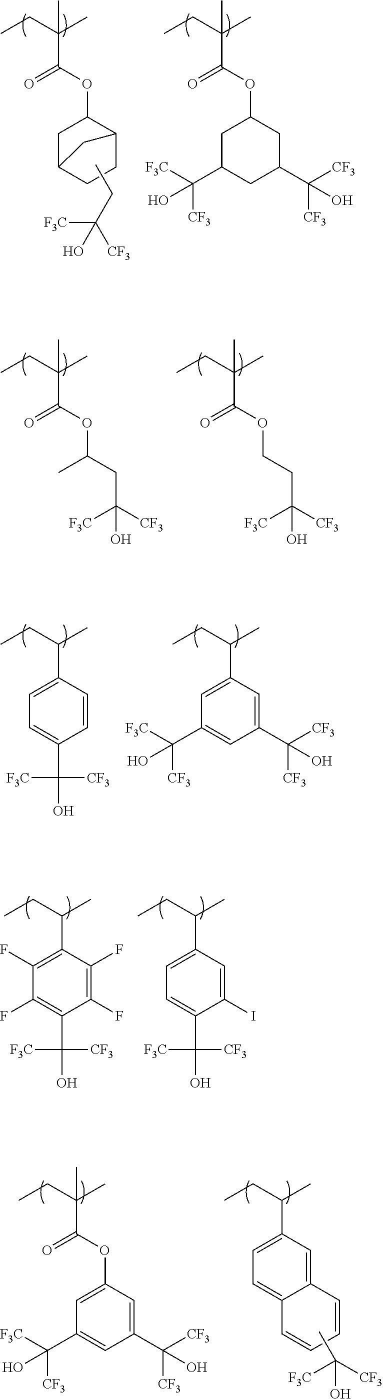

A content of the repeating unit having an acid group is preferably 5% by mole or more, and more preferably 10% by mole or more with respect to all repeating units in the acid-decomposable resin. The upper limit thereof is preferably 70% by mole or less, more preferably 65% by mole or less, and still more preferably 60% by mole or less with respect to all repeating units in the acid-decomposable resin.

(Repeating Unit Having Lactone Group)

The acid-decomposable resin may have a repeating unit having a lactone group.

The repeating unit having a lactone group may or may not correspond to the repeating unit having an acid-decomposable group.

For example, as long as it has a lactone group, the repeating unit having a lactone group may or may not correspond to the repeating unit a, and may or may not correspond to the repeating unit having an acid-decomposable group.

It is sufficient that the lactone group has a lactone structure. The lactone structure is preferably a 5- to 7-membered ring lactone structure. Among these, those in which another ring structure is fused to the 5- to 7-membered ring lactone structure to form a bicyclo structure or a spiro structure are more preferable.

It is preferable that the acid-decomposable resin has a repeating unit having a lactone group, which is obtained by removing one or more (for example, one or two) hydrogen atoms from a lactone structure represented by any of General Formulae (LC1-1) to (LC1-21).

In addition, the lactone group may be bonded directly to the main chain. For example, a ring member atom of the lactone group may constitute a main chain of the acid-decomposable resin.

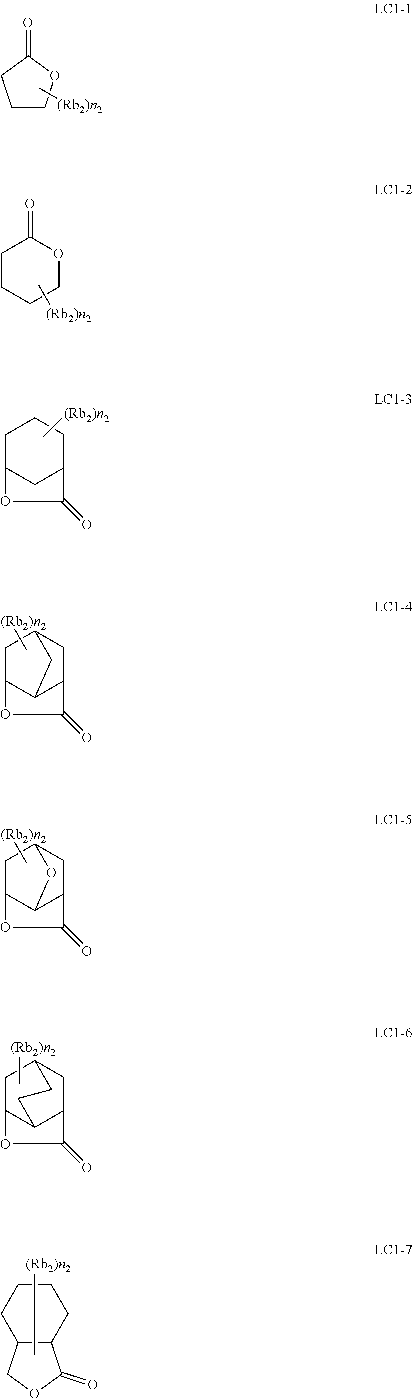

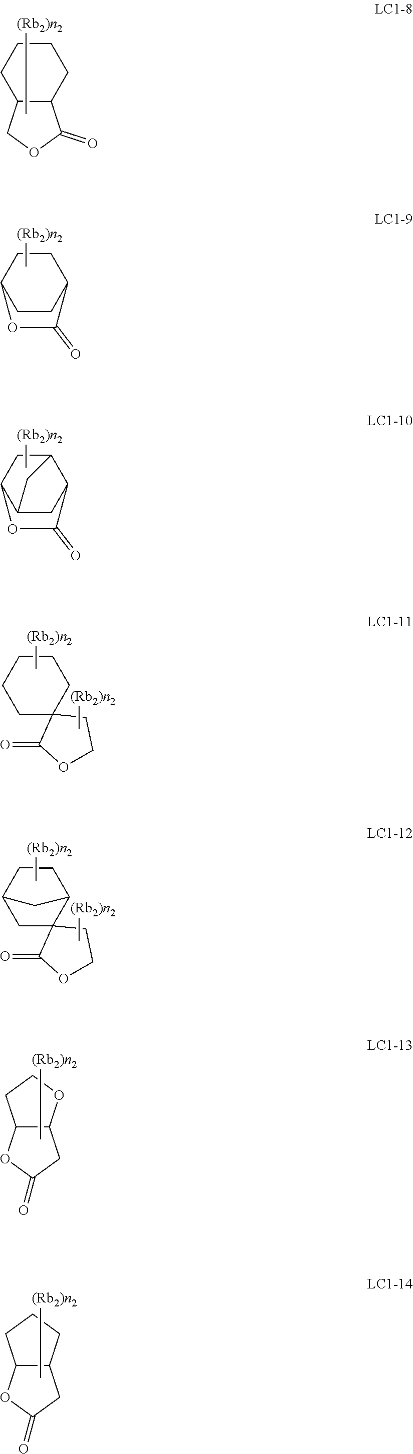

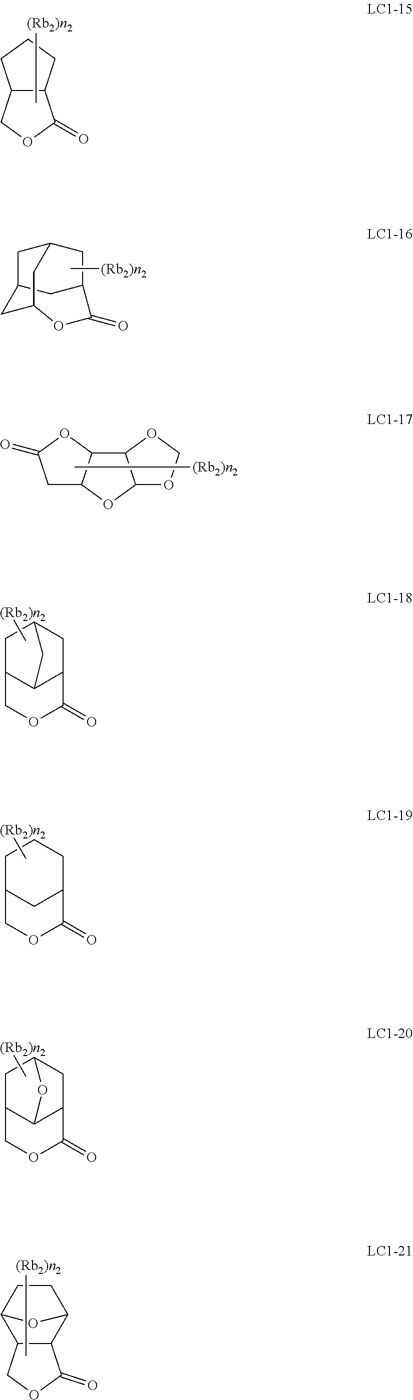

The above-described lactone structures may have a substituent (Rb₂). Examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxy group, a halogen atom, a hydroxyl group, a cyano group, a group including an acid-decomposable group (acid-decomposable group itself may be used), and a group formed by a combination of these groups. n2 represents an integer of 0 to 4. In a case where n2 is 2 or more, a plurality of Rb₂'s may be different from each other, and the plurality of Rb₂'s may be bonded to each other to form a ring.

One or more (for example, one or two) methylene groups not adjacent to —COO— or —O— in the ring member atoms of the above-described lactone structure may be replaced with a heteroatom such as —O— and —S—.

Examples of the repeating unit having a lactone group include a repeating unit represented by General Formula (AI).

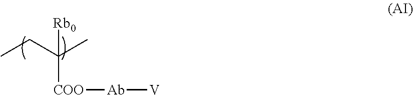

In General Formula (AI), Rb₀ represents a hydrogen atom, a halogen atom, or an alkyl group having 1 to 4 carbon atoms.

As the substituent which may be included in the above-described alkyl group, a hydroxyl group or a halogen atom is preferable.

Examples of the above-described halogen atom include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, —COO—, a carbonyl group, a carboxy group, or a group formed by a combination thereof. Among these, a single bond or a linking group represented by Ab₁-CO₂— is preferable. Ab₁ is a linear or branched alkylene group, or a monocyclic or polycyclic cycloalkylene group. Among these, a methylene group, an ethylene group, a cyclohexylene group, an adamantylene group, or a norbornylene group is preferable.

V represents a group formed by removing one hydrogen atom from ring member atoms of the lactone structure represented by any of General Formulae (LC1-1) to (LC1-21).

The repeating unit having a lactone group may be, for example, a repeating unit represented by General Formula (AII) or (AIII).

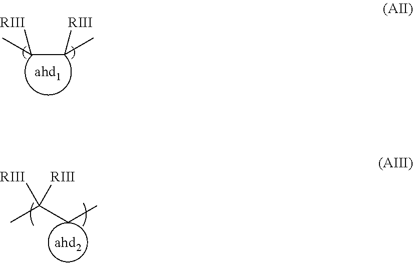

In General Formulae (AII) and (AIII), RIII's each independently represent a hydrogen atom or a substituent.

RIII is preferably a hydrogen atom.

In General Formula (AII), ahd₁ represents a group formed by removing one hydrogen atom from each of adjacent ring member atoms of the lactone structure represented by any of General Formulae (LC1-1) to (LC1-21).

In General Formula (AIII), ahd₂ represents a group formed by removing two hydrogen atoms from ring member atoms of the lactone structure represented by any of General Formulae (LC1-1) to (LC1-21).

The repeating unit having a lactone group is exemplified below.

(in the formulae, X is H, CH₃, CH₂OH, or CF₃)

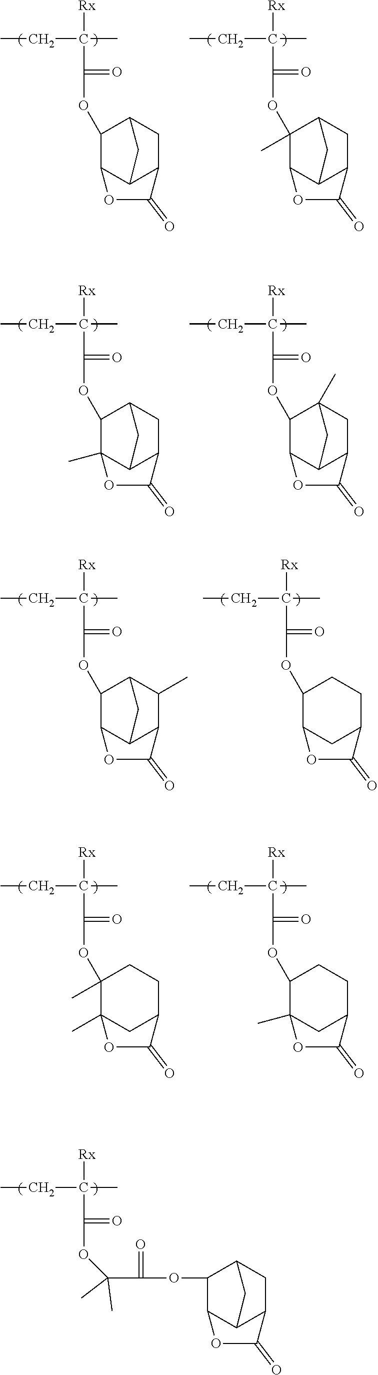

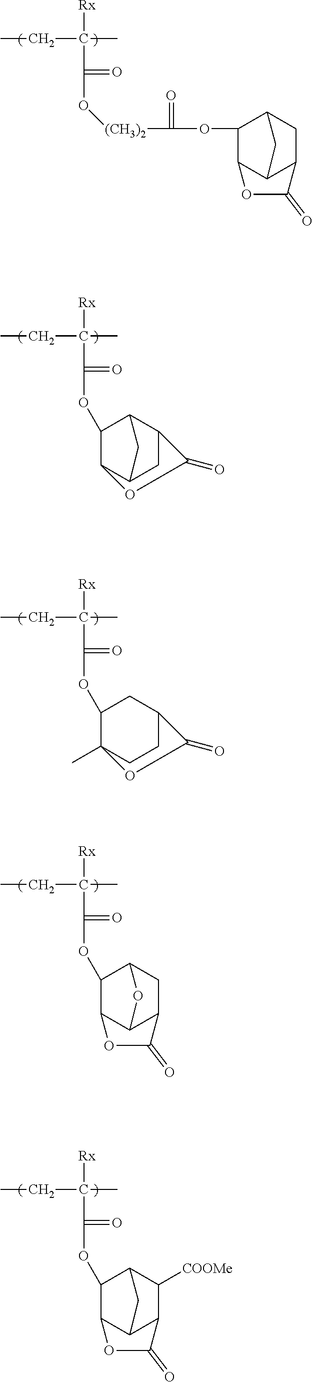

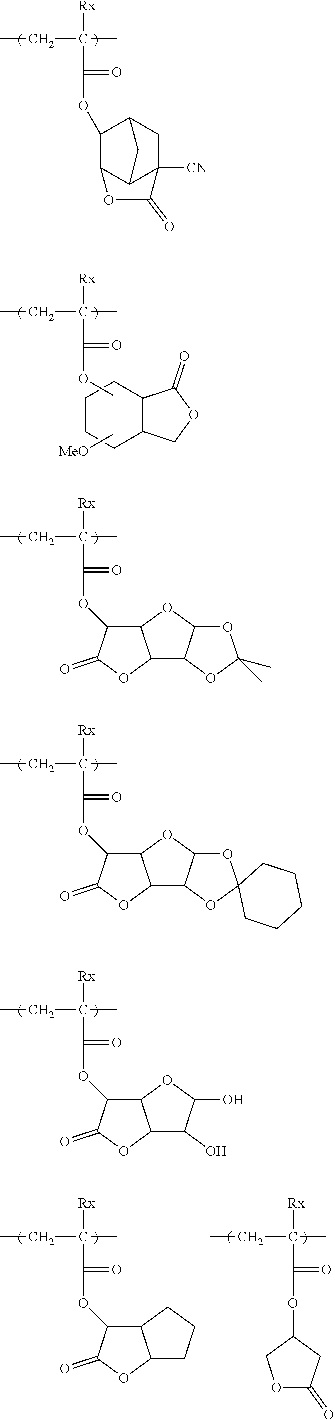

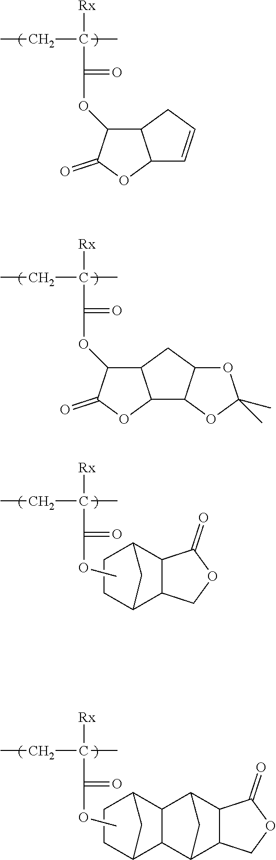

(in the formulae, X is H, CH₃, CH₂OH, or CF₃)

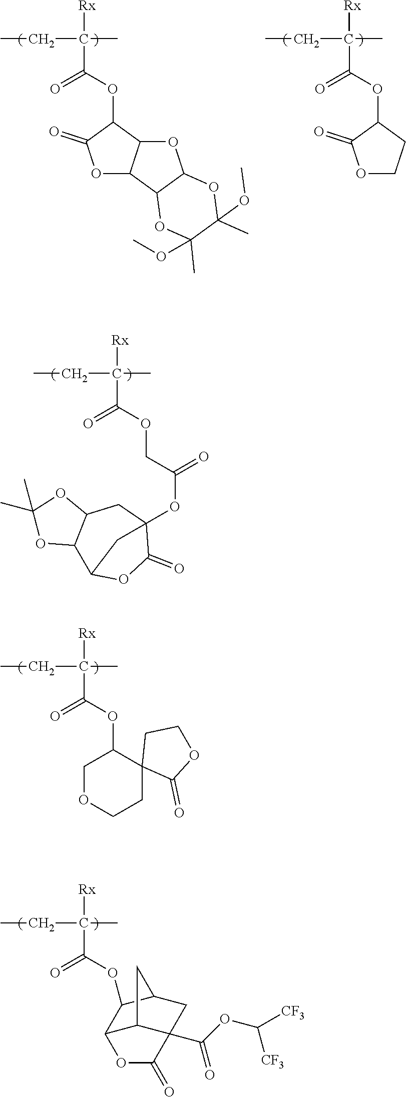

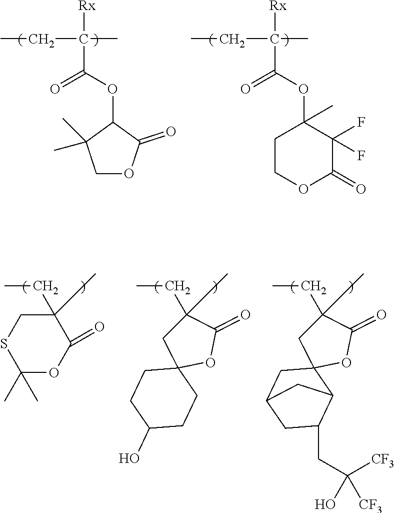

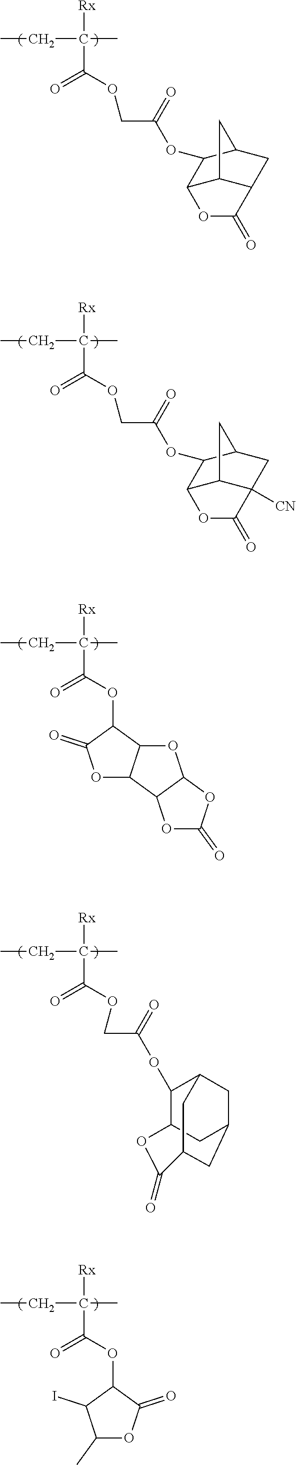

In a case where an optical isomer is present in the repeating unit having a lactone group, any of optical isomers may be used. In addition, one optical isomer may be used alone or a mixture of a plurality of the optical isomers may be used. In a case where one kind of optical isomers is mainly used, an optical purity (ee) thereof is preferably 90 or more, and more preferably 95 or more.

A content of the repeating unit having a lactone group is preferably 5% to 100% by mole, more preferably 10% to 80% by mole, and still more preferably 15% to 65% by mole with respect to all repeating units of the acid-decomposable resin.

Among the repeating units having a lactone group, a total of the repeating unit having a lactone group, which corresponds to the repeating unit a, and the repeating unit having a lactone group, which does not correspond to the repeating unit a, may satisfy the above-described suitable content; the repeating unit having a lactone group, which corresponds to the repeating unit a, alone may satisfy the above-described suitable content; or the repeating unit having a lactone group, which does not correspond to the repeating unit a, alone may satisfy the above-described suitable content.

The repeating unit having a lactone group may be used alone or in combination of two or more kinds thereof. In a case where two or more kinds thereof are used, a total content thereof is preferably within the suitable content range.

(Repeating Unit Having Sultone Group or Carbonate Group)

The acid-decomposable resin may have a repeating unit having a sultone group or a repeating unit having a carbonate group.

It is sufficient that the sultone group has a sultone structure. The sultone structure is preferably a 5- to 7-membered ring sultone structure. Among these, those in which another ring structure is fused to the 5- to 7-membered ring sultone structure to form a bicyclo structure or a spiro structure are more preferable.

In addition, the sultone group may be bonded directly to the main chain. For example, a ring member atom of the sultone group may constitute the main chain of the acid-decomposable resin.

It is preferable that the acid-decomposable resin has a repeating unit having a sultone group, which is formed by removing one or more (for example, one or two) hydrogen atoms from ring member atoms of a sultone structure represented by any of General Formulae (SL1-1) to (SL1-3).

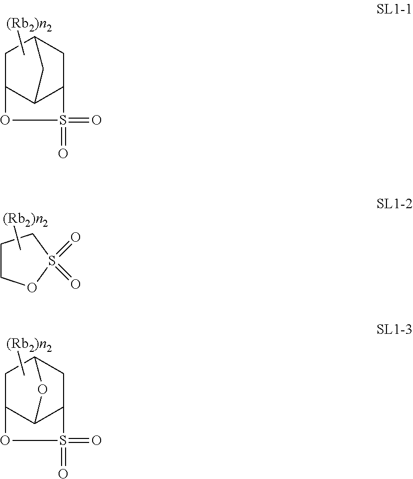

The above-described sultone structures may have a substituent (Rb₂). The substituent (Rb₂) in General Formulae (SL1-1) to (SL1-3) can be described in the same manner as the substituent (Rb₂) in the lactone structure represented by General Formulae (LC1-1) to (LC1-21) described above.

One or more (for example, one or two) methylene groups not adjacent to —COO— or —O— in the ring member atoms of the above-described sultone structure may be replaced with a heteroatom such as —O— and —S—.

Examples of the repeating unit having a sultone group include a repeating unit in which V in the repeating unit represented by General Formula (AI) described above is replaced with a group formed by removing one hydrogen atom from ring member atoms of the sultone structure represented by any of General Formulae (SL1-1) to (SL1-3); a repeating unit in which ahd₁ in the repeating unit represented by General Formula (AII) described above is replaced with a group formed by removing one hydrogen atom from each of adjacent ring member atoms of the sultone structure represented by any of General Formulae (SL1-1) to (SL1-3); and a repeating unit in which ahd₂ in the repeating unit represented by General Formula (AIII) described above is replaced with a group formed by removing two hydrogen atoms from ring member atoms of the sultone structure represented by any of General Formulae (SL1-1) to (SL1-3).

As the carbonate group, a cyclic carbonate ester group is preferable.

As the repeating unit having a cyclic carbonate ester group, a repeating unit represented by General Formula (A-1) is preferable.

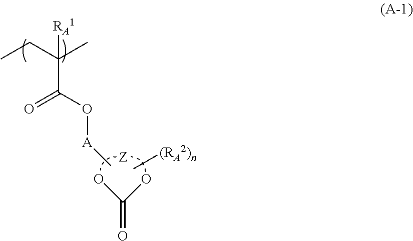

In General Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more, a plurality of R_{A}²'s may be the same or different from each other.

A represents a single bond or a divalent linking group. As the above-described divalent linking group, an alkylene group, a divalent linking group having a monocyclic or polycyclic alicyclic hydrocarbon structure, —O—, —COO—, a carbonyl group, a carboxy group, or a divalent group formed by a combination thereof is preferable.

Z represents an atomic group which forms a monocycle or polycycle with a group represented by —O—CO—O— in the general formula.

The repeating unit having a sultone group or a carbonate group is exemplified below.

(in the formulae, X is H, CH₃, CH₂OH, or CF₃)

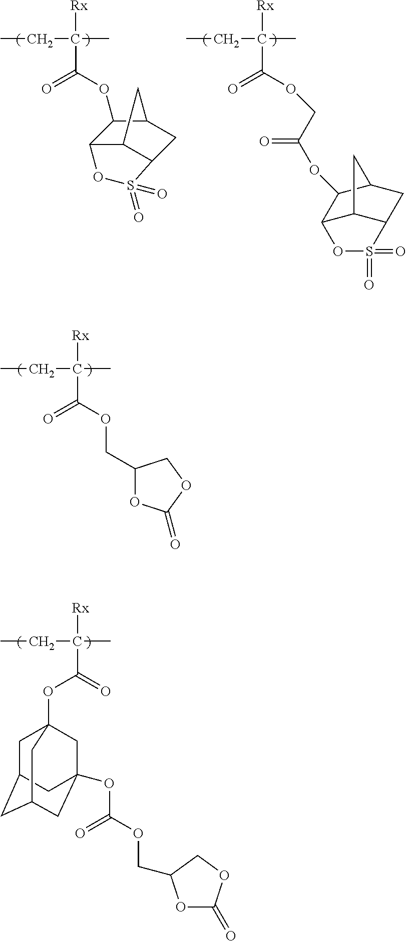

A content of the repeating unit having a sultone group or a carbonate group is preferably 1% by mole or more, and more preferably 10% by mole or more with respect to all the repeating units in the acid-decomposable resin. The upper limit thereof is preferably 85% by mole or less, more preferably 80% by mole or less, still more preferably 70% by mole or less, and particularly preferably 60% by mole or less with respect to all repeating units in the acid-decomposable resin.

(Repeating Unit Having Fluorine Atom or Iodine Atom)

The acid-decomposable resin may have a repeating unit having a fluorine atom or an iodine atom.

It is preferable that the repeating unit having a fluorine atom or an iodine atom is different from the above-described repeating units.

A content of the repeating unit having a fluorine atom or an iodine atom is preferably 0% by mole or more, more preferably 5% by mole or more, and still more preferably 10% by mole or more with respect to all repeating units in the acid-decomposable resin. The upper limit thereof is preferably 50% by mole or less, more preferably 45% by mole or less, and still more preferably 40% by mole or less with respect to all repeating units in the acid-decomposable resin.

(Repeating Unit for Reducing Mobility of Main Chain)

The acid-decomposable resin may have a repeating unit for reducing mobility of the main chain, as a repeating unit different from the repeating unit a.

In order to raise the Tg of the acid-decomposable resin (preferably to raise the Tg to higher than 90° C.), it is preferable to reduce the mobility of the main chain of the acid-decomposable resin. Examples of a method for lowering the mobility of the main chain of the acid-decomposable resin include the following (a) to (e) methods.
(a) introduction of a bulky substituent into the main chain
(b) introduction of a plurality of substituents into the main chain
(c) introduction of a substituent causing an interaction between the acid-decomposable resins into the vicinity of the main chain
(d) formation of the main chain in a cyclic structure
(e) linking of a cyclic structure to the main chain

Examples of a repeating unit corresponding to the method (a) include repeating units described in paragraphs [0107] to [0119] of WO2018/193954A.

Examples of a repeating unit corresponding to the method (b) include repeating units described in paragraphs [0113] to [0115] of WO2018/193954A.

Examples of a repeating unit corresponding to the method (c) include repeating units described in paragraphs [0119] to [0121] of WO2018/193954A.

Examples of a repeating unit corresponding to the method (d) include repeating units described in paragraphs [0126] to [0127] of WO2018/193954A.

Examples of a repeating unit corresponding to the method (e) include repeating units described in paragraphs [0131] to [0133] of WO2018/193954A.

A content of the repeating unit corresponding to each of the above-described methods is preferably 1% to 65% by mole, and more preferably 5% to 45% by mole with respect to all repeating units in the acid-decomposable resin.

(Repeating Unit Having Hydroxyl Group or Cyano Group)

The acid-decomposable resin may have a repeating unit having a hydroxyl group or a cyano group.

Examples of the repeating unit having a hydroxyl group or a cyano group include repeating units described in paragraphs [0153] to [0158] of WO2020/004306A.

A content of the repeating unit having a hydroxyl group or a cyano group is preferably 1% to 65% by mole, and more preferably 5% to 45% by mole with respect to all repeating units in the acid-decomposable resin.

(Repeating Unit Having Alicyclic Hydrocarbon Structure and not Exhibiting Acid Decomposability)

The acid-decomposable resin may have a repeating unit having an alicyclic hydrocarbon structure and not exhibiting acid decomposability. As a result, it is possible to reduce elution of low-molecular-weight components from the resist film into the immersion liquid during liquid immersion exposure.

A content of the repeating unit having an alicyclic hydrocarbon structure and not exhibiting acid decomposability is preferably 1% to 65% by mole, and more preferably 5% to 45% by mole with respect to all repeating units in the acid-decomposable resin.

(Other Repeating Units)

The acid-decomposable resin may have other repeating units in addition to the above-described repeating units.

The other repeating units are not particularly limited as long as a repeating unit other than the above-described repeating units.

For the purpose of controlling dry etching resistance, suitability for a standard developer, substrate adhesiveness, resist profile, resolving power, heat resistance, sensitivity, and the like, the acid-decomposable resin may have various repeating units in addition to the repeating units described above.

The acid-decomposable resin can be synthesized in accordance with an ordinary method (for example, a radical polymerization).

A weight-average molecular weight of the acid-decomposable resin as a value expressed in terms of polystyrene by a GPC method is preferably 1,000 to 200,000, more preferably 3,000 to 20,000, and still more preferably 5,000 to 15,000. By setting the weight-average molecular weight of the acid-decomposable resin to 1,000 to 200,000, deterioration of heat resistance and dry etching resistance can be further suppressed. In addition, deterioration of developability and deterioration of film-forming properties due to high viscosity can also be further suppressed.

A dispersity (molecular weight distribution) of the acid-decomposable resin is usually 1 to 5, and preferably 1.00 to 3.00, more preferably 1.20 to 3.00, and still more preferably 1.20 to 2.00. As the dispersity is smaller, resolution and resist shape are more excellent, and a side wall of a resist pattern is smoother and roughness is also more excellent.

In the resist composition, a content of the acid-decomposable resin is preferably 10.0% to 99.0% by mass, more preferably 20.0% to 98.0% by mass, and still more preferably 25.0% to 95.0% by mass with respect to the total solid content of the resist composition.

In addition, the acid-decomposable resin may be used alone or in combination of two or more kinds thereof. In a case where two or more kinds thereof are used, a total content thereof is preferably within the suitable content range.

[Photoacid Generator]

The resist composition may contain a photoacid generator other than the salt B.

The photoacid generator does not include the salt B.

Examples of other photoacid generators include photoacid generators described in paragraphs [0178] to [0215] of WO2020/004306A.

A molecular weight of the photoacid generator is preferably 100 to 10,000, more preferably 100 to 2,500, and still more preferably 100 to 1,500.

A content of the photoacid generator is preferably 10% by mass or more, more preferably 15% by mass or more, still more preferably 20% by mass or more, and particularly more preferably 40% by mass or more with respect to the total solid content of the resist composition. The upper limit thereof is preferably 80% by mass or less, more preferably 70% by mass or less, and still more preferably 60% by mass or less with respect to the total solid content of the resist composition.

The photoacid generator may be used alone or in combination of two or more kinds thereof. In a case where two or more kinds thereof are used, a total content thereof is preferably within the suitable content range.

[Acid Diffusion Control Agent]

The resist composition may contain an acid diffusion control agent.

The acid diffusion control agent acts as a quencher which suppresses a reaction of an acid-decomposable resin in a non-exposed portion by excessive generated acids by trapping the acids generated from the photoacid generator and the like during exposure.

The type of the acid diffusion control agent is not particularly limited, and examples thereof include a basic compound (CA), a low-molecular-weight compound (CB) having a nitrogen atom and a group which is eliminated by action of acid, and a compound (CC) in which ability to control acid diffusion decreases or disappears in a case of being irradiated with actinic ray or radiation.

Examples of the compound (CC) include an onium salt compound (CD) which is a relatively weak acid with respect to the photoacid generator, and a basic compound (CE) in which basicity decreases or disappears in a case of being irradiated with actinic ray or radiation.

In addition, specific examples of the basic compound (CA) include compounds described in paragraphs [0132] to [0136] of WO2020/066824A; specific examples of the basic compound (CE) in which basicity decreases or disappears in a case of being irradiated with actinic ray or radiation include compounds described in paragraphs [0137] to [0155] of WO2020/066824A; specific examples of the low-molecular-weight compound (CB) having a nitrogen atom and a group which is eliminated by action of acid include paragraphs [0156] to [0163] of WO2020/066824A; and specific examples of the onium salt compound (CE) having a nitrogen atom in the cationic moiety include paragraph [0164] of WO2020/066824A.

In addition, specific examples of the onium salt compound (CD) which is a relatively weak acid with respect to the photoacid generator include compounds described in paragraphs [0305] to [0314] of WO2020/158337A.

In addition to above, for example, as the acid diffusion control agent, known compounds described in paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used.

In a case where the resist composition contains the acid diffusion control agent, a content of the acid diffusion control agent (in a case of a plurality of types, the total thereof) is preferably 0.1% to 15.0% by mass, and more preferably 1.0% to 15.0% by mass with respect to the total solid content of the resist composition.

In the resist composition, the acid diffusion control agent may be used alone or in combination of two or more kinds thereof.

[Hydrophobic Resin]

The resist composition may contain a hydrophobic resin different from the acid-decomposable resin, in addition to the above-described acid-decomposable resin.

It is preferable that the hydrophobic resin is designed to be unevenly distributed on a surface of the resist film, and it is not necessary to have a hydrophilic group in the molecule as different from a surfactant, and is not necessary to contribute to uniform mixing of polar materials and non-polar materials.

Examples of an effect caused by the addition of the hydrophobic resin include a control of static and dynamic contact angles of a surface of the resist film with respect to water and suppression of outgas.

From the viewpoint of uneven distribution on the film surface layer, the hydrophobic resin preferably has any one or more of a fluorine atom, a silicon atom, and a CH₃ partial structure which is included in a side chain moiety of a resin, and more preferably has two or more kinds thereof. In addition, the above-described hydrophobic resin preferably has a hydrocarbon group having 5 or more carbon atoms. These groups may be included in the main chain of the resin or may be substituted in the side chain of the resin.

Examples of the hydrophobic resin include compounds described in paragraphs [0275] to [0279] of WO2020/004306A.

In a case where the resist composition contains the hydrophobic resin, a content thereof is preferably 0.01% to 20% by mass, more preferably 0.1% to 15% by mass, still more preferably 0.1% to 10% by mass, and particularly preferably 0.1% to 8.0% by mass with respect to the total solid content of the resist composition.

The hydrophobic resin may be used alone or in combination of two or more kinds thereof. In a case where two or more kinds thereof are used, a total content thereof is preferably within the suitable content range.

[Surfactant]

The resist composition may contain a surfactant.

In a case where the surfactant is contained, it is possible to form a pattern having more excellent adhesiveness and fewer development defects.

The surfactant is preferably a fluorine-based surfactant or a silicon-based surfactant. From the viewpoint of environmental load, a silicon-based surfactant containing no fluorine atom may be used. In addition, from the viewpoint of environmental regulation, a silicon-based surfactant may be used.

As the fluorine-based fluorine-based surfactant and the silicon-based surfactant, for example, surfactants described in paragraphs [0218] and [0219] of WO2018/19395A can be used.

In a case where the resist composition contains a surfactant, a content thereof is preferably 0.0001% to 2% by mass, and more preferably 0.0005% to 1% by mass with respect to the total solid content of the resist composition.

The surfactant may be used alone or in combination of two or more kinds thereof. In a case where two or more kinds thereof are used, a total content thereof is preferably within the suitable content range.

[Solvent]

The resist composition may contain a solvent.

The solvent preferably includes at least one solvent of (M1) propylene glycol monoalkyl ether carboxylate or (M2) at least one selected from the group consisting of propylene glycol monoalkyl ether, lactic acid ester, acetic acid ester, alkoxypropionic acid ester, chain ketone, cyclic ketone, lactone, and alkylene carbonate. The solvent may further include a component other than the components (M1) and (M2).

The present inventors have found that, by using such a solvent and the above-described resin in combination, a pattern having a small number of development defects can be formed while improving coating property of the resist composition. A reason for this is not always clear, but the present inventors have considered that, since these solvents have a good balance of solubility, boiling point, and viscosity of the above-described resin, unevenness of a film thickness of a resist film, generation of precipitates during spin coating, and the like can be suppressed.

Details of the component (M1) and the component (M2) are described in paragraphs [0218] to [0226] of WO2020/004306A, the contents of which are incorporated herein by reference.

In a case where the solvent further contains a component other than the components (M1) and (M2), a content of the component other than the components (M1) and (M2) is preferably 5% to 30% by mass with respect to the total amount of the solvent.

A content of the solvent in the resist composition is preferably set such that the concentration of solid contents is 0.5% to 30% by mass, and more preferably set such that the concentration of solid contents is 1% to 20% by mass. With this content, the coating property of the resist composition can be further improved.

[Other Additives]

The resist composition may further contain at least one or more of a dissolution inhibiting compound, a dye, a plasticizer, a photosensitizer, a light absorbing agent, or a compound promoting a solubility in a developer (an alicyclic or aliphatic compound including a carboxylic acid group).

The resist composition may further contain a dissolution inhibiting compound. Here, the “dissolution inhibiting compound” is intended to be a compound having a molecular weight of 3000 or less, in which solubility in an organic developer decreases by decomposition due to action of acid.

The resist composition according to the embodiment of the present invention is also suitably used as a photosensitive composition for EUV light.

Since the EUV light has a wavelength of 13.5 nm and has a shorter wavelength than that of ArF (wavelength: 193 nm), the number of incident photons in a case of being exposed with the same sensitivity is small. Therefore, influence of “photon shot noise” in which the number of photons varies probabilistically is large, which causes deterioration of LWR and bridge defects. In order to reduce the photon shot noise, there is a method of increasing the number of incident photons by increasing an exposure amount, but there is a trade-off with the demand for higher sensitivity.

In a case where an A value obtained by Expression (1) is high, absorption efficiency of EUV light and electron beams of the resist film formed from the resist composition is high, which is effective in reducing the photon shot noise. The A value represents the absorption efficiency of EUV light and electron beams of the resist film in terms of a mass proportion.

A=([H]×0.04+[C]×1.0+[N]×2.1+[O]×3.6+[F]×5.6+[S]×1.5+[I]×39.5)/([H]×1+[C]×12+[N]×14+[O]×16+[F]×19+[S]×32+[I]×127) Expression (1):

The A value is preferably 0.120 or more. In a case where the A value is extremely high, the transmittance of EUV light and electron beams of the resist film is lowered and the optical image profile in the resist film is deteriorated, which results in difficulty in obtaining a good pattern shape, so that the upper limit thereof is preferably 0.240 or less, and more preferably 0.220 or less.

In Expression (1), [H] represents a molar ratio of hydrogen atoms derived from a total solid content with respect to all atoms of the total solid content in the actinic ray-sensitive or radiation-sensitive resin composition, [C] represents a molar ratio of carbon atoms derived from the total solid content with respect to all atoms of the total solid content in the actinic ray-sensitive or radiation-sensitive resin composition, [N] represents a molar ratio of nitrogen atoms derived from the total solid content with respect to all atoms of the total solid content in the actinic ray-sensitive or radiation-sensitive resin composition, [O] represents a molar ratio of oxygen atoms derived from the total solid content with respect to all atoms of the total solid content in the actinic ray-sensitive or radiation-sensitive resin composition, [F] represents a molar ratio of fluorine atoms derived from the total solid content with respect to all atoms of the total solid content in the actinic ray-sensitive or radiation-sensitive resin composition, [S] represents a molar ratio of sulfur atoms derived from the total solid content with respect to all atoms of the total solid content in the actinic ray-sensitive or radiation-sensitive resin composition, and [I] represents a molar ratio of iodine atoms derived from the total solid content with respect to all atoms of the total solid content in the actinic ray-sensitive or radiation-sensitive resin composition.

For example, in a case where the resist composition contains the acid-decomposable resin, the salt B, and the solvent, the acid-decomposable resin and salt B correspond to the solid content. That is, all atoms of the total solid content correspond to a sum of all atoms derived from the acid-decomposable resin and all atoms derived from the salt B. For example, [H] represents a molar ratio of hydrogen atoms derived from the total solid content with respect to all atoms in the total solid content, and by way of description based on the example above, [H] represents a molar ratio of a sum of hydrogen atoms derived from the acid-decomposable resin and hydrogen atoms derived from the compound (1) with respect to the sum of all atoms derived from the acid-decomposable resin and all atoms derived from the compound (1).

The A value can be calculated by computation of the structure of constituent components of the total solid content in the resist composition, and the ratio of the number of atoms contained in a case where the content is already known. In addition, even in a case where the constituent component is not known yet, it is possible to calculate a ratio of the number of constituent atoms by subjecting a resist film obtained after evaporating the solvent components of the resist composition to computation according to an analytic approach such as elemental analysis.

{Resist Film Forming Method and Pattern Forming Method}

A procedure of the pattern forming method using the above-described resist composition preferably has the following steps.
Step 1: step of forming a resist film on a substrate using the resist composition
Step 2: step of exposing the resist film
Step 3: step of developing the exposed resist film using a developer

Hereinafter, the procedure of each of the above-described steps will be described in detail.

(Step 1: Resist Film Forming Step)

The step 1 is a step of forming a resist film on a substrate using the resist composition.

The definition of the resist composition is as described above.

Examples of a method for forming a resist film on a substrate using the resist composition include a method in which a resist composition is applied to a substrate.

In addition, it is preferable that the resist composition before the application is filtered through a filter, as desired. A pore size of the filter is preferably 0.1 μm or less, more preferably 0.05 μm or less, and still more preferably 0.03 μm or less. In addition, the filter is preferably a polytetrafluoroethylene-made filter, a polyethylene-made filter, or a nylon-made filter.

The resist composition can be applied to a substrate (for example, silicon and silicon dioxide coating) as used in the manufacture of integrated circuit elements by a suitable application method such as an application using a spinner or a coater. The coating method is preferably a spin coating using a spinner. A rotation speed upon the spin coating using a spinner is preferably 1000 to 3000 rpm.

After the application of the resist composition, the substrate may be dried to form a resist film. In addition, various underlying films (an inorganic film, an organic film, or an antireflection film) may be formed on an underlayer of the resist film.

Examples of the drying method include a method of heating and drying. The heating can be carried out using a unit included in at least one of an ordinary exposure machine or an ordinary development machine, and may also be carried out using a hot plate or the like. A heating temperature is preferably 80° C. to 150° C., more preferably 80° C. to 140° C., and still more preferably 80° C. to 130° C. A heating time is preferably 30 to 1000 seconds, more preferably 60 to 800 seconds, and still more preferably 60 to 600 seconds.

From the viewpoint that a fine pattern having higher accuracy can be formed, a film thickness of the resist film is preferably 10 to 120 nm. Among these, in a case of performing EUV exposure, the film thickness of the resist film is more preferably 10 to 65 nm and still more preferably 15 to 50 nm.

A topcoat may be formed on an upper layer of the resist film using a topcoat composition.

It is preferable that the topcoat composition is not mixed with the resist film and can be uniformly applied to the upper layer of the resist film. The topcoat is not particularly limited, a topcoat known in the related art can be formed by the methods known in the related art, and for example, the topcoat can be formed based on the description in paragraphs [0072] to [0082] of JP2014-059543A.

For example, it is preferable that a topcoat including a basic compound as described in JP2013-061648A is formed on the resist film. Specific examples of the basic compound which can be included in the topcoat include a basic compound which may be included in the resist composition.

In addition, it is also preferable that the topcoat includes a compound which includes at least one group or bond selected from the group consisting of an ether bond, a thioether bond, a hydroxyl group, a thiol group, a carbonyl bond, and an ester bond.

(Step 2: Exposing Step)

The step 2 is a step of exposing the resist film.

Examples of an exposing method include a method in which the formed resist film is irradiated with actinic ray or radiation through a predetermined mask.

Examples of the actinic ray or radiation include infrared light, visible light, ultraviolet light, far ultraviolet light, extreme ultraviolet light, X-rays, and electron beam.

The wavelength of the far ultraviolet light is preferably 250 nm or less, more preferably 220 nm or less, and still more preferably 1 to 200 nm. Specific examples thereof include a KrF excimer laser (248 nm), an ArF excimer laser (193 nm), an F₂ excimer laser (157 nm), EUV light (13 nm), X-rays, and electron beams.

It is preferable to perform baking (heating) before performing development and after the exposure. The baking accelerates a reaction in the exposed portion, and the sensitivity and the pattern shape are improved.

A heating temperature is preferably 80° C. to 150° C., more preferably 80° C. to 140° C., and still more preferably 80° C. to 130° C.

A heating time is preferably 10 to 1000 seconds, more preferably 10 to 180 seconds, and still more preferably 30 to 120 seconds.

The heating can be carried out using a unit included in at least one of an ordinary exposure machine or an ordinary development machine, and may also be carried out using a hot plate or the like.

This step is also referred to as post exposure bake (PEB).

(Step 3: Developing Step)

The step 3 is a step of developing the exposed resist film using a developer to form a pattern.

The developer may be either an alkali developer or a developer including an organic solvent (hereinafter, also referred to as “organic developer”).

Examples of a developing method include a method in which the substrate is immersed in a tank filled with a developer for a certain period of time (a dipping method), a method in which a development is performed by heaping a developer up onto the surface of the substrate by surface tension, and then leaving it to stand for a certain period of time (a puddle method), a method in which a developer is sprayed on the surface of the substrate (a spraying method), and a method in which a developer is continuously jetted onto the substrate rotating at a constant rate while scanning a developer jetting nozzle at a constant rate (a dynamic dispensing method).

In addition, after the step of performing the development, a step of stopping the development may be carried out while replacing the solvent with another solvent.

A developing time is not particularly limited as long as it is a period of time where the non-exposed portion of the resin is sufficiently dissolved, and is preferably 10 to 300 seconds and more preferably 20 to 120 seconds.

A temperature of the developer is preferably 0° C. to 50° C. and more preferably 15° C. to 35° C.

As the alkali developer, it is preferable to use an aqueous alkali solution including an alkali. Examples of the type of the aqueous alkali solution include an aqueous alkali solution including a quaternary ammonium salt typified by tetramethylammonium hydroxide, an inorganic alkali, a primary amine, a secondary amine, a tertiary amine, an alcoholamine, a cyclic amine, or the like. Among these, the alkali developer is preferably aqueous solutions of the quaternary ammonium salts typified by tetramethylammonium hydroxide (TMAH). An appropriate amount of alcohols, a surfactant, or the like may be added to the alkali developer. An alkali concentration of the alkali developer is usually 0.1% to 20% by mass. In addition, a pH of the alkali developer is usually 10.0 to 15.0. A content of water in the alkali developer is preferably 51% to 99.95% by mass.

The organic developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

A plurality of the above-described solvents may be mixed, or the solvent may be used in admixture with a solvent other than those described above or water. With respect to the total mass of the developer, a moisture content in the entire developer is preferably less than 50% by mass, more preferably less than 20% by mass, and still more preferably less than 10% by mass, and it is particularly preferable that the entire developer contains substantially no water.

A content of the organic solvent with respect to the organic developer is preferably 50% to 100% by mass, more preferably 80% to 100% by mass, still more preferably 90% to 100% by mass, and particularly preferably 95% to 100% by mass with respect to the total mass of the developer.

(Other Steps)

It is preferable that the above-described pattern forming method includes a step of performing washing using a rinsing liquid after the step 3.

Examples of the rinsing liquid used in the rinsing step after the step of performing development using an alkali developer include pure water. An appropriate amount of a surfactant may be added to the pure water.

An appropriate amount of a surfactant may be added to the rinsing liquid.

The rinsing liquid used in the rinsing step after the developing step with an organic developer is not particularly limited as long as the rinsing liquid does not dissolve the pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

A method for the rinsing step is not particularly limited, and examples thereof include a method in which the rinsing liquid is continuously jetted onto the substrate rotated at a constant rate (a spin coating method), a method in which the substrate is immersed in a tank filled with the rinsing liquid for a certain period of time (a dipping method), and a method in which the rinsing liquid is sprayed on the surface of the substrate (a spraying method).

In addition, the pattern forming method according to the embodiment of the present invention may include a heating step (post baking) after the rinsing step. By this step, the developer and the rinsing liquid remaining between and inside the patterns are removed by baking. In addition, this step also has an effect that a resist pattern is annealed and the surface roughness of the pattern is improved. The heating step after the rinsing step is usually performed at 40° C. to 250° C. (preferably 90° C. to 200° C.) for usually 10 seconds to 3 minutes (preferably 30 seconds to 2 minutes).

In addition, an etching treatment on the substrate may be carried out using the formed pattern as a mask. That is, the substrate (or the underlayer film and the substrate) may be processed using the pattern formed in the step 3 as a mask to form a pattern on the substrate.

A method for processing the substrate (or the underlayer film and the substrate) is not particularly limited, but a method in which a pattern is formed on a substrate by subjecting the substrate (or the underlayer film and the substrate) to dry etching using the pattern formed in the step 3 as a mask is preferable. Oxygen plasma etching is preferable as the dry etching.

It is preferable that various materials (for example, the solvent, the developer, the rinsing liquid, a composition for forming the antireflection film, a composition for forming the topcoat, and the like) used in the resist composition and the pattern forming method according to the embodiment of the present invention do not include impurities such as metals. A content of the impurities included in these materials is preferably 1 ppm by mass or less, more preferably 10 ppb by mass or less, still more preferably 100 parts per trillion (ppt) by mass or less, particularly preferably 10 ppt by mass or less, and most preferably 1 ppt by mass or less with respect to the total solid content of the resist composition or the various materials. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing the impurities such as metals from the various materials include filtration using a filter. Details of the filtration using a filter are described in paragraph [0321] of WO2020/004306A.

In addition, examples of a method for reducing the impurities such as metals included in the various materials include a method of selecting raw materials having a low content of metals as raw materials constituting the various materials, a method of subjecting raw materials constituting the various materials to filter filtration, and a method of performing distillation under the condition for suppressing the contamination as much as possible by, for example, lining the inside of a device with TEFLON (registered trademark).

In addition to the filter filtration, removal of the impurities by an adsorbing material may be performed, or a combination of filter filtration and an adsorbing material may be used. As the adsorbing material, known adsorbing materials can be used, and for example, inorganic adsorbing materials such as silica gel and zeolite and organic adsorbing materials such as activated carbon can be used. It is necessary to prevent the incorporation of impurities such as metals in the production process in order to reduce the metal impurities included in the above-described various materials. Sufficient removal of the metal impurities from a production device can be confirmed by measuring the content of metal components included in a washing solution used to wash the production device. A content of the metal components included in the washing solution after the use is preferably 100 parts per trillion (ppt) by mass or less, more preferably 10 ppt by mass or less, and still more preferably 1 ppt by mass or less.

A conductive compound may be added to an organic treatment liquid such as the rinsing liquid in order to prevent breakdown of chemical liquid pipes and various parts (a filter, an O-ring, a tube, or the like) due to electrostatic charging, and subsequently generated electrostatic discharging. Examples of the conductive compound include methanol. From the viewpoint that preferred development characteristics or rinsing characteristics are maintained, an addition amount thereof is preferably 10% by mass or less and more preferably 5% by mass or less.

For members of the chemical liquid pipe, for example, various pipes coated with stainless steel (SUS), or a polyethylene, polypropylene, or a fluororesin (a polytetrafluoroethylene resin, a perfluoroalkoxy resin, or the like) that has been subjected to an antistatic treatment can be used. In the same manner, for the filter or the O-ring, polyethylene, polypropylene, or a fluororesin (polytetrafluoroethylene, a perfluoroalkoxy resin, or the like) that has been subjected to an antistatic treatment can be used.

{Method for Manufacturing Electronic Device}

In addition, the present invention further relates to a method for manufacturing an electronic device, including the above-described pattern forming method, and an electronic device manufactured by this manufacturing method.

The electronic device according to the embodiment of the present invention is suitably mounted on electric and electronic apparatus (for example, home appliances, office automation (OA)-related equipment, media-related equipment, optical equipment, telecommunication equipment, and the like).

### EXAMPLES

Hereinbelow, the present invention will be described in more detail with reference to Examples.

The materials, the amounts of materials used, the proportions, the treatment details, and the treatment procedure in Examples below may be appropriately modified as long as the modifications do not depart from the spirit of the present invention. Therefore, the scope of the present invention should not be construed as being limited to Examples shown below.

{Various Components of Resist Composition}

Each component contained in the resist composition used in Examples and Comparative Examples is shown below.

[Resin A]

Structures of resins (A-1 to A-15 and AX-1) used for preparing the resist composition are shown below.

A numerical value attached to each repeating unit represents a molar ratio of each repeating unit in the resin. “Mw” represents a weight-average molecular weight, and “Pd” represents a ratio of the weight-average molecular weight to a number-average molecular weight, that is, a dispersity.

In addition, a portion of structural formulae of the resin (A-3), the resin (A-5), and the resin (A-8), which is surrounded by a broken line, corresponds to an electron-withdrawing group. A σₚ value of Hammett's law in the resin (A-3) was 0.68 and a σₚ value of Hammett's rule in the resin (A-5) and the resin (A-8) was 0.72.

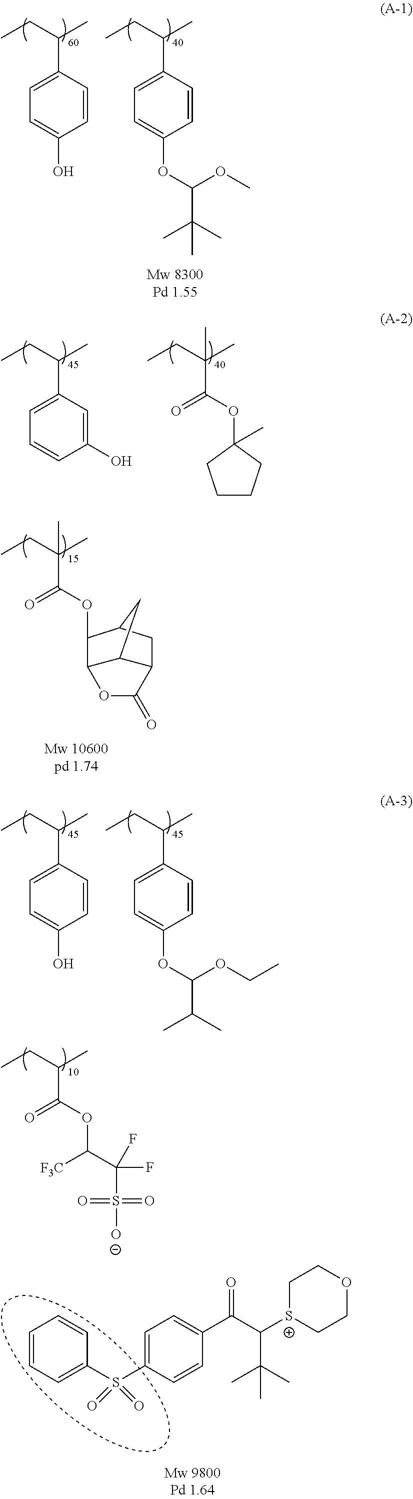

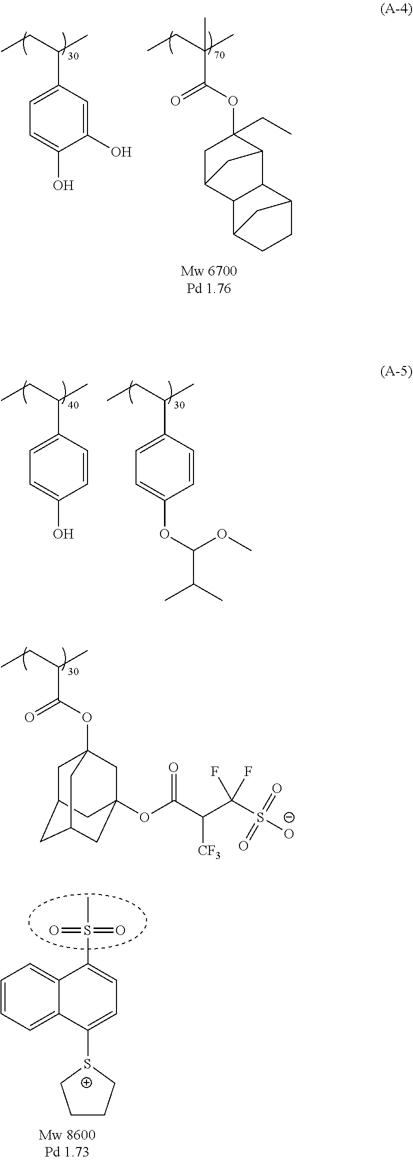

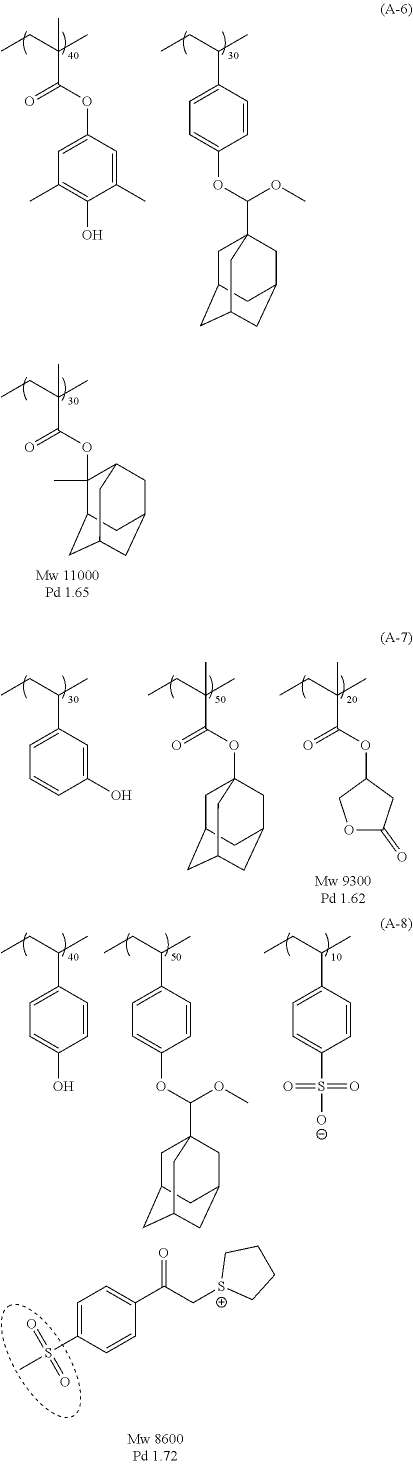

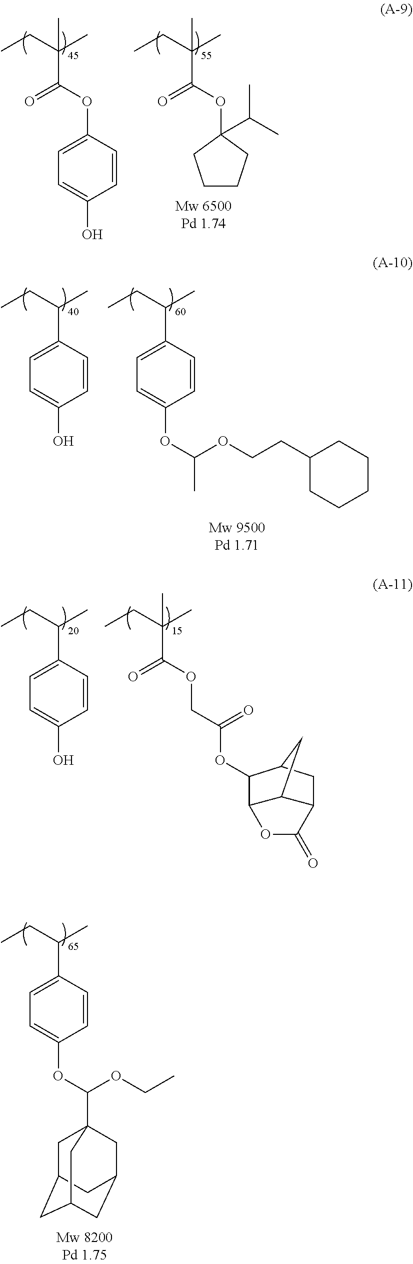

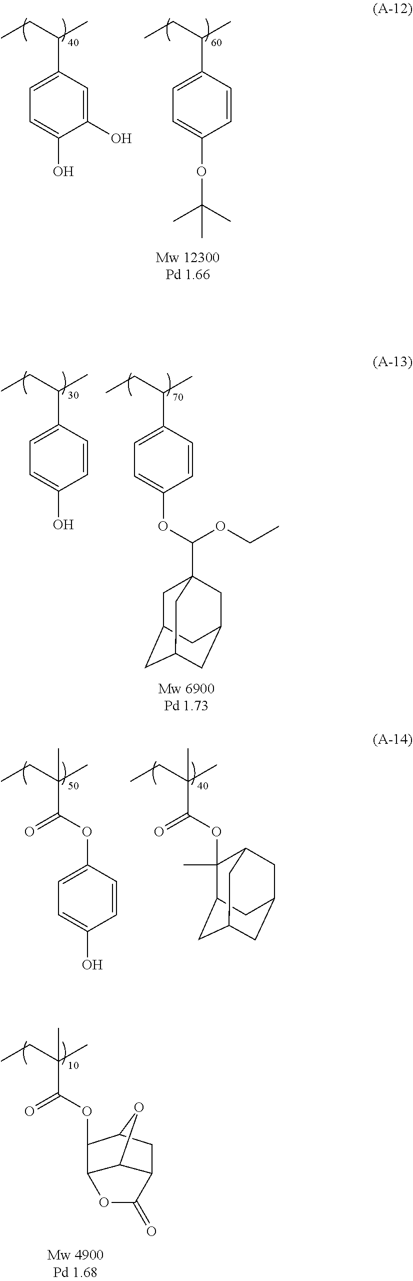

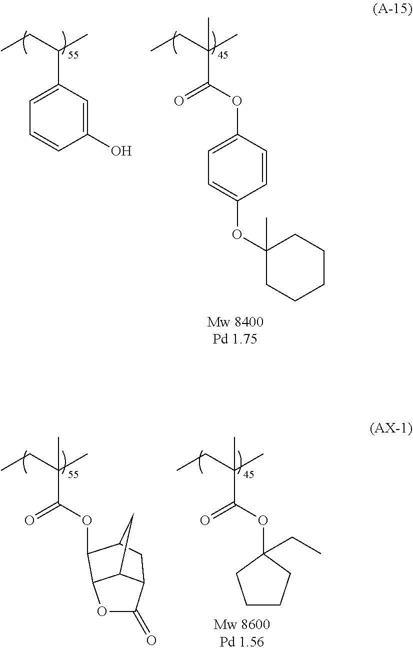

(Synthesis of Resin A-1)

A mixed solution of a monomer (43.3 g) represented by General Formula M-1, a monomer (52.9 g) represented by General Formula M-2, cyclohexanone (130 g), and dimethyl 2,2′-azobisisobutyrate [V-601, manufactured by FUJIFILM Wako Pure Chemical Corporation] (8.6 g) was prepared.

Cyclohexanone (65 g) was heated to 85° C. under a nitrogen stream, and while stirring this liquid, the above-described mixed solution was added dropwise to the liquid over 3 hours. After completion of the dropwise addition, the mixture was further stirred at 85° C. for 3 hours to obtain a reaction solution. After allowing the reaction solution to cool, the reaction solution was added to an ethyl acetate/heptane (mass ratio: 1:9) solution (5,000 g) to generate precipitation. The generated precipitate was filtered and vacuum-dried to obtain a resin A-1 (85 g).

In addition, resins other than the resin A-1 were synthesized according to the synthesis method of the resin A-1.

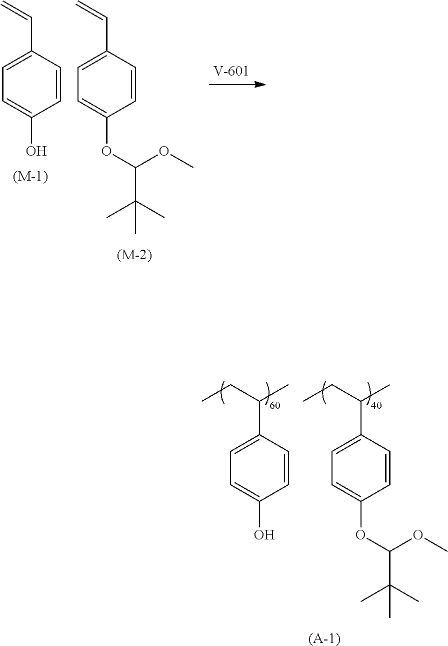

[Salt B]

Structures of salts B (B-1 to B-10) used for preparing the resist composition are shown below.

In addition, a salt BX-1, which was a comparative compound, is also shown below.

A portion in the following structural formulae, which is surrounded by a broken line, corresponds an electron-withdrawing group.

A σₚ value of Hammett's law of the electron-withdrawing group in the salt B-1 was 0.72.

A σₚ value of Hammett's law of the electron-withdrawing group in the salt B-2 was 0.51.

A σₚ value of Hammett's law of the electron-withdrawing group in the salt B-3 was 0.77.

A σₚ value of Hammett's law of the electron-withdrawing group in the salt B-4 was 0.68.

A σₚ value of Hammett's law of the electron-withdrawing group in the salt B-5 was 0.68.

A σₚ value of Hammett's law of the electron-withdrawing group in the salt B-6 was 0.80.

A σₚ value of Hammett's law of the electron-withdrawing group in the salt B-7 was 0.78.

A σₚ value of Hammett's law of the electron-withdrawing group in the salt B-8 was 0.66.

A σₚ value of Hammett's law of the electron-withdrawing group in the salt B-9 was 0.79.

A σₚ value of Hammett's law of the electron-withdrawing group in the salt B-10 was 0.66.

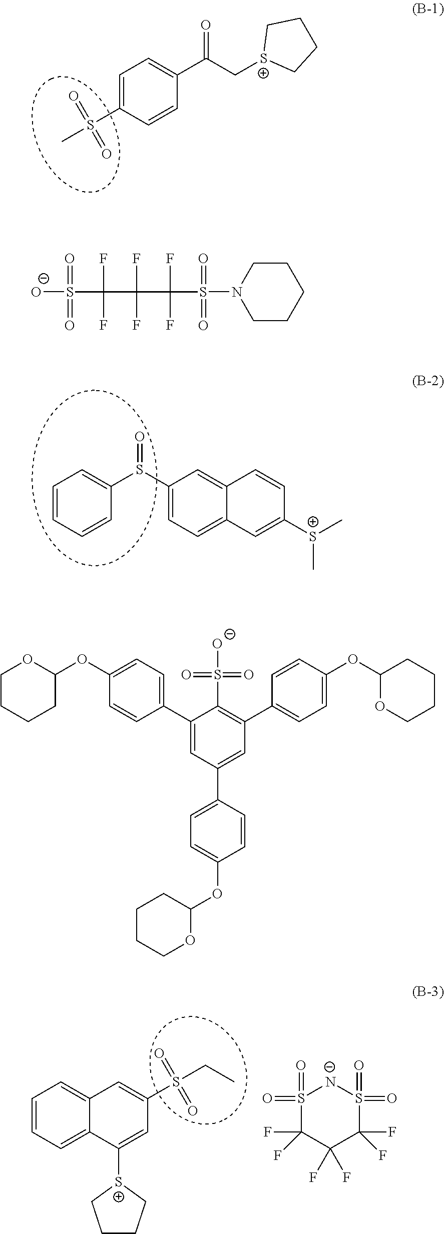 [SMILES: CS(=O)(=O)c1ccc(C(=O)C[S+]2CCCC2)cc1 ; O=S(=O)([O-])C(F)(F)C(F)(F)C(F)(F)S(=O)(=O)N1CCCCC1 ; C[S+](C)c1ccc2cc(S(=O)c3ccccc3)ccc2c1 ; O=S(=O)([O-])c1c(-c2ccc(OC3CCCCO3)cc2)cc(-c2ccc(OC3CCCCO3)cc2)cc1-c1ccc(OC2CCCCO2)cc1 ; CCS(=O)(=O)c1cc([S+]2CCCC2)c2ccccc2c1 ; O=S1(=O)[N-]S(=O)(=O)C(F)(F)C(F)(F)C1(F)F]

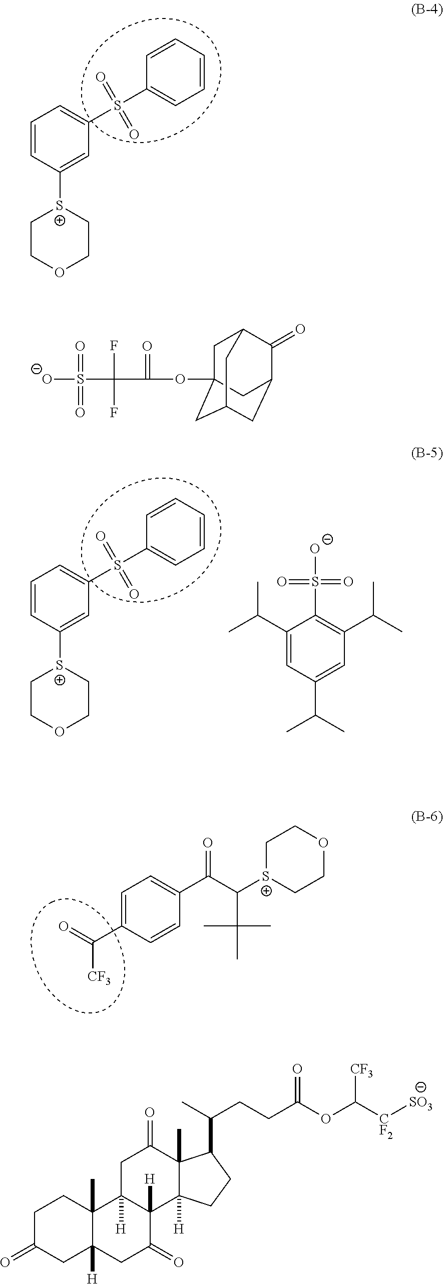

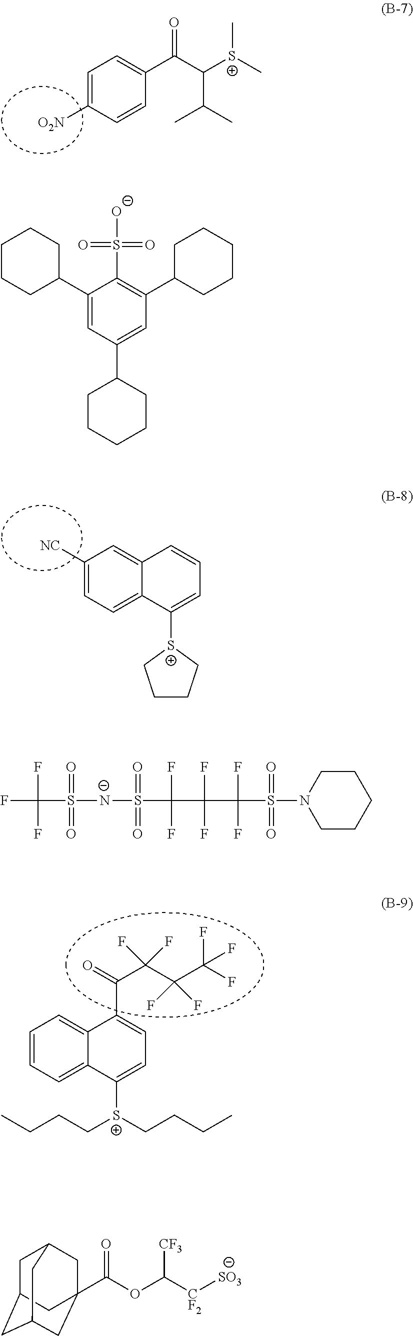

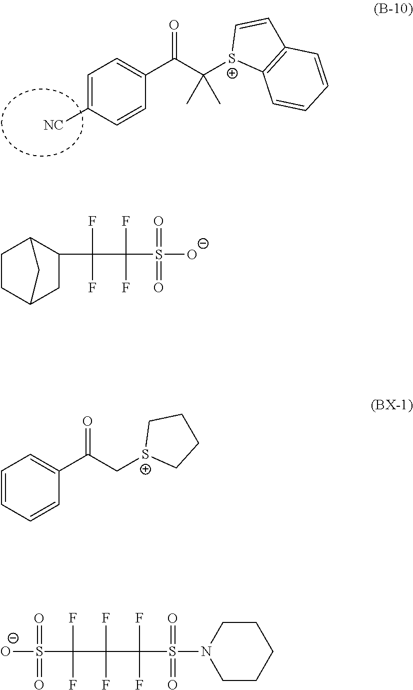 [SMILES: CC(C)(C(=O)c1ccc(C#N)cc1)[s+]1ccc2ccccc21 ; O=S(=O)([O-])C(F)(F)C(F)(F)C1CC2CCC1C2 ; O=C(C[S+]1CCCC1)c1ccccc1 ; O=S(=O)([O-])C(F)(F)C(F)(F)C(F)(F)S(=O)(=O)N1CCCCC1]

(Synthesis of Salt B-1)

2-Bromo-4′-(methylsulfonyl)acetophenone (10 g) was dissolved in tetrahydrofuran (hereinafter, also referred to as “THF”) (20 g). Tetrahydrothiophene (8 g) was added to the solution, and the mixture was stirred at 50° C. for 8 hours to obtain a reaction solution. After allowing the reaction solution to cool, ethyl acetate (50 g) and distilled water (50 g) was added to the reaction solution to separate layers. Thereafter, the organic phase was concentrated to obtain BA-1 (9.5 g).

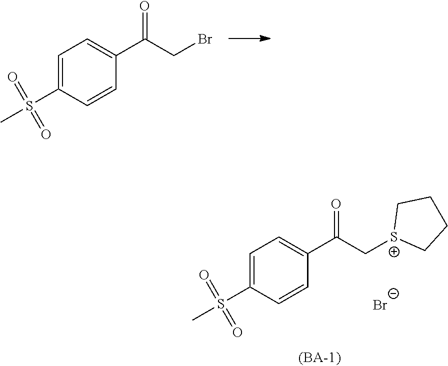 [SMILES: CS(=O)(=O)c1ccc(C(=O)CBr)cc1 ; CS(=O)(=O)c1ccc(C(=O)C[S+]2CCCC2)cc1 ; [Br-]]

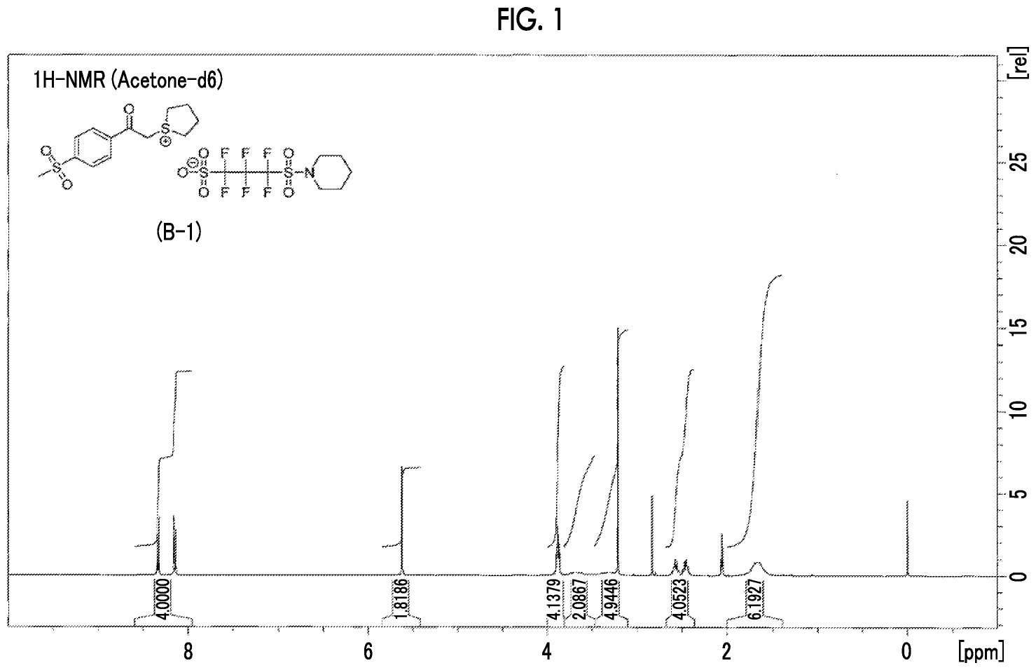

BA-2 (5 g) was dissolved in THF (20 g). A mixed solution of piperidine (1.35 g) and triethylamine (3.2 g) was added dropwise to the solution under ice-cooling. After stirring the obtained solution at room temperature for 2 hours, water (10 g) was added thereto and the mixture was further stirred at room temperature for 2 hours, and the BA-1 (6 g) and methylene chloride (50 g) were further added thereto and the mixture was further stirred at room temperature for 3 hours to obtain a reaction solution. The organic phase was separated from the reaction solution, washed twice with distilled water (50 g), and concentrated to obtain B-1 (7.2 g) as white crystals. In addition, the structure of the salt B-1 was identified by proton nuclear magnetic resonance measurement. FIG. 1 shows a proton nuclear magnetic resonance chart of the salt B-1.

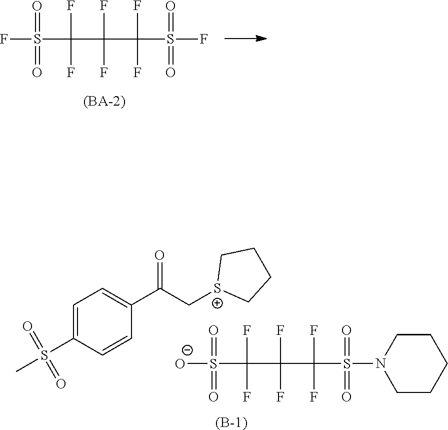

Other salts B were also synthesized by the known method.

[Acid Diffusion Control Agent]

Structures of acid diffusion suppressing agents (D-1 to D-8) used for preparing the resist composition are shown below.

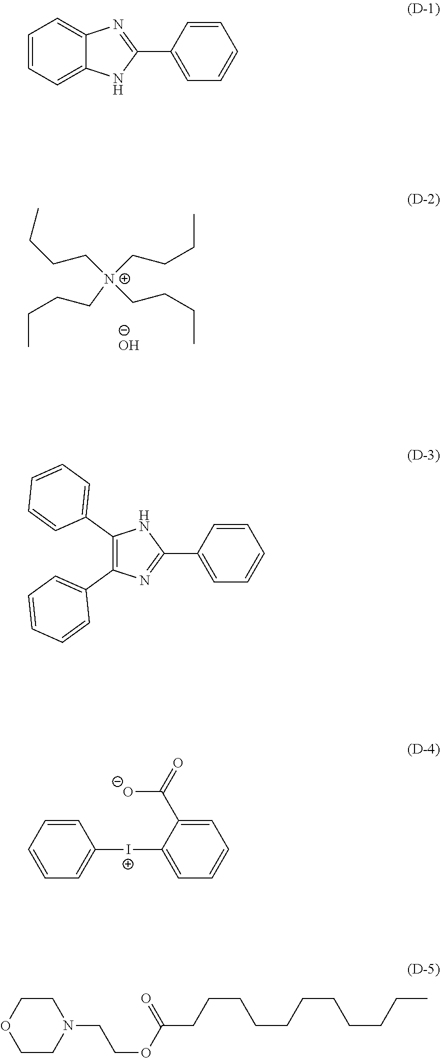

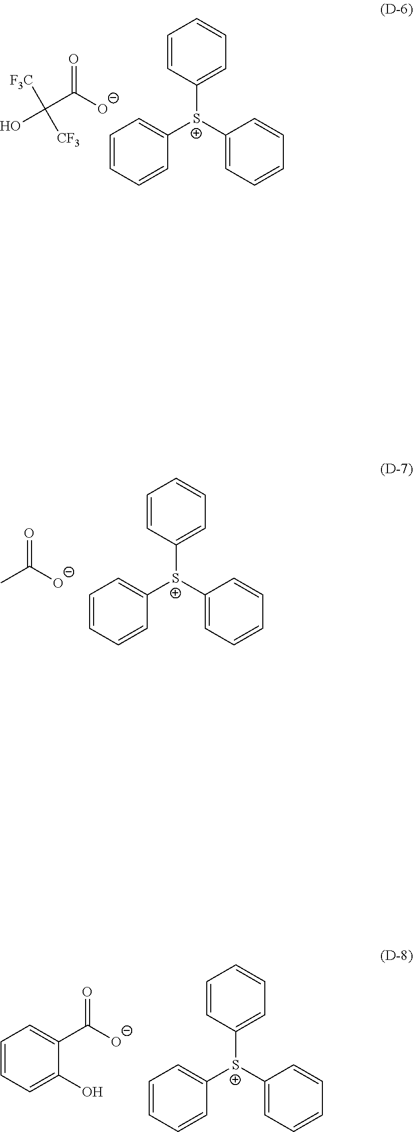

[Surfactant]

Structures of surfactants used for preparing the resist composition are shown below.
W-1: MEGAFACE F176 (manufactured by DIC CORPORATION)
W-2: MEGAFACE R₀₈ (manufactured by DIC CORPORATION)
W-3: Polysiloxane polymer KP-341 (manufactured by Shin-Etsu Chemical Co., Ltd.)
W-4: TROYSOL S-366 (manufactured by Troy Corporation)
W-5: KH-20 (manufactured by Asahi Glass Co., Ltd.)
W-6: PolyFox PF-6320 (manufactured by OMNOVA Solutions Inc.)

[Solvent]

Solvents used for preparing the resist composition are shown below.
SL-1: Propylene glycol monomethyl ether acetate (PGMEA)
SL-2: Propylene glycol monomethyl ether propionate
SL-3: 2-Heptanone
SL-4: Ethyl lactate
SL-5: Propylene glycol monomethyl ether (PGME)
SL-6: Cyclohexanone
SL-7: γ-Butyrolactone
SL-8: Propylene carbonate

{Preparation and Application of Resist Composition}

Each component shown in Table 1 was mixed so that the concentration of solid contents was 3.0% by mass. The obtained mixed solution was filtered through a polyethylene filter having a pore size of 0.02 μm to prepare a resist composition.

“Solid content” means all components excluding the solvent.

Each of these resist compositions was applied onto a 6-inch silicon (Si) wafer pre-treated with hexamethyldisilazane (HMDS) using a spin coater “Mark 8” manufactured by Tokyo Electron Limited, and dried on a hot plate at 130° C. for 300 seconds to obtain a resist film having a film thickness of 100 nm.

Here, 1 inch is 0.0254 m.

In addition, it was confirmed that, even in a case where the Si wafer was changed to a chromium substrate, the same resist film was obtained.

{Exposure and Evaluation}

[EB Exposure]

(Exposure and Development)

The Si wafer on which the resist film obtained above was applied was subjected to pattern irradiation using an electron beam drawing apparatus “F7000S” manufactured by Advantest Corporation (acceleration voltage: 50 KeV). The pattern drawing with the electron beam was performed so that a 1:1 line-and-space having a line width of 50 nm was formed. After the drawing with electron beam, the resist film was heated on a hot plate at 100° C. for 60 seconds, immersed in a 2.38% by mass tetramethylammonium (TMAH) aqueous solution for 60 seconds, and then rinsed with water for 30 seconds. Thereafter, the wafer was rotated at a rotation speed of 4,000 rpm for 30 seconds, baked at 95° C. for 60 seconds, and dried.

(Evaluation)

<Evaluation of LWR>

With the 1:1 line-and-space pattern having a line width of 50 nm, which was obtained by the development, a line width was measured at arbitrary points from an upper part of the pattern using a length-measuring scanning electron microscope “S-9380II” manufactured by Hitachi, Ltd. Variation of each obtained line width was evaluated as 3a (nm). The evaluation results are shown in Table 1. As the value is smaller, the LWR is better.

<Evaluation of Development Defect>

Development defect was evaluated in the pattern obtained by the development. Since the development defect caused a decrease in yield of the product, it is preferable that there were few development defects.

The evaluation of the development defect was carried out on the pattern obtained above using a defect inspection device “2360” manufactured by KLA-Tencor Corporation and “SEMVISION G3” manufactured by Applied Materials, Inc. The defect inspection device was set to a pixel size of 0.16 μm, a threshold value of 20, and measurement in a random mode. The detection of the development defect was performed by extracting from a difference caused by superimposition of a comparative image and a pixel-by-pixel unit. Thereafter, the number of defects per unit area (pieces/cm²) on the wafer was measured by SEMVISION G3. The evaluation of the development defect was carried out according to the following standard.

The evaluation results are shown in Table 1.

—Evaluation Standard—
A: less than 0.5 pieces/cm²
B: 0.5 pieces/cm² or more and less than 0.8 pieces/cm²
C: 0.8 pieces/cm² or more

[EUV Exposure]

(Exposure and Development)

The wafer on which the resist film obtained above was applied was subjected to pattern exposure using an EUV exposure device (numerical aperture (NA): 0.3, Quadrupole, outer sigma: 0.68, inner sigma: 0.36) manufactured by Exitech Ltd. As an exposure mask, a mask having a line width of 50 nm and a 1:1 line-and-space pattern was used.

After the exposure, the resist film was heated on a hot plate at 100° C. for 90 seconds, immersed in a 2.38% by mass tetramethylammonium (TMAH) aqueous solution for 60 seconds, and then rinsed with water for 30 seconds. Thereafter, the wafer was rotated at a rotation speed of 4,000 rpm for 30 seconds, baked at 95° C. for 60 seconds, and dried.

(Evaluation)

<Evaluation of LWR>

With the 1:1 line-and-space pattern having a line width of 50 nm, which was obtained by the development, LWR was evaluated in the same manner as in the case of EB exposure. The results are shown in Table 1. As the value is smaller, the LWR is better.

In the table, each description indicates the following.

“-” in the column of the salt B indicates that the salt B was not blended.

In the column of the type of the solvent, for example, the notation of “SL-1/SL-5” in Example 1 indicates SL-1 and SL-5 were mixed and used, and the notation of “60/40” in the column of the mass ratio indicates that the mass ratio of SL-1 was 60 and the mass ratio of SL-5 was 40 in a case where the total mass of the solvent was set to 100.

In the column of “General Formula (2)”, a case where the salt (B) or the salt (B) in the specific group included in the resin (A) corresponded to the salt represented by General Formula (2) was defined as “A”, and a case of not corresponding to the salt represented by General Formula (2) was defined as “B”. In Example 8, the result of the salt in the specific group included in the resin (A) and the result of the salt (B) are shown from the left side.

In the column of “General Formula (X1)”, a case where the salt (B) or the specific group included in the resin (A) had the group represented by General Formula (X1) was defined as “A”, and a case of not having the group represented by General Formula (X1) was defined as “B”. In Example 8, the result of the salt in the specific group included in the resin (A) and the result of the salt (B) are shown from the left side.

In the column of “General Formula (X2)”, a case where the salt (B) or the specific group included in the resin (A) had the group represented by General Formula (X2) was defined as “A”, and a case of not having the group represented by General Formula (X2) was defined as “B”. In Example 8, the result of the salt in the specific group included in the resin (A) and the result of the salt (B) are shown from the left side.

In the column of “Unit 1”, a case where the resin (A) had the repeating unit represented by any one of General Formula (3), (4), (5), (6), or (7) was defined as “A”, and a case of not having the repeating unit was defined as “B”.

In the column of “Unit 2”, a case where the resin (A) had the repeating unit represented by General Formula (6) or General Formula (7) was defined as “A”, and a case of not having the repeating unit was defined as “B”.

TABLE 1

| | Resin (A) | | Salt (B) | | Basic | | Surfactant | | Solvent | |
|---|---|---|---|---|---|---|---|---|---|---|
| | | Content | | Content | | Content | | Content | | Mass |
| | Type | (g) | Type | (g) | Type | (g) | Type | (g) | Type | ratio |
| Example 1 | A-1 | 10 | B-1 | 1.0 | D-1 | 0.2 | W-1 | 0.003 | SL-1/SL-5 | 60/40 |
| Example 2 | A-2 | 10 | B-2 | 1.2 | D-4 | 0.2 | W-4 | 0.003 | SL-1/SL-2 | 60/40 |
| Example 3 | A-3 | 9 | — | — | D-5 | 0.1 | W-5 | 0.003 | SL-1/SL-5 | 60/40 |
| Example 4 | A-4 | 10 | B-4 | 0.9 | D-6 | 0.2 | W-3 | 0.003 | SL-1/SL-7 | 90/10 |
| Example 5 | A-5 | 10 | — | — | D-8 | 0.2 | W-6 | 0.003 | SL-1/SL-6 | 60/40 |
| Example 6 | A-6 | 10 | B-6 | 0.85 | D-1 | 0.25 | W-1 | 0.003 | SL-1/SL-5 | 50/50 |
| Example 7 | A-7 | 9 | B-7 | 1.0 | D-6 | 0.3 | W-3 | 0.003 | SL-1/SL-5 | 70/30 |
| Example 8 | A-8 | 10 | B-8 | 0.2 | D-7 | 0.3 | W-4 | 0.003 | SL-1/SL-8 | 80/20 |
| Example 9 | A-9 | 10 | B-9 | 1.1 | D-8 | 0.2 | W-4 | 0.003 | SL-1/SL-8 | 80/20 |
| Example 10 | A-10 | 9 | B-10 | 1.0 | D-3 | 0.15 | W-6 | 0.003 | SL-1/SL-5 | 70/30 |
| Example 11 | A-11 | 10 | B-3 | 1.0 | D-4 | 0.15 | W-1 | 0.003 | SL-1/SL-7 | 90/10 |
| Example 12 | A-12 | 10 | B-1 | 1.1 | D-5 | 0.1 | W-5 | 0.003 | SL-1/SL-5 | 60/40 |
| Example 13 | A-13 | 9 | B-5 | 1.0 | D-8 | 0.25 | W-2 | 0.003 | SL-1/SL-5 | 60/40 |
| Example 14 | A-14 | 10 | B-7 | 1.2 | D-5 | 0.3 | W-6 | 0.003 | SL-4/SL-2 | 60/40 |
| Example 15 | A-15 | 10 | B-6 | 1.0 | D-2 | 0.2 | W-3 | 0.003 | SL-1/SL-5 | 60/40 |
| Example 16 | A-1 | 10 | B-10 | 1.0 | D-1 | 0.2 | W-1 | 0.003 | SL-1/SL-5 | 60/40 |
| Comparative | AX-1 | 10 | B-1 | 1.0 | D-1 | 0.2 | W-1 | 0.003 | SL-1/SL-5 | 60/40 |
| Example 1 | | | | | | | | | | |
| Comparative | AX-1 | 10 | BX-1 | 1.0 | D-1 | 0.2 | W-1 | 0.003 | SL-1/SL-5 | 60/40 |
| Example 2 | | | | | | | | | | |

| | | | | | | | | EUV |
|---|---|---|---|---|---|---|---|---|
| | General | General | General | | | EB evaluation | | evaluation |
| | Formula | Formula | Formula | | | LWR | Development | LWR |
| | (2) | (X1) | (X2) | Unit 1 | Unit 2 | (nm) | defect | (nm) |
| Example 1 | A | A | A | A | A | 4.0 | A | 4.1 |
| Example 2 | B | A | B | A | B | 4.4 | B | 4.5 |
| Example 3 | A | A | A | A | A | 4.1 | A | 4.0 |
| Example 4 | B | A | A | A | B | 4.5 | A | 4.5 |
| Example 5 | B | A | A | A | A | 4.3 | A | 4.3 |
| Example 6 | A | A | B | A | A | 4.0 | B | 4.0 |
| Example 7 | A | B | B | A | B | 4.2 | B | 4.3 |
| Example 8 | A/B | A/B | A/B | A | A | 4.0 | B | 4.1 |
| Example 9 | B | A | B | A | B | 4.5 | B | 4.5 |
| Example 10 | A | B | B | A | A | 4.0 | B | 4.0 |
| Example 11 | B | A | A | A | A | 4.2 | A | 4.3 |
| Example 12 | A | A | A | B | B | 4.2 | A | 4.3 |
| Example 13 | B | A | A | A | A | 4.2 | A | 4.3 |
| Example 14 | A | B | B | A | B | 4.3 | B | 4.3 |
| Example 15 | A | A | B | B | B | 4.2 | B | 4.2 |
| Example 16 | A | B | B | A | A | 4.1 | B | 4.0 |
| Comparative | — | — | — | — | — | 5.5 | C | 5.3 |
| Example 1 | | | | | | | | |
| Comparative | — | — | — | — | — | 6.4 | C | 6.5 |
| Example 2 | | | | | | | | |

In Table 1, by comparing the results of Examples and Comparative Examples, it was confirmed that the composition according to the embodiment of the present invention was excellent in LWR. Furthermore, it was confirmed that the composition according to the embodiment of the present invention was also excellent in development defect property during EB exposure.

In Table 1, by comparing the results of Examples 1, 3 to 5, and 11 to 13 and the results of other Examples, it was confirmed that, in a case where at least one of R₁'s in General Formula (1) was the group represented by General Formula (X2), the development defect property during EB exposure was excellent.

In Table 1, from a comparison of Examples (for example, Examples 1 and 5), it was confirmed that, in a case where the salt was the salt represented by General Formula (2), the composition according to the embodiment of the present invention was excellent in LWR.

In Table 1, from a comparison of Examples (for example, Examples 4 and 5), it was confirmed that, in a case where the repeating unit having a group which is decomposed by action of acid to generate a polar group was the repeating unit represented by General Formula (6) or General Formula (7), the composition according to the embodiment of the present invention was excellent in LWR.

What is claimed is:

1. An actinic ray-sensitive or radiation-sensitive resin composition comprising:
a resin having a group which is decomposed by action of acid to generate a polar group,
wherein the resin includes a repeating unit represented by General Formula (A2), and
at least one of a requirement 1 or a requirement 2 is satisfied,
the requirement 1: the actinic ray-sensitive or radiation-sensitive resin composition contains a salt represented by General Formula (1),
the requirement 2: the resin has a residue formed by removing one hydrogen atom from the salt represented by General Formula (1), 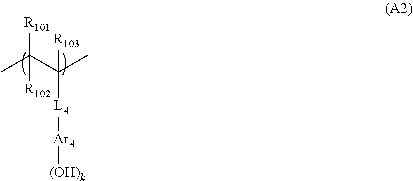
in General Formula (A2),
R₁₀₁ to R₁₀₃ each independently represent a hydrogen atom, an alkyl group, a cycloalkyl group, a halogen atom, a cyano group, or an alkyloxycarbonyl group, where R₁₀₂ may be bonded to Ar_{A} to form a ring, and in this case, R₁₀₂ represents a single bond or an alkylene group,
L_{A} represents a single bond or a divalent linking group,
Ar_{A} represents a (k+1)-valent aromatic ring group, and
k represents an integer of 1 to 5, 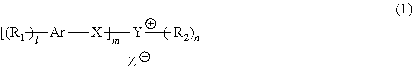
in General Formula (1), R₁'s each independently represent a monovalent substituent, R₂ represents an alkyl group which may have a substituent, a cycloalkyl group which may have a substituent, or an aryl group which may have a substituent, where in a case where n is 2, two R₂'s may be bonded to each other to form a ring, Ar represents an (l+1)-valent aromatic ring group, X represents a single bond or a divalent linking group, Y represents a sulfur atom or an iodine atom, Z⁻ represents an anion, 1 represents an integer of 1 to 5, in a case where Y is a sulfur atom, m represents an integer of 1 to 3 and n represents 3−m, in a case where Y is an iodine atom, m represents 1 or 2 and n represents 2−m, and at least one of R₁'s represents an electron-withdrawing group.

2. The actinic ray-sensitive or radiation-sensitive resin composition according to claim 1,
wherein the salt represented by General Formula (1) is a salt represented by General Formula (2), 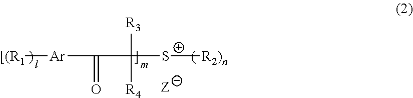
in General Formula (2), R₁'s each independently represent a monovalent substituent, R₂ represents an alkyl group which may have a substituent, a cycloalkyl group which may have a substituent, or an aryl group which may have a substituent, where in a case where n is 2, two R₂'s may be bonded to each other to form a ring, Ar represents an (l+1)-valent aromatic ring group, R₃ and R₄ each independently represent a hydrogen atom, an alkyl group, a cycloalkyl group, or an aryl group, where R₃ and R₄ may be bonded to each other to form a ring, Z⁻ represents an anion, 1 represents an integer of 1 to 5, m represents an integer of 1 to 3, n represents 3−m, and at least one of R₁'s represents an electron-withdrawing group.

3. The actinic ray-sensitive or radiation-sensitive resin composition according to claim 1,
wherein at least one of R₁'s represents a group represented by General Formula (X1),
*-L-R₅ (X1)
in General Formula (X1), L represents —CO—, —SO₂—, or —SO—, R₅ represents a monovalent substituent, and * represents a bonding position.

4. The actinic ray-sensitive or radiation-sensitive resin composition according to claim 1,
wherein at least one of R₁'s represents a group represented by General Formula (X2),
*—SO₂—R₅ (X2)
in General Formula (X2), R₅ represents a monovalent substituent, and * represents a bonding position.

5. The actinic ray-sensitive or radiation-sensitive resin composition according to claim 1,
wherein the resin has a repeating unit having a group which is decomposed by action of acid to generate a polar group, and
the group which is decomposed by action of acid to generate a polar group is a group which is decomposed by action of acid to generate a carboxy group or a phenolic hydroxyl group.

6. The actinic ray-sensitive or radiation-sensitive resin composition according to claim 5,
wherein the repeating unit having a group which is decomposed by action of acid to generate a polar group is a repeating unit represented by any one of General Formula (3), (4), (5), (6), or (7), 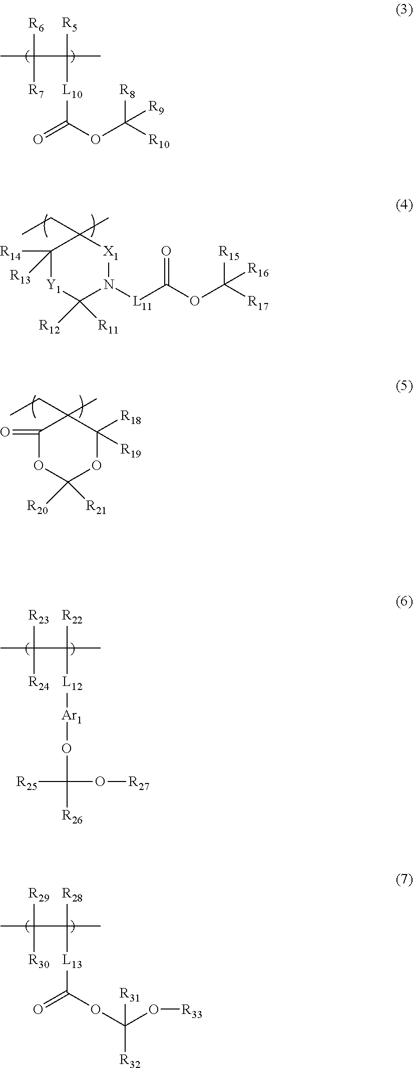
in General Formula (3), R₅ to R₇ each independently represent a hydrogen atom, an alkyl group, a cycloalkyl group, a halogen atom, a cyano group, or an alkoxycarbonyl group, L₁₀ represents a single bond or a divalent linking group, R₈ to R₁₀ each independently represent an alkyl group, a cycloalkyl group, an aryl group, an aralkyl group, or an alkenyl group, and at least two of R₈ to R₁₀ may be bonded to each other to form a ring,
in General Formula (4), R₁₁ to R₁₄ each independently represent a hydrogen atom or an organic group, where at least one of R₁₁ or R₁₂ represents an organic group, X₁ represents —CO—, —SO—, or —SO₂—, Y₁ represents —O—, —S—, —SO—, —SO₂—, or —NR₃₄—, R₃₄ represents a hydrogen atom or an organic group, L₁₁ represents a single bond or a divalent linking group, R₁₅ to R₁₇ each independently represent an alkyl group, a cycloalkyl group, an aryl group, an aralkyl group, or an alkenyl group, and at least two of R₁₅ to R₁₇ may be bonded to each other to form a ring,
in General Formula (5), R₁₈ and R₁₉ each independently represent a hydrogen atom or an organic group, R₂₀ and R₂₁ each independently represent a hydrogen atom, an alkyl group, a cycloalkyl group, an aryl group, an aralkyl group, or an alkenyl group, and R₂₀ and R₂₁, and R₁₈ and R₁₉ may be bonded to each other to form a ring,
in General Formula (6), R₂₂ to R₂₄ each independently represent a hydrogen atom, an alkyl group, a cycloalkyl group, a halogen atom, a cyano group, or an alkoxycarbonyl group, L₁₂ represents a single bond or a divalent linking group, Ar₁ represents an aromatic ring group, R₂₅ to R₂₇ each independently represent a hydrogen atom, an alkyl group, a cycloalkyl group, an aryl group, an aralkyl group, or an alkenyl group, R₂₆ and R₂₇ may be bonded to each other to form a ring, and Ar₁ may be bonded to R₂₄ or R₂₅ to form a ring,
in General Formula (7), R₂₈ to R₃₀ each independently represent a hydrogen atom, an alkyl group, a cycloalkyl group, a halogen atom, a cyano group, or an alkoxycarbonyl group, L₁₃ represents a single bond or a divalent linking group, R₃₁ and R₃₂ each independently represent a hydrogen atom, an alkyl group, a cycloalkyl group, an aryl group, an aralkyl group, or an alkenyl group, R₃₃ represents an alkyl group, a cycloalkyl group, an aryl group, an aralkyl group, or an alkenyl group, and R₃₂ and R₃₃ may be bonded to each other to form a ring.

7. The actinic ray-sensitive or radiation-sensitive resin composition according to claim 6,
wherein the repeating unit having a group which is decomposed by action of acid to generate a polar group is the repeating unit represented by General Formula (6) or General Formula (7).

8. A resist film formed of the actinic ray-sensitive or radiation-sensitive resin composition according to claim 1.

9. A pattern forming method comprising:
a resist film forming step of forming a resist film using the actinic ray-sensitive or radiation-sensitive resin composition according to claim 1;
an exposing step of exposing the resist film; and
a developing step of developing the exposed resist film using a developer.

10. A method for manufacturing an electronic device, comprising:
the pattern forming method according to claim 9.

11. The actinic ray-sensitive or radiation-sensitive resin composition according to claim 2,
wherein at least one of R₁'s represents a group represented by General Formula (X1),
*-L-R₅ (X1)
in General Formula (X1), L represents —CO—, —SO₂—, or —SO—, R₅ represents a monovalent substituent, and * represents a bonding position.

12. The actinic ray-sensitive or radiation-sensitive resin composition according to claim 2,
wherein at least one of R₁'s represents a group represented by General Formula (X2),
*—SO₂—R₅ (X2)
in General Formula (X2), R₅ represents a monovalent substituent, and * represents a bonding position.

13. The actinic ray-sensitive or radiation-sensitive resin composition according to claim 2,
wherein the resin has a repeating unit having a group which is decomposed by action of acid to generate a polar group, and
the group which is decomposed by action of acid to generate a polar group is a group which is decomposed by action of acid to generate a carboxy group or a phenolic hydroxyl group.

14. The actinic ray-sensitive or radiation-sensitive resin composition according to claim 13,
wherein the repeating unit having a group which is decomposed by action of acid to generate a polar group is a repeating unit represented by any one of General Formula (3), (4), (5), (6), or (7), 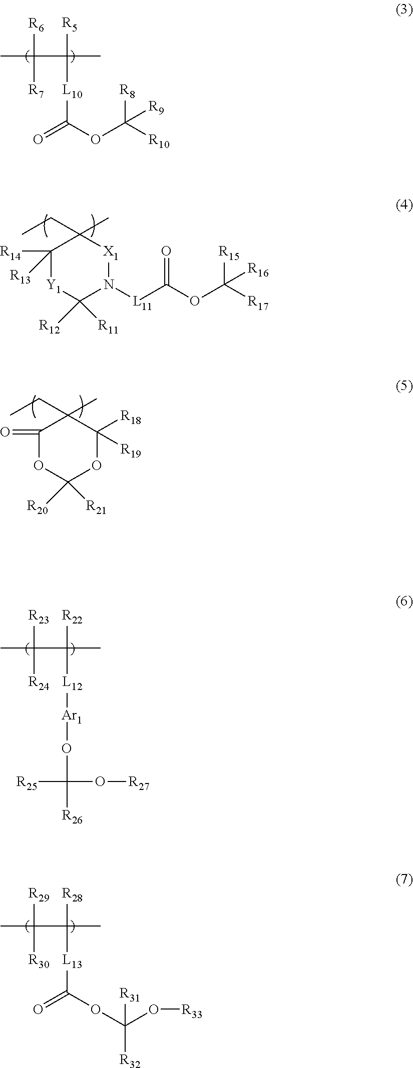
in General Formula (3), R₅ to R₇ each independently represent a hydrogen atom, an alkyl group, a cycloalkyl group, a halogen atom, a cyano group, or an alkoxycarbonyl group, L₁₀ represents a single bond or a divalent linking group, R₈ to R₁₀ each independently represent an alkyl group, a cycloalkyl group, an aryl group, an aralkyl group, or an alkenyl group, and at least two of R₈ to R₁₀ may be bonded to each other to form a ring,
in General Formula (4), R₁₁ to R₁₄ each independently represent a hydrogen atom or an organic group, where at least one of R₁₁ or R₁₂ represents an organic group, X₁ represents —CO—, —SO—, or —SO₂—, Y₁ represents —O—, —S—, —SO—, —SO₂—, or —NR₃₄—, R₃₄ represents a hydrogen atom or an organic group, L₁₁ represents a single bond or a divalent linking group, R₁₅ to R₁₇ each independently represent an alkyl group, a cycloalkyl group, an aryl group, an aralkyl group, or an alkenyl group, and at least two of R₁₅ to R₁₇ may be bonded to each other to form a ring,
in General Formula (5), R₁₈ and R₁₉ each independently represent a hydrogen atom or an organic group, R₂₀ and R₂₁ each independently represent a hydrogen atom, an alkyl group, a cycloalkyl group, an aryl group, an aralkyl group, or an alkenyl group, and R₂₀ and R₂₁, and R₁₈ and R₁₉ may be bonded to each other to form a ring,
in General Formula (6), R₂₂ to R₂₄ each independently represent a hydrogen atom, an alkyl group, a cycloalkyl group, a halogen atom, a cyano group, or an alkoxycarbonyl group, L₁₂ represents a single bond or a divalent linking group, Ar₁ represents an aromatic ring group, R₂₅ to R₂₇ each independently represent a hydrogen atom, an alkyl group, a cycloalkyl group, an aryl group, an aralkyl group, or an alkenyl group, R₂₆ and R₂₇ may be bonded to each other to form a ring, and Ar₁ may be bonded to R₂₄ or R₂₅ to form a ring,
in General Formula (7), R₂₈ to R₃₀ each independently represent a hydrogen atom, an alkyl group, a cycloalkyl group, a halogen atom, a cyano group, or an alkoxycarbonyl group, L₁₃ represents a single bond or a divalent linking group, R₃₁ and R₃₂ each independently represent a hydrogen atom, an alkyl group, a cycloalkyl group, an aryl group, an aralkyl group, or an alkenyl group, R₃₃ represents an alkyl group, a cycloalkyl group, an aryl group, an aralkyl group, or an alkenyl group, and R₃₂ and R₃₃ may be bonded to each other to form a ring.

15. The actinic ray-sensitive or radiation-sensitive resin composition according to claim 14,
wherein the repeating unit having a group which is decomposed by action of acid to generate a polar group is the repeating unit represented by General Formula (6) or General Formula (7).

16. A resist film formed of the actinic ray-sensitive or radiation-sensitive resin composition according to claim 2.

17. A pattern forming method comprising:
a resist film forming step of forming a resist film using the actinic ray-sensitive or radiation-sensitive resin composition according to claim 2;
an exposing step of exposing the resist film; and
a developing step of developing the exposed resist film using a developer.

18. A method for manufacturing an electronic device, comprising:
the pattern forming method according to claim 17.

19. The actinic ray-sensitive or radiation-sensitive resin composition according to claim 3,
wherein the resin has a repeating unit having a group which is decomposed by action of acid to generate a polar group, and
the group which is decomposed by action of acid to generate a polar group is a group which is decomposed by action of acid to generate a carboxy group or a phenolic hydroxyl group.

20. The actinic ray-sensitive or radiation-sensitive resin composition according to claim 19,
wherein the repeating unit having a group which is decomposed by action of acid to generate a polar group is a repeating unit represented by any one of General Formula (3), (4), (5), (6), or (7), 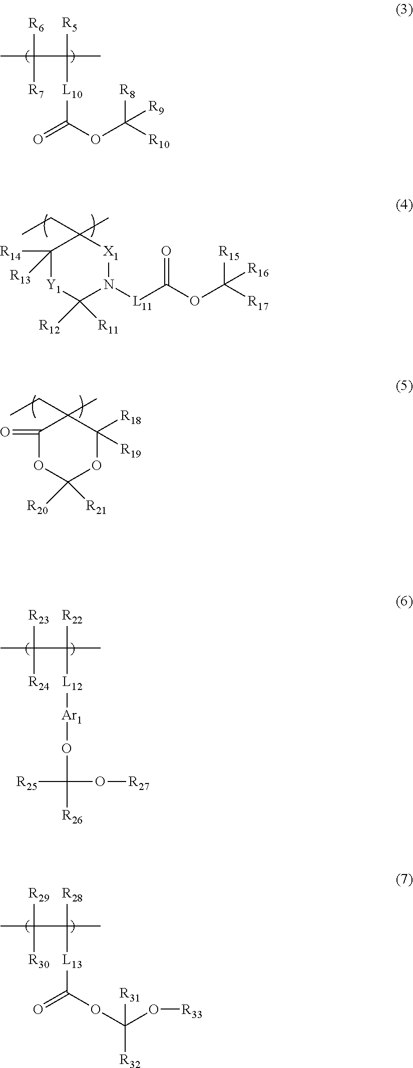
in General Formula (3), R₅ to R₇ each independently represent a hydrogen atom, an alkyl group, a cycloalkyl group, a halogen atom, a cyano group, or an alkoxycarbonyl group, L₁₀ represents a single bond or a divalent linking group, R₈ to R₁₀ each independently represent an alkyl group, a cycloalkyl group, an aryl group, an aralkyl group, or an alkenyl group, and at least two of R₈ to R₁₀ may be bonded to each other to form a ring,
in General Formula (4), R₁₁ to R₁₄ each independently represent a hydrogen atom or an organic group, where at least one of R₁₁ or R₁₂ represents an organic group, X₁ represents —CO—, —SO—, or —SO₂—, Y₁ represents —O—, —S—, —SO—, —SO₂—, or —NR₃₄—, R₃₄ represents a hydrogen atom or an organic group, L₁₁ represents a single bond or a divalent linking group, R₁₅ to R₁₇ each independently represent an alkyl group, a cycloalkyl group, an aryl group, an aralkyl group, or an alkenyl group, and at least two of R₁₅ to R₁₇ may be bonded to each other to form a ring,
in General Formula (5), R₁₈ and R₁₉ each independently represent a hydrogen atom or an organic group, R₂₀ and R₂₁ each independently represent a hydrogen atom, an alkyl group, a cycloalkyl group, an aryl group, an aralkyl group, or an alkenyl group, and R₂₀ and R₂₁, and R₁₈ and R₁₉ may be bonded to each other to form a ring,
in General Formula (6), R₂₂ to R₂₄ each independently represent a hydrogen atom, an alkyl group, a cycloalkyl group, a halogen atom, a cyano group, or an alkoxycarbonyl group, L₁₂ represents a single bond or a divalent linking group, Ar₁ represents an aromatic ring group, R₂₅ to R₂₇ each independently represent a hydrogen atom, an alkyl group, a cycloalkyl group, an aryl group, an aralkyl group, or an alkenyl group, R₂₆ and R₂₇ may be bonded to each other to form a ring, and Ar₁ may be bonded to R₂₄ or R₂₅ to form a ring,
in General Formula (7), R₂₈ to R₃₀ each independently represent a hydrogen atom, an alkyl group, a cycloalkyl group, a halogen atom, a cyano group, or an alkoxycarbonyl group, L₁₃ represents a single bond or a divalent linking group, R₃₁ and R₃₂ each independently represent a hydrogen atom, an alkyl group, a cycloalkyl group, an aryl group, an aralkyl group, or an alkenyl group, R₃₃ represents an alkyl group, a cycloalkyl group, an aryl group, an aralkyl group, or an alkenyl group, and R₃₂ and R₃₃ may be bonded to each other to form a ring.
